(19) United States
(12) Patent Application Publication
(10) Pub. No.: US 2024/0215276 A1
(43) Pub. Date: Jun. 27, 2024

(54) ORGANIC PHOTODETECTOR AND ELECTRONIC APPARATUS INCLUDING THE SAME

(71) Applicant: Samsung Display Co., Ltd., Yongin-si (KR)

(72) Inventors: Jinsoo Jung, Yongin-si (KR); Minsoo Choi, Yongin-si (KR); Soungwook Kim, Yongin-si (KR); Seokgyu Yoon, Yongin-si (KR)

(21) Appl. No.: 18/483,459

(22) Filed: Oct. 9, 2023

(30) Foreign Application Priority Data
Nov. 30, 2022 (KR) 10-2022-0165100

(51) Int. Cl. H10K 30/86; H10K 30/81; H10K 30/85; H10K 39/00; H10K 50/15; H10K 85/60

(52) U.S. Cl. CPC H10K 30/86; H10K 30/81; H10K 30/85; H10K 39/601; H10K 50/157; H10K 85/615; H10K 85/633; H10K 85/654; H10K 2101/40

(57) ABSTRACT

An organic photodetector includes an activation layer including a p-type semiconductor compound and an n-type semiconductor compound, an optical auxiliary layer including a first optical auxiliary layer including a first amine compound and a second optical auxiliary layer including a second amine compound, a highest occupied molecular orbital (HOMO) energy absolute value of the first amine compound is smaller than a HOMO energy absolute value of the second amine compound, and the first optical auxiliary layer faces the first electrode.

### CROSS-REFERENCE TO RELATED APPLICATION

This application claims priority to and the benefit of Korean Patent Application No. 10-2022-0165100, filed on Nov. 30, 2022, in the Korean Intellectual Property Office, the disclosure of which is incorporated by reference herein in its entirety.

### BACKGROUND

### 1. Field

One or more embodiments of the present disclosure relate to an organic photodetector and an electronic apparatus including the same.

### 2. Description of the Related Art

Photoelectric devices, which convert light and an electrical signal, may include a photodiode and a phototransistor and may be applied to an image sensor, a solar cell, an organic light-emitting device, and/or the like.

In the case of silicon, which is utilized in photodiodes, as the size of pixels decreases, an absorption area may decrease, thus deteriorating sensitivity. Accordingly, organic materials that may replace silicon are being studied.

Because organic materials have a relatively large extinction coefficient and may selectively absorb light in a specific wavelength region according to the molecular structure thereof, organic materials may replace photodiodes and color filters concurrently (e.g., simultaneously), which may facilitate improvements in sensitivity and high integration.

An organic photodetector (OPD) including such an organic material may be applied to, for example, a display apparatus or an image sensor.

### SUMMARY

Aspects of embodiments may be directed toward an organic photodetector with substantially improved efficiency and an electronic apparatus including the same.

Additional aspects will be set forth in part in the description, which follows and, in part, will be apparent from the description, or may be learned by practice of the presented embodiments of the disclosure.

According to one or more embodiments, an organic photodetector includes
a first electrode,
a second electrode facing the first electrode, and
an activation layer and an optical auxiliary layer, wherein the activation layer and the optical auxiliary layer may be between the first electrode and the second electrode,
wherein the activation layer includes a p-type semiconductor (e.g., p-semiconductor) compound and an n-type semiconductor (e.g., n-semiconductor) compound,
the optical auxiliary layer includes a first optical auxiliary layer including a first amine compound, and a second optical auxiliary layer including a second amine compound,
a highest occupied molecular orbital (HOMO) energy absolute value of the first amine compound is smaller than a HOMO energy absolute value of the second amine compound, and
the first optical auxiliary layer faces the first electrode.

In an embodiment, the activation layer and the optical auxiliary layer may be in contact with each other.

In an embodiment, the activation layer and the second optical auxiliary layer may be in contact with each other.

In an embodiment, the activation layer may include a layer including the p-type semiconductor compound and a layer including the n-type semiconductor compound, and
the layer including the p-type semiconductor compound may be in contact with the second optical auxiliary layer.

In an embodiment, the HOMO energy absolute value of the first amine compound may be 5.00 eV or more.

In an embodiment, the HOMO energy absolute value of the second amine compound may be 5.20 eV or more.

In an embodiment, the first optical auxiliary layer and the second optical auxiliary layer may be in contact with each other.

In an embodiment, the first electrode may be an anode, the second electrode may be a cathode, the organic photodetector may further include a hole transport region arranged between the optical auxiliary layer and the first electrode, and the hole transport region may include a hole injection layer, a hole transport layer, an electron blocking layer, or any combination thereof.

In an embodiment, the first electrode may be an anode, the second electrode may be a cathode, the organic photodetector may further include an electron transport region arranged between the activation layer and the second electrode, and the electron transport region may include a buffer layer, a hole blocking layer, an electron transport layer, an electron injection layer, or any combination thereof.

In an embodiment, the p-type semiconductor compound may include boron subphthalocyanine chloride (SubPc), copper(II)phthalocyanine (CuPc), tetraphenyldibenzoperiflanthene (DBP), a compound represented by Formula 1, or any combination thereof.

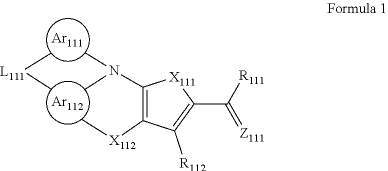

In Formula 1,
Ar₁₁₁ and Ar₁₁₂ may each independently be a C₆-C₃₀ arylene group that is unsubstituted or substituted with at least one R₁₀ₐ or a C₃-C₃₀ heteroarylene group that is unsubstituted or substituted with at least one R₁₀ₐ,
X₁₁₁ may be selected from —Se—, —Te—, —S(═O)—, —S(═O)₂—, —N(Q₁₁₁)-, —B(Q₁₁₁)-, —C(Q₁₁₁)(Q₁₁₂)-, —Si(Q₁₁₁)(Q₁₁₂)-, and —Ge(Q₁₁₁)(Q₁₁₂)-,
X₁₁₂ and L₁₁₁ may each independently be selected from —O—, —S—, —Se—, —Te—, —S(═O)—, —S(═O)₂—, —N(Q₁₁₁)-, —B(Q₁₁₁)-, —C(Q₁₁₁)(Q₁₁₂)-, —Si(Q₁₁₁)(Q₁₁₂)-, —Ge(Q₁₁₁)(Q₁₁₂)-, —(C(Q₁₁₁)=C(Q₁₁₂))-, and —(C(Q₁₁₁)=N))-,
when L₁₁₁ is selected from —N(Q₁₁₁)-, —B(Q₁₁₁)-, —C(Q₁₁₁)(Q₁₁₂)-, —Si(Q₁₁₁)(Q₁₁₂)-, —Ge(Q₁₁₁)(Q₁₁₂)-, —(C(Q₁₁₁)=C(Q₁₁₂))-, and —(C(Q₁₁₁)=N))—, L₁₁₁ may optionally be linked to Ar₁₁₁ or Ar₁₁₂ to form a condensed ring,
Z₁₁₁ may be a C₆-C₃₀ carbocyclic group that is unsubstituted or substituted with at least one R₁₀ₐ and may have at least one functional group selected from C═O, C═S, C═Se, and C═Te, or a C₁-C₃₀ heterocyclic group that is unsubstituted or substituted with at least one R₁₀ₐ and may have at least one functional group selected from C═O, C═S, C═Se, and C═Te,
R₁₁₁ to R₁₁₆ may each independently be hydrogen, deuterium, a halogen, a cyano group, a nitro group, a hydroxy group, a C₁-C₃₀ alkyl group that is unsubstituted or substituted with at least one R₁₀ₐ, a C₁-C₃₀ alkoxy group that is unsubstituted or substituted with at least one R₁₀ₐ, a C₆-C₃₀ aryl group that is unsubstituted or substituted with at least one R₁₀ₐ, a C₃-C₃₀ heteroaryl group that is unsubstituted or substituted with at least one R₁₀ₐ, a C₂-C₃₀ acyl group that is unsubstituted or substituted with at least one R₁₀ₐ, or any combination thereof,
R₁₀ₐ may be
deuterium, —F, —Cl, —Br, —I, a hydroxyl group, a cyano group, or a nitro group, a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof,
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, or a C₁-C₆₀ heteroarylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof, or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁₁ to Q₁₃, Q₂₁ to Q₂₃, Q₃₁ to Q₃₂, Q₁₁₁, and Q₁₁₂ may each independently be hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, or a C₃-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment, Z₁₁₁ in Formula 1 may be represented by one of Formulae 111A to 111F.

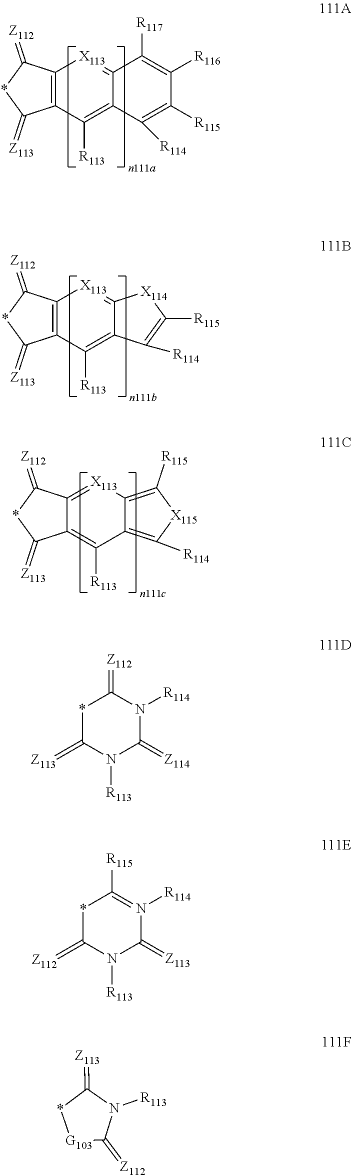

In Formulae 111A to 111F,
Z₁₁₂ to Z₁₁₄ may each independently be O, S, Se, or Te,
X₁₁₃ may be N or C(Q₁₁₃),
X₁₁₄ and X₁₁₅ may each independently be O, S, Se, Te, Si(Q₁₁₁)(Q₁₁₂), or Ge(Q₁₁₁)(Q₁₁₂),
n₁₁₁ₐ to n_{111c} may each independently be an integer from 0 to 3,
R₁₁₃ to R₁₁₇ may each independently be hydrogen, deuterium, a halogen, a cyano group, a nitro group, a hydroxy group, a C₁-C₃₀ alkyl group that is unsubstituted or substituted with at least one R₁₀ₐ, a C₆-C₃₀ aryl group that is unsubstituted or substituted with at least one R₁₀ₐ, a C₃-C₃₀ heteroaryl group that is unsubstituted or substituted with at least one R₁₀ₐ, or any combination thereof, and
Q₁₁₁ to Q₁₁₃ may each be the same as described in connection with Q₁₁₁.

In an embodiment, the n-type semiconductor compound may include C60 fullerene, C70 fullerene, a compound represented by Formula 2, a compound represented by Formula 3, or any combination thereof.

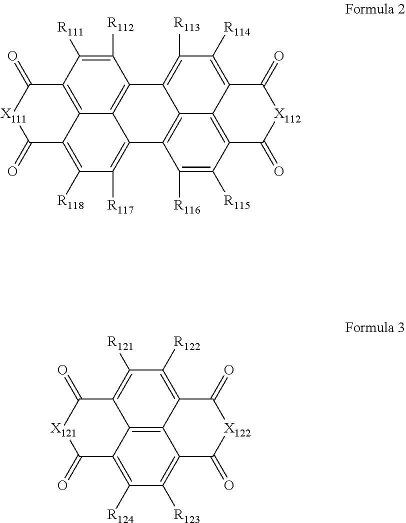

In Formula 2,
X₁₁₁ and X₁₁₂ may each independently be O or NR₁₁₉, and
R₁₁₁ to R₁₁₉ may each independently be hydrogen, deuterium, a halogen, a cyano group, a nitro group, a hydroxy group, a C₁-C₃₀ alkyl group that is unsubstituted or substituted with at least one R₁₀ₐ, a C₆-C₃₀ aryl group that is unsubstituted or substituted with at least one R₁₀ₐ, a C₃-C₃₀ heteroaryl group that is unsubstituted or substituted with at least one R₁₀ₐ, or any combination thereof,
in Formula 3,
X₁₂₁ and X₁₂₂ may each independently be O or NR₁₂₅, and
R₁₂₁ to R₁₂₅ may each independently be hydrogen, deuterium, a halogen, a cyano group, a nitro group, a hydroxy group, a C₁-C₃₀ alkyl group that is unsubstituted or substituted with at least one R₁₀ₐ, a C₆-C₃₀ aryl group that is unsubstituted or substituted with at least one R₁₀ₐ, a C₃-C₃₀ heteroaryl group that is unsubstituted or substituted with at least one R₁₀ₐ, or any combination thereof,
in Formulae 2 and 3,
R₁₀ₐ may be
deuterium, —F, —Cl, —Br, —I, a hydroxyl group, a cyano group, or a nitro group, a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof,
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, or a C₁-C₆₀ heteroarylthio group, each unsubstituted or substituted with deuterium, —F, —CI, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof, or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁₁ to Q₁₃, Q₂₁ to Q₂₃, Q₃₁, and Q₃₂ may each independently be hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment, each of the compound represented by Formula 2 and the compound represented by Formula 3 may include one of compounds.

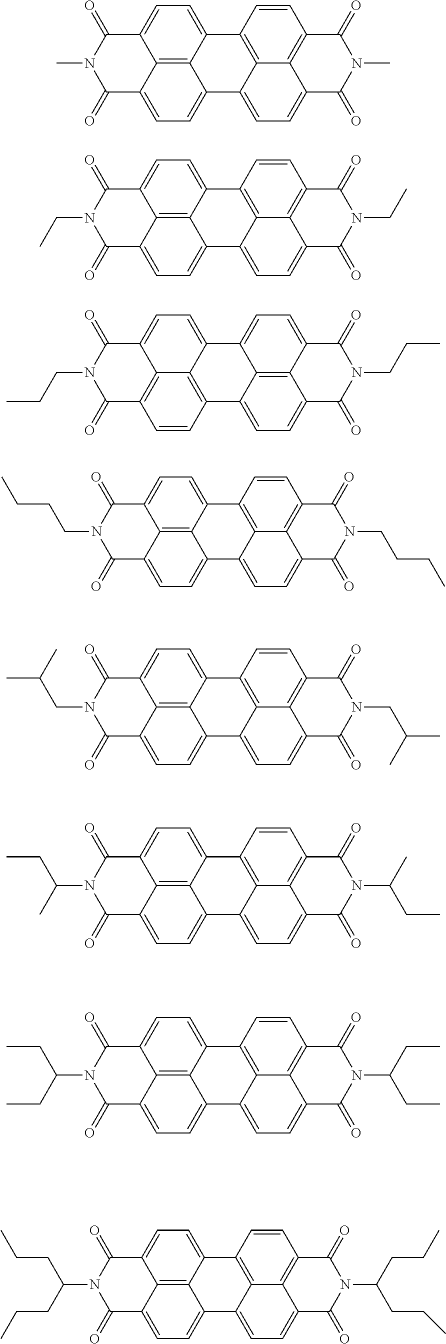

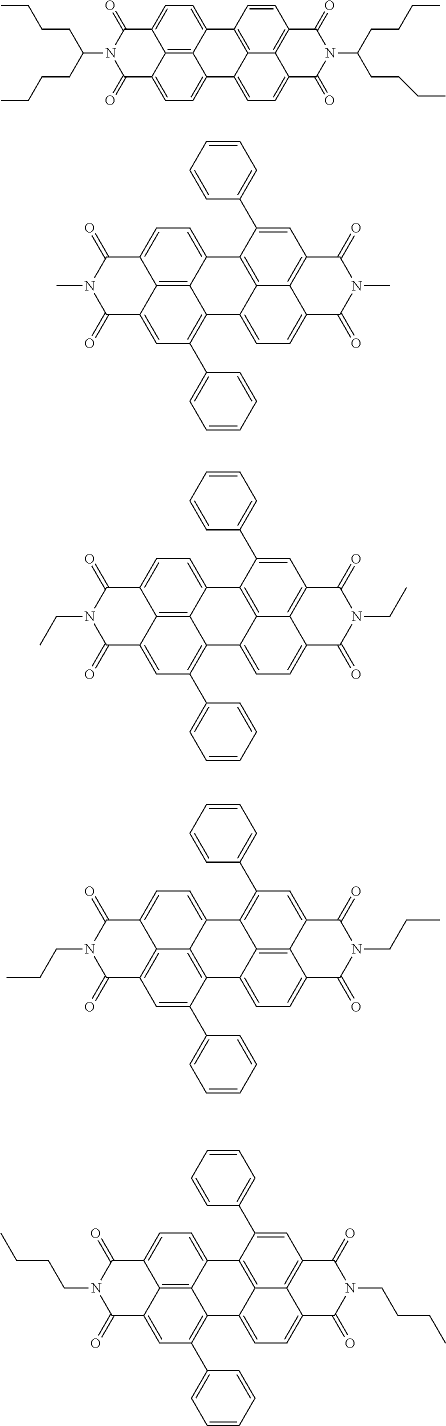

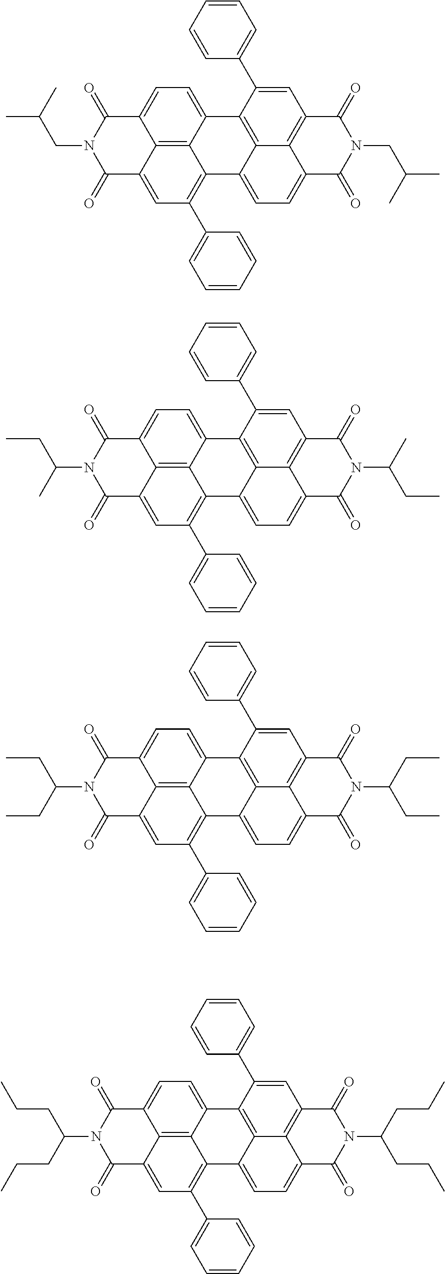

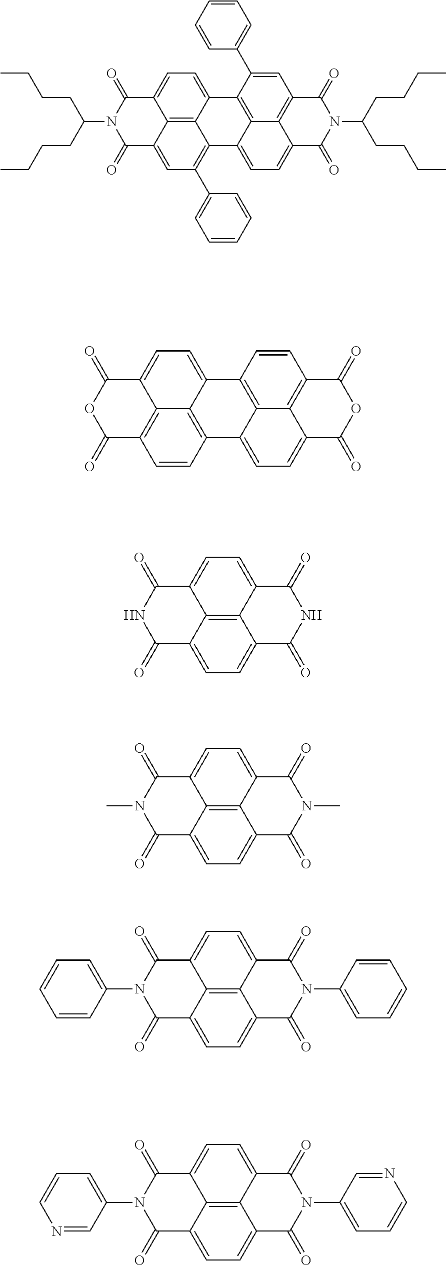

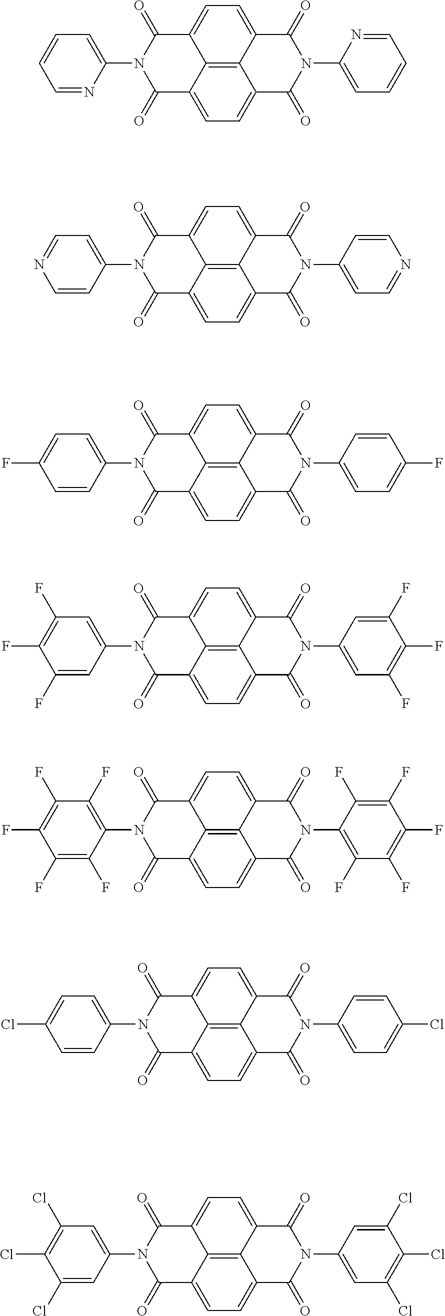

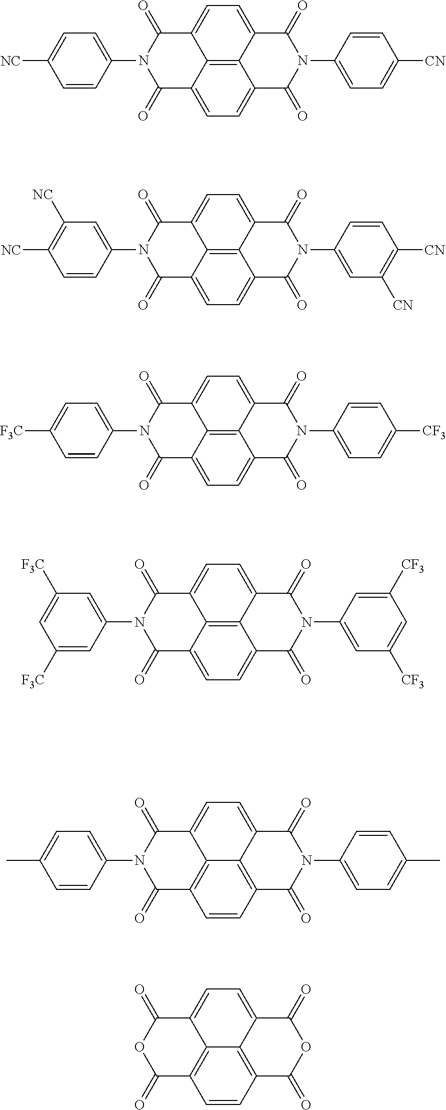

In an embodiment, the first amine compound may be a tertiary amine compound including one or two fluorene moieties, and at least one aryl moiety.

In an embodiment, the second amine compound may be a tertiary amine compound including three fluorene moieties.

In an embodiment, the first amine compound may include one of compounds.

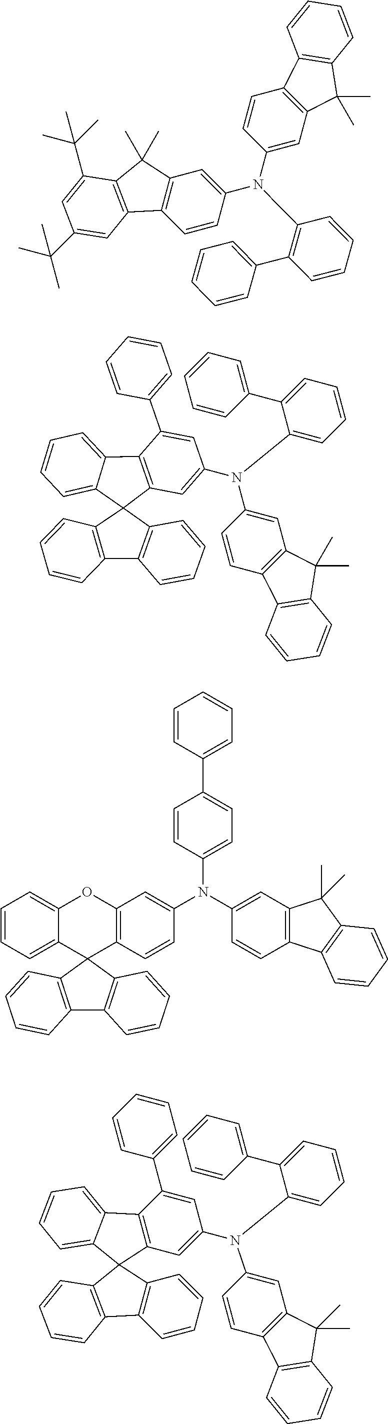 [SMILES: CC(C)(C)c1cc2c(c(C(C)(C)C)c1)C(C)(C)c1cc(N(c3ccc4c(c3)C(C)(C)c3ccccc3-4)c3ccccc3-c3ccccc3)ccc1-2 ; CC1(C)c2ccccc2-c2ccc(N(c3cc(-c4ccccc4)c4c(c3)C3(c5ccccc5-c5ccccc53)c3ccccc3-4)c3ccccc3-c3ccccc3)cc21 ; CC1(C)c2ccccc2-c2ccc(N(c3ccc(-c4ccccc4)cc3)c3ccc4c(c3)Oc3ccccc3C43c4ccccc4-c4ccccc43)cc21 ; CC1(C)c2ccccc2-c2ccc(N(c3cc(-c4ccccc4)c4c(c3)C3(c5ccccc5-c5ccccc53)c3ccccc3-4)c3ccccc3-c3ccccc3)cc21]

In an embodiment, the second amine compound may include one of compounds.

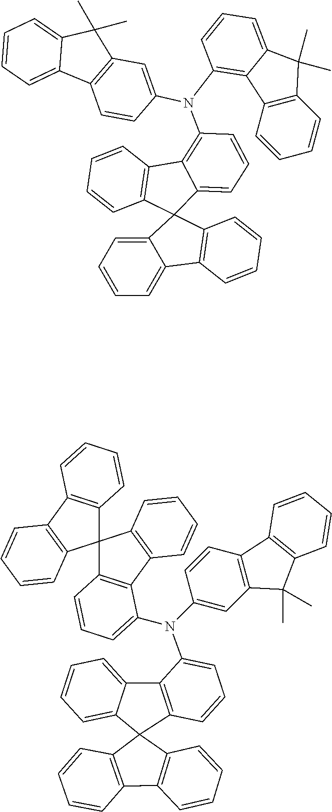 [SMILES: CC1(C)c2ccccc2-c2ccc(N(c3cccc4c3-c3ccccc3C4(C)C)c3cccc4c3-c3ccccc3C43c4ccccc4-c4ccccc43)cc21 ; CC1(C)c2ccccc2-c2ccc(N(c3cccc4c3-c3ccccc3C43c4ccccc4-c4ccccc43)c3cccc4c3-c3ccccc3C43c4ccccc4-c4ccccc43)cc21]

According to one or more embodiments, there is provided an electronic apparatus including the organic photodetector.

In an embodiment, the electronic apparatus may further include a light-emitting device.

According to one or more embodiments, an electronic apparatus includes a substrate including a photodetection area and an emission area,
an organic photodetector disposed on the photodetection area, and
a light-emitting device disposed on the emission area,
wherein the organic photodetector includes a first pixel electrode, an opposite electrode facing the first pixel electrode, and a hole transport layer, an optical auxiliary layer, and an activation layer, sequentially arranged between the first pixel electrode and the opposite electrode, the activation layer includes a p-type semiconductor compound and an n-type semiconductor compound, the optical auxiliary layer includes a first optical auxiliary layer including a first amine compound and a second optical auxiliary layer including a second amine compound, a highest occupied molecular orbital (HOMO) energy absolute value of the first amine compound is smaller than a HOMO energy absolute value of the second amine compound, and the first optical auxiliary layer faces the first pixel electrode,
the light-emitting device includes a second pixel electrode, the opposite electrode facing the second pixel electrode, and the hole transport layer, the optical auxiliary layer, and an emission layer, sequentially arranged between the second pixel electrode and the opposite electrode,
the first pixel electrode and the activation layer are arranged in correspondence with the photodetection area,
the second pixel electrode and the emission layer are arranged in correspondence with the emission area, and
the hole transport layer, the optical auxiliary layer, and the opposite electrode are arranged throughout the photodetection area and the emission area.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic view of a structure of an organic photodetector according to an embodiment;

FIGS. 2 and 3 are schematic views of a structure of an electronic apparatus according to an embodiment; and

FIGS. 4A and 4B are diagrams illustrating an electronic apparatus according to an embodiment.

### DETAILED DESCRIPTION

Reference will now be made in more detail to embodiments, examples of which are illustrated in the accompanying drawings, wherein like reference numerals refer to like elements throughout, and duplicative descriptions thereof may not be provided the specification. In this regard, the present embodiments may have different forms and should not be construed as being limited to the descriptions set forth herein. Accordingly, the embodiments are merely described, by referring to the drawings, to explain aspects of the present description. any Further, the use of “may” when describing embodiments of the inventive concept refers to “one or more embodiments of the present disclosure.”

As utilized herein, the term “and/or” includes anynd all combinations of one or more of the associated listed items. Throughout the disclosure, the expression “at least one of a, b or c”, “at least one of a-c”, “at least one of a to c”, “at least one of a, b, and/or c”, etc., indicates only a, only b, only c, both (e.g., simultaneously) a and b, both (e.g., simultaneously) a and c, both (e.g., simultaneously) b and c, all of a, b, and c, or variations thereof.

In the present specification, “including A or B”, “A and/or B”, etc., represents A or B, or A and B.

Spatially relative terms, such as “beneath”, “below”, “lower”, “downward”, “above”, “upper”, “left”, “right”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

Unless explicitly described to the contrary, the word “comprise”, and variations such as “comprises” or “comprising”, will be understood to imply the inclusion of stated elements but not the exclusion of any other elements.

As used herein, the term “substantially,” “about,” and similar terms are used as terms of approximation and not as terms of degree, and are intended to account for the inherent deviations in measured or calculated values that would be recognized by those of ordinary skill in the art. “About” or “substantially”, as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” or “substantially” may mean within one or more standard deviations, or within ±30%, 20%, 10%, 5% of the stated value.

Depending on context, a divalent group may refer or be a polyvalent group (e.g., trivalent, tetravalent, etc., and not just divalent) per, e.g., the structure of a formula in connection with which of the terms are utilized.

The disclosure may include one or more suitable modifications and one or more suitable embodiments, and specific embodiments will be illustrated in the drawings and described in more detail in the detailed description. Effects and features of the disclosure, and methods of achieving the same will be clarified by referring to embodiments described in more detail later with reference to the drawings. The disclosure may, however, be embodied in many different forms and should not be construed as limited to the embodiments set forth herein.

As utilized herein, the singular forms “a,” “an” and “the” are intended to include the plural forms as well, unless the context clearly indicates otherwise.

As utilized herein, the terms “comprise”, “include”, “have”, and/or the like, specify the presence of stated features and/or elements, and do not exclude the presence of addition of one or more other features and/or elements.

It will be understood that when a layer, region, or element is referred to as being “on” or “onto” another layer, region, or element, it may be directly or indirectly formed over the other layer, region, or element. For example, for example, intervening layers, regions, or elements may be present.

Like reference numerals in the drawings denote like elements, and thus their description will not be provided.

Sizes of elements in the drawings may be exaggerated for convenience of explanation. In other words, the sizes and thicknesses of elements are arbitrarily illustrated in the drawings for the convenience of explanation, and the disclosure is not limited thereto.

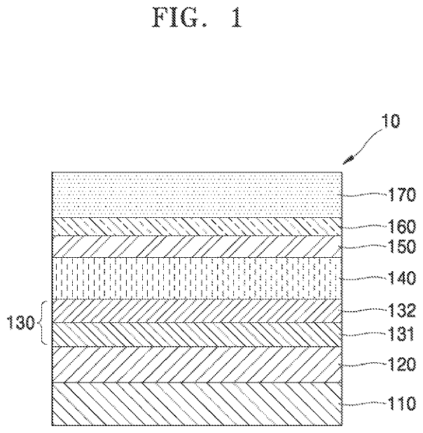

### Description of FIG. 1

FIG. 1 is a schematic cross-sectional view of an organic photodetector 10 according to an embodiment.

Referring to FIG. 1, the organic photodetector 10 according to an embodiment may include: a first electrode 110; a second electrode 170 facing the first electrode 110; an activation layer 140 arranged between the first electrode 110 and the second electrode 170; an electron injection layer, an electron transport layer 160, and a buffer layer 150, which are arranged between the activation layer 140 and the second electrode 170; and a hole injection layer, a hole transport layer 120, and an optical auxiliary layer 130, which are arranged between the first electrode 110 and the activation layer 140. The optical auxiliary layer 130 may include a first optical auxiliary layer 131 and a second optical auxiliary layer 132.

The activation layer 140 generates excitons by receiving light from the outside and divides the generated excitons into holes and electrons. The activation layer 140 may include a p-type semiconductor (e.g., p-semiconductor) compound and an n-type semiconductor (e.g., n-semiconductor) compound.

The first optical auxiliary layer 131 faces the first electrode 110. In other words, the first electrode 110 is closer to the first optical auxiliary layer 131 among the first optical auxiliary layer 131 and the second optical auxiliary layer 132 (e.g., the first electrode 110 is closer to the first optical auxiliary layer 131 than to the second optical auxiliary layer 132).

The optical auxiliary layer 130 may compensate for an optical resonance distance according to a wavelength of light introduced to the activation layer 140 to increase light introduction efficiency.

For example, a total thickness of the optical auxiliary layer 130 may be about 100 Å to about 500 Å, and a thickness of the first optical auxiliary layer 131 and a thickness of the second optical auxiliary layer 132 may each independently be 10 Å to 490 Å. When the thickness of the optical auxiliary layer 130 is within the range described above, the thickness may be appropriate or suitable as a resonance thickness.

In FIG. 1, for example, in some cases, the electron injection layer, the buffer layer 150, and the hole injection layer may each independently exist or not exist.

The activation layer 140 may include a p-type semiconductor compound and an n-type semiconductor compound. For example, the activation layer 140 may be a mixed layer including the p-type semiconductor compound and the n-type semiconductor compound, or may include a layer including the p-type semiconductor compound and a layer including the n-type semiconductor compound.

The layer including the p-type semiconductor compound and the layer including the n-type semiconductor compound may form a PN junction. Excitons may be efficiently separated into holes and electrons by photo-induced charge separation occurring at an interface between these layers.

When the activation layer 140 is a mixed layer, excitons may be generated within a diffusion distance from a p-type semiconductor compound-n-type semiconductor compound interface, and thus, the organic photodetector 10 may have improved efficiency. A ratio of the p-type semiconductor compound-n-type semiconductor compound may be, for example, 10:90 to 90:10 (weight ratio).

For example, the activation layer 140 may be a mixed layer consisting of the p-type semiconductor compound and the n-type semiconductor compound. For example, the activation layer 140 may include (e.g., consist of) a layer consisting of the p-type semiconductor compound and a layer consisting of the n-type semiconductor compound.

In an embodiment, the activation layer 140 and the optical auxiliary layer 130 may be in direct contact with each other. For example, the activation layer 140 and the second optical auxiliary layer 132 may be in direct contact with each other.

When the activation layer 140 includes a layer including the p-type or kind semiconductor compound and a layer including the n-type semiconductor compound, the layer including the p-type semiconductor compound may be in direct contact with the second optical auxiliary layer 132.

A total thickness of the activation layer 140 may be about 200 Å to about 2,000 Å, for example, about 400 Å to about 600 Å. When the activation layer 140 includes a layer including the p-type semiconductor compound and a layer including the n-type semiconductor compound, a thickness of the layer including the p-type semiconductor compound and a thickness of the layer including the n-type semiconductor compound may each independently be about 50 Å to about 1,000 Å, for example, about 100 Å to about 400 Å.

When the thickness of the activation layer 140 is within the range described above, absorption of incident light may be efficient, and for example, absorption of green light may be efficient. A wavelength of the green light may be, for example, about 490 nm to about 560 nm.

For example, the first optical auxiliary layer 131 may include (e.g., consist of) a first amine compound, and the second optical auxiliary layer 132 may include (e.g., consist of) a second amine compound.

In the organic photodetector 10 according to an embodiment, when a HOMO energy absolute value of the first amine compound of the first optical auxiliary layer 131 is smaller than a HOMO energy absolute value of the second amine compound of the second optical auxiliary layer 132, and the first optical auxiliary layer 131 faces the first electrode 110, energy barrier may be reduced, and efficiency may increase.

In an embodiment, the HOMO energy absolute value of the first amine compound may be 5.00 eV or more.

In an embodiment, the HOMO energy absolute value of the second amine compound may be 5.20 eV or more.

In an embodiment, the first optical auxiliary layer 131 and the second optical auxiliary layer 132 may be in direct contact with each other.

One of the first electrode 110 and the second electrode 170 may be an anode, and the other one may be a cathode. For example, the first electrode 110 may be an anode, and the second electrode 170 may be a cathode.

A hole transport region of the organic photodetector 10 may include a structure in which a hole injection layer, the hole transport layer 120, an electron blocking layer, or any combination thereof is disposed above the first electrode 110. For example, the hole injection layer may be arranged between the first electrode 110 and the hole transport layer 120.

For example, the hole transport layer 120 may include a layer including a p-dopant. The layer including the p-dopant may be in direct contact with the first electrode 110.

For example, a HOMO energy absolute value of the electron transport layer 160 may be smaller than a HOMO energy absolute value of the first amine compound.

The p-dopant will be described.

An electron transport region of the organic photodetector 10 may include a structure in which the buffer layer 150, a hole blocking layer, the electron transport layer 160, an electron injection layer, or any combination thereof is arranged above the activation layer 140. For example, the electron injection layer may be arranged between the second electrode 170 and the electron transport layer 160.

In an embodiment, the p-type semiconductor compound may include boron subphthalocyanine chloride (SubPc), copper(II)phthalocyanine (CuPc), tetraphenyldibenzoperiflanthene (DBP), a compound represented by Formula 1, or any combination thereof:

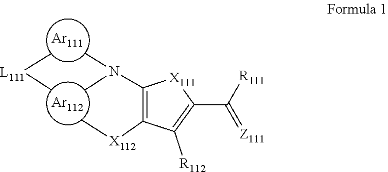

wherein, in Formula 1,
Ar₁₁₁ and Ar₁₁₂ may each independently be a C₆-C₃₀ arylene group that is unsubstituted or substituted with at least one R₁₀ₐ or a C₃-C₃₀ heteroarylene group that is unsubstituted or substituted with at least one R₁₀ₐ,
X₁₁₁ may be selected from —Se—, —Te—, —S(═O)—, —S(═O)₂—, —N(Q₁₁₁)-, —B(Q₁₁₁)-, —C(Q₁₁₁)(Q₁₁₂)-, —Si(Q₁₁₁)(Q₁₁₂)-, and —Ge(Q₁₁₁)(Q₁₁₂)-,
X₁₁₂ and L₁₁₁ may each independently be selected from —O—, —S—, —Se—, —Te—, —S(═O)—, —S(═O)₂—, —N(Q₁₁₁)-, —B(Q₁₁₁)-, —C(Q₁₁₁)(Q₁₁₂)-, —Si(Q₁₁₁)(Q₁₁₂)-, —Ge(Q₁₁₁)(Q₁₁₂)-, —(C(Q₁₁₁)=C(Q₁₁₂)-, and —(C(Q₁₁₁)=N)—,
when L₁₁₁ is selected from —N(Q₁₁₁)-, —B(Q₁₁₁)-, —C(Q₁₁₁)(Q₁₁₂)-, —Si(Q₁₁₁)(Q₁₁₂)-, —Ge(Q₁₁₁)(Q₁₁₂)-, —(C(Q₁₁₁)=C(Q₁₁₂)-, and —(C(Q₁₁₁)=N))—, L₁₁₁ may optionally be linked to Ar₁₁₁ or Ar₁₁₂ to form a condensed ring,
Z₁₁₁ may be a C₆-C₃₀ carbocyclic group that is unsubstituted or substituted with at least one R₁₀ₐ and may have at least one functional group selected from C═O, C═S, C═Se, and C=Te, or a C₁-C₃₀ heterocyclic group that is unsubstituted or substituted with at least one R₁₀ₐ and may have at least one functional group selected from C═O, C═S, C═Se, and C═Te,
R₁₁₁ to R₁₁₆ may each independently be hydrogen, deuterium, a halogen, a cyano group, a nitro group, a hydroxy group, a C₁-C₃₀ alkyl group that is unsubstituted or substituted with at least one R₁₀ₐ, a C₁-C₃₀ alkoxy group that is unsubstituted or substituted with at least one R₁₀ₐ, a C₆-C₃₀ aryl group that is unsubstituted or substituted with at least one R₁₀ₐ, a C₃-C₃₀ heteroaryl group that is unsubstituted or substituted with at least one R₁₀ₐ, a C₂-C₃₀ acyl group that is unsubstituted or substituted with at least one R₁₀ₐ, or any combination thereof,
R₁₀ₐ may be:
deuterium, —F, —Cl, —Br, —I, a hydroxyl group, a cyano group, or a nitro group; a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, or a C₁-C₆₀ heteroarylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), -S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q31), —S(═O)₂(Q31), or —P(═O)(Q₃₁)(Q₃₂), and
Q₁₁ to Q_{13,} Q₂₁ to Q₂₃, Q₃₁ to Q₃₂, Q₁₁₁, and Q₁₁₂ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment, Z₁₁₁ in Formula 1 may be represented by one of Formulae 111A to 111F:

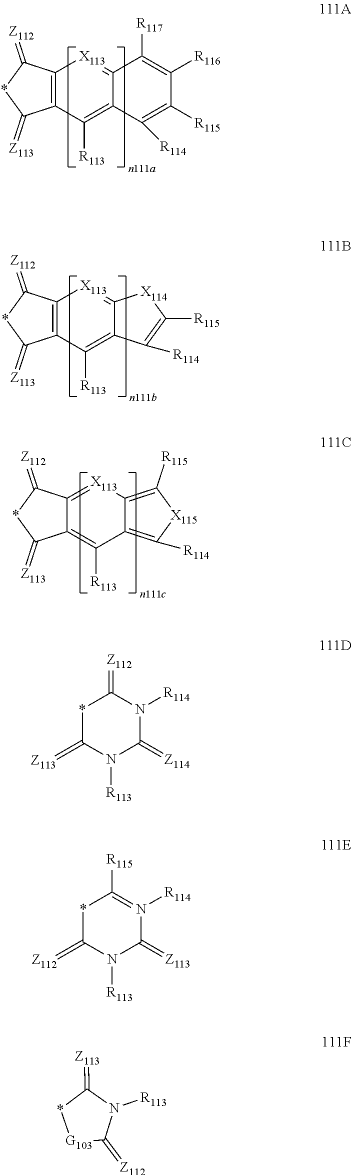

wherein, in Formulae 111A to 111F,
Z₁₁₂ to Z₁₁₄ may each independently be O, S, Se, or Te,
X₁₁₃ may be N or C(Q₁₁₃),
X₁₁₄ and X₁₁₅ may each independently be O, S, Se, Te, Si(Q₁₁₁)(Q₁₁₂), or Ge(Q₁₁₁)(Q₁₁₂),
n₁₁₁ₐ to n_{111c} may each independently be an integer from 0 to 3,
R₁₁₃ to R₁₁₇ may each independently be hydrogen, deuterium, a halogen, a cyano group, a nitro group, a hydroxy group, a C₁-C₃₀ alkyl group that is unsubstituted or substituted with at least one R₁₀ₐ, a C₆-C₃₀ aryl group that is unsubstituted or substituted with at least one R₁₀ₐ, a C₃-C₃₀ heteroaryl group that is unsubstituted or substituted with at least one R₁₀ₐ, or any combination thereof, and
Q₁₁₁ to Q₁₁₃ may each be the same as described in connection with Q₁₁₁ in Formula 1.

In an embodiment, the compound represented by Formula 1 may include one of compounds of Group 1 to Group 3:

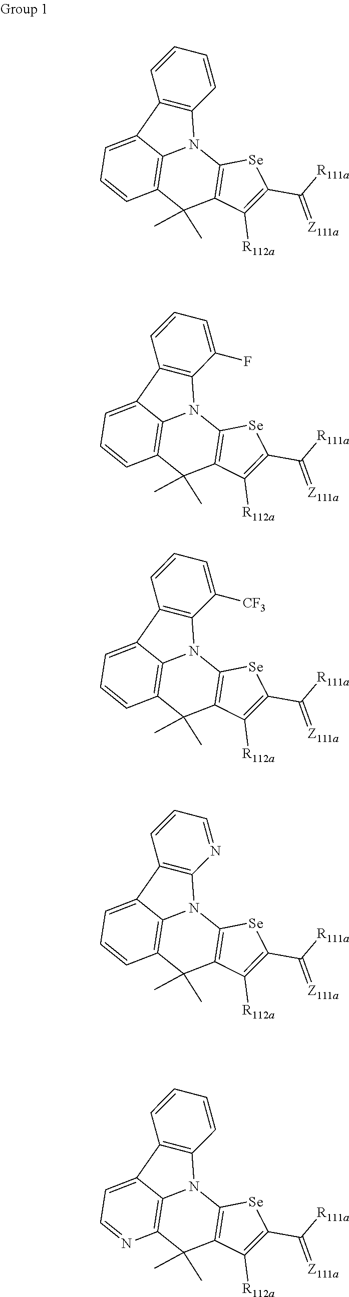

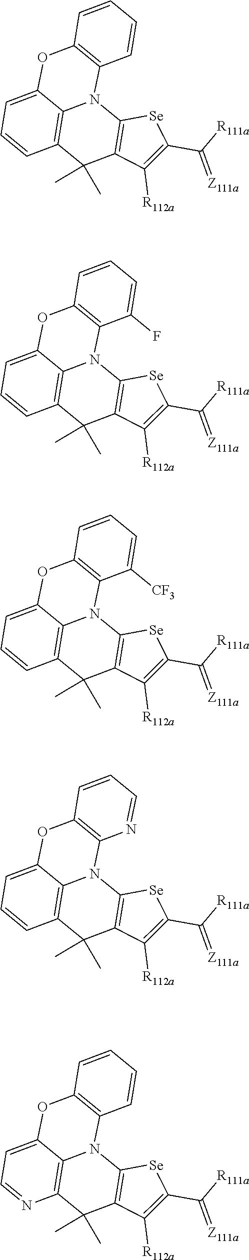

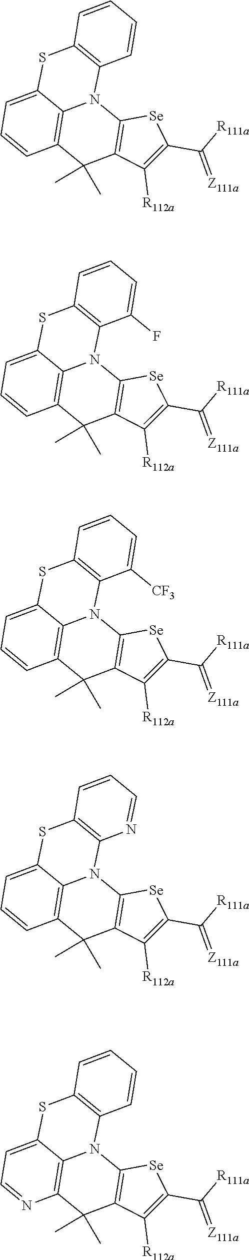

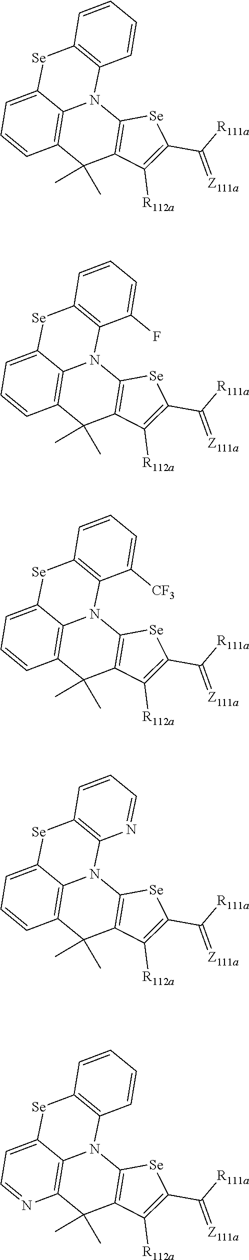

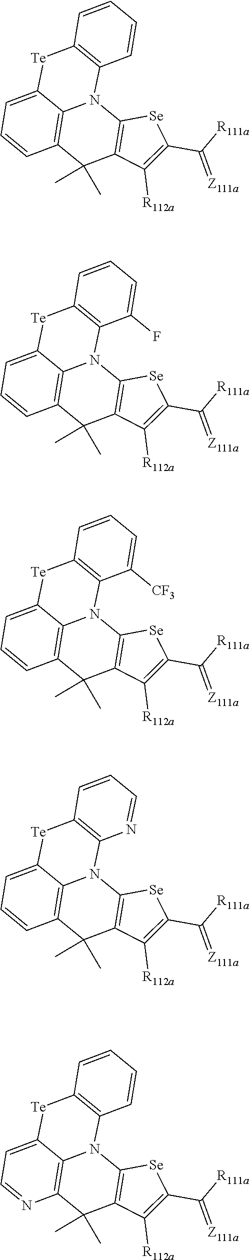

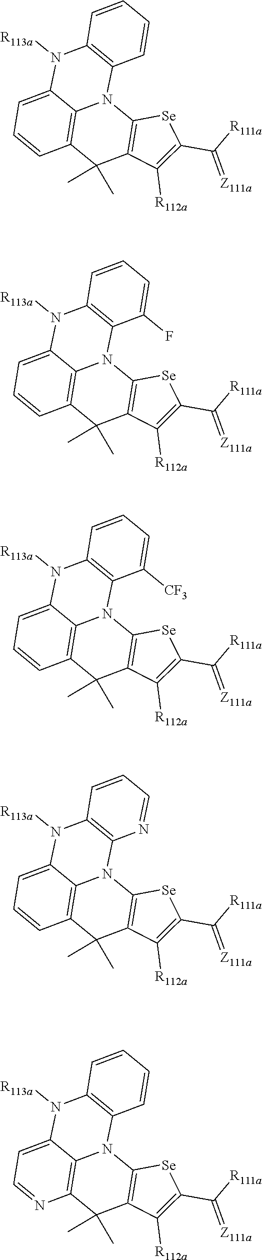

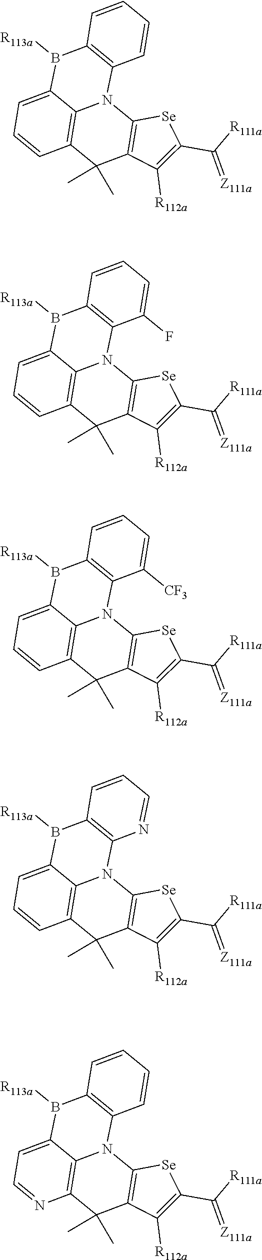

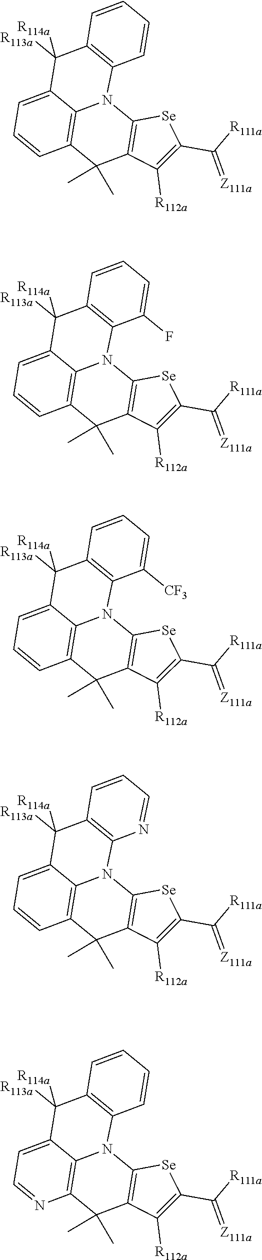

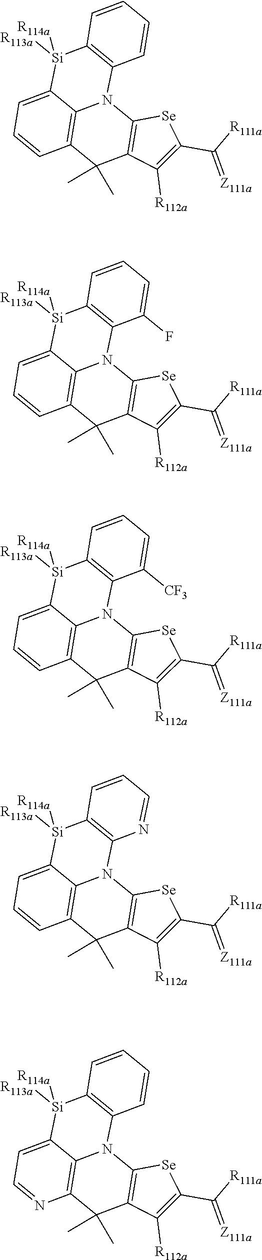

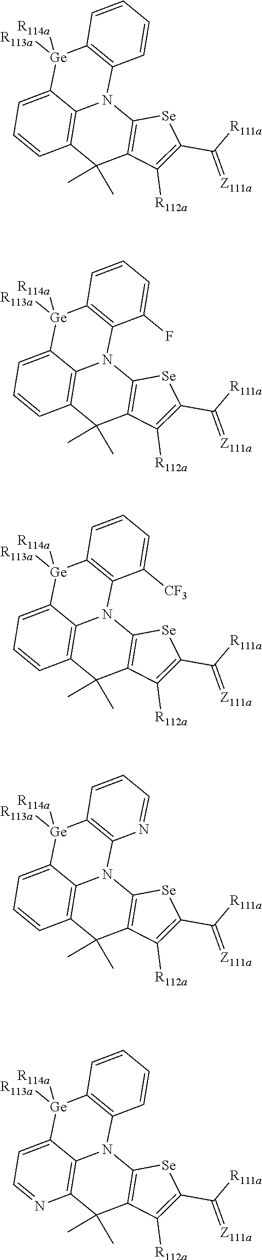

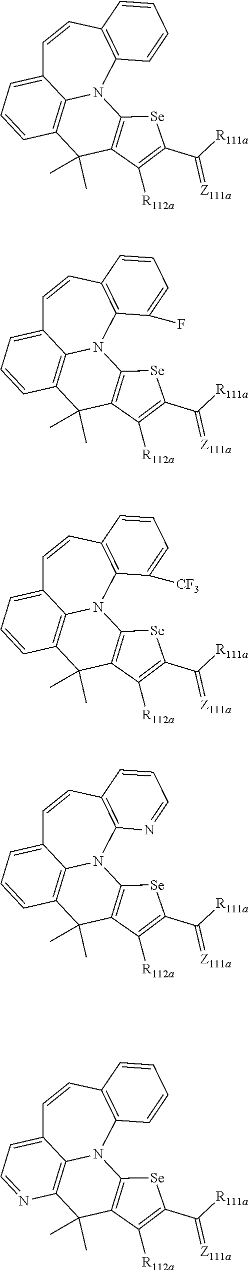

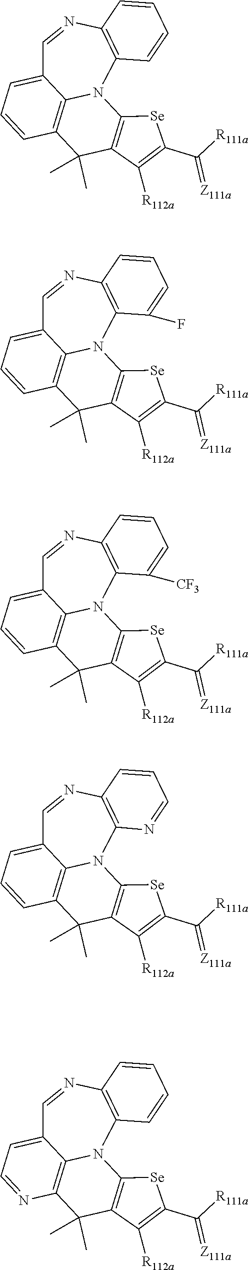

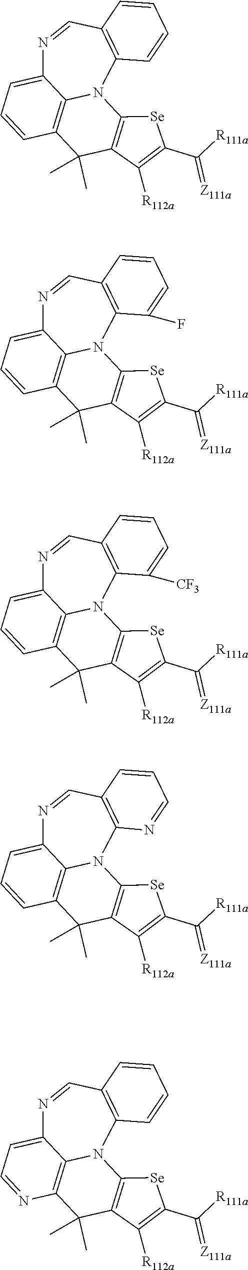

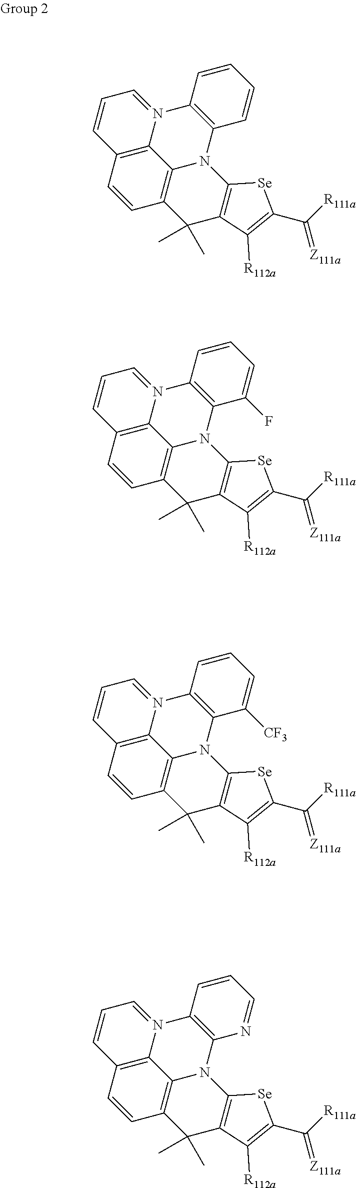

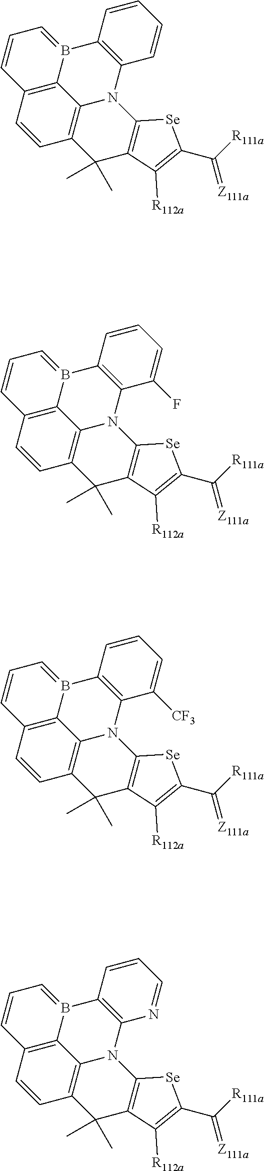

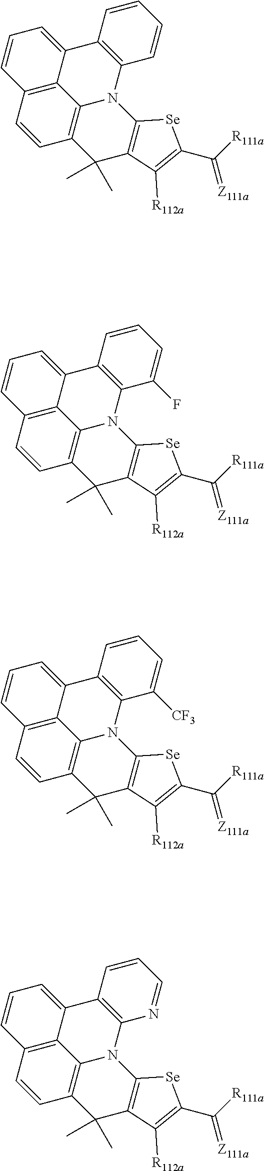

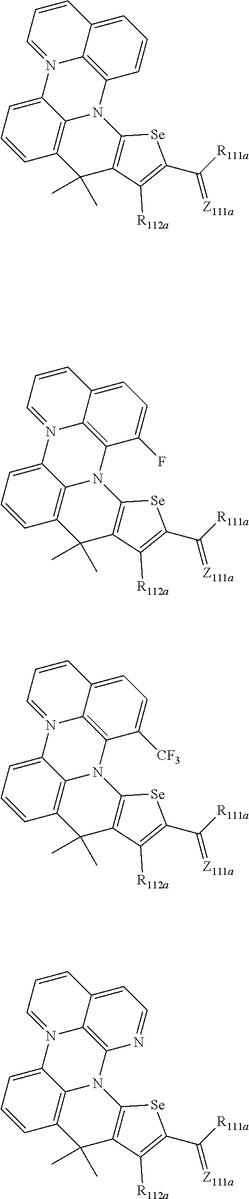

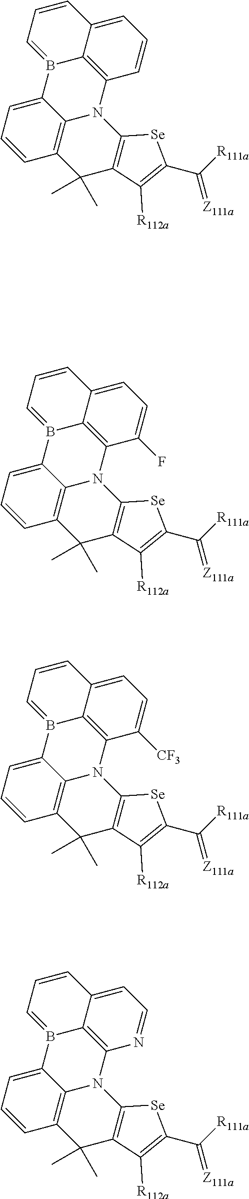

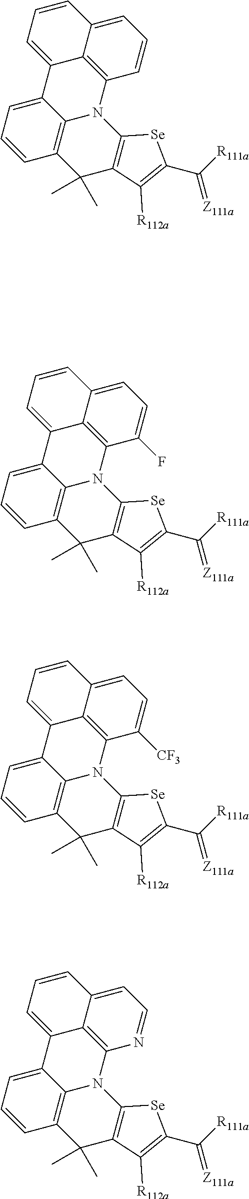

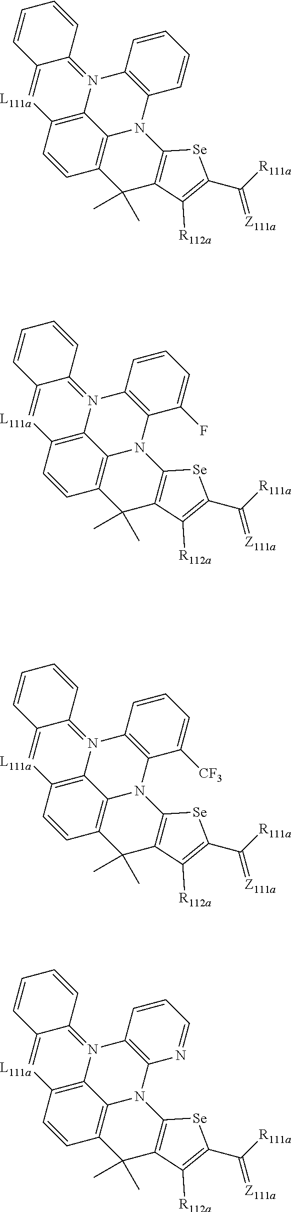

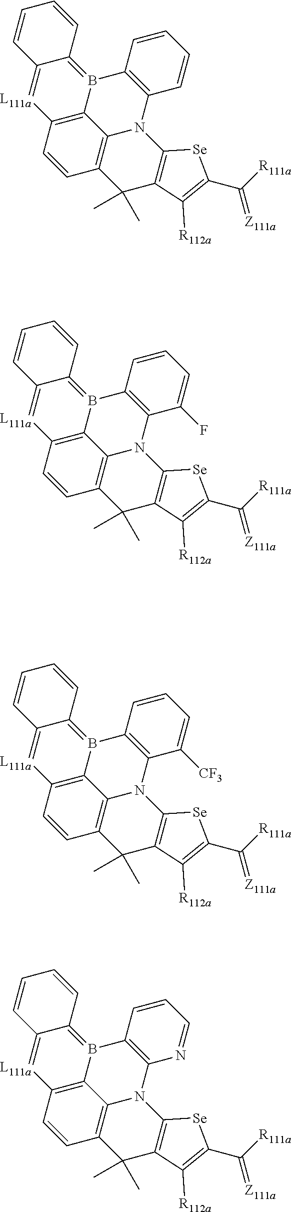

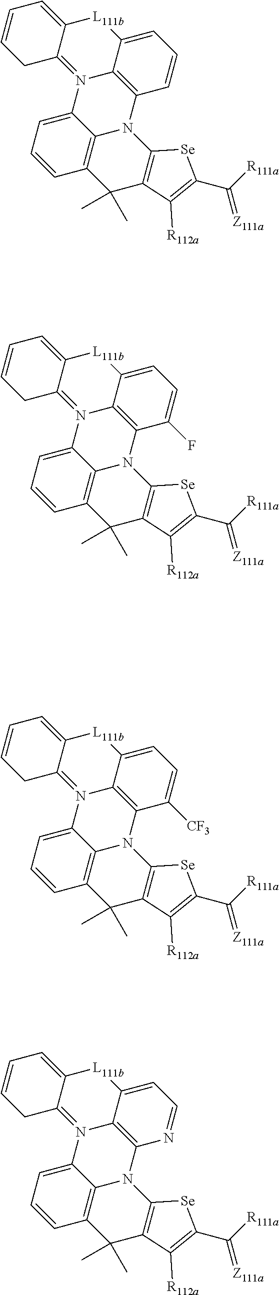

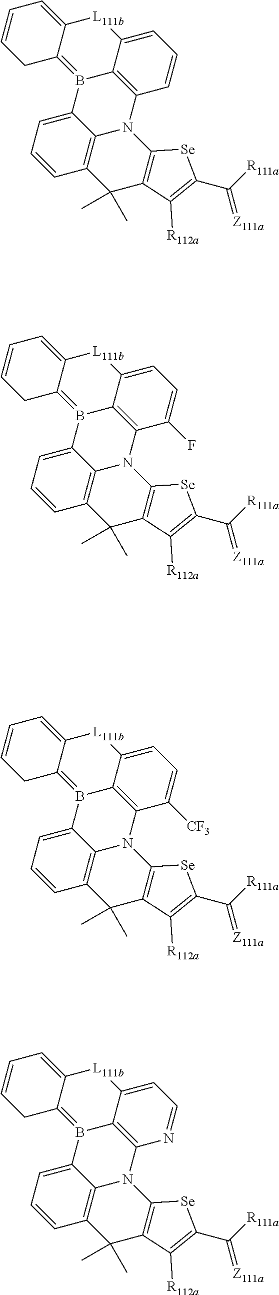

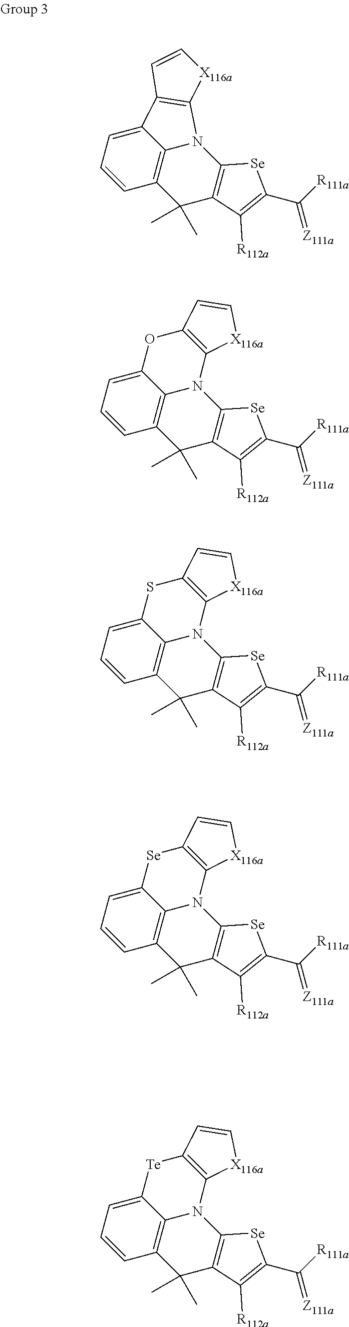

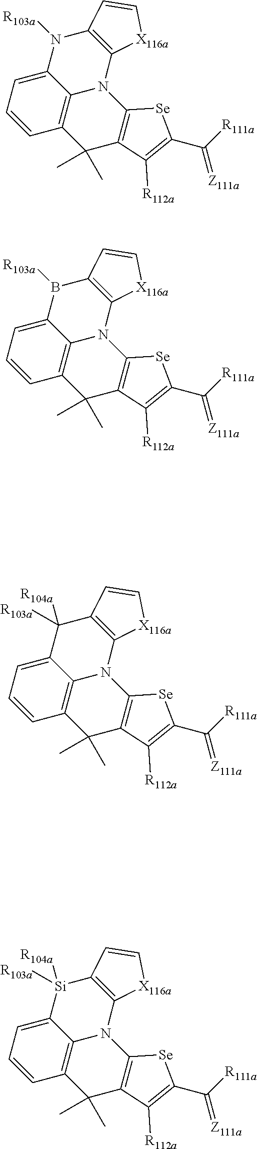

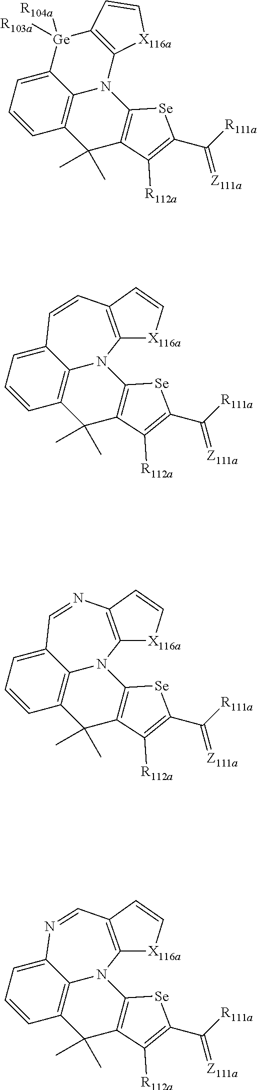

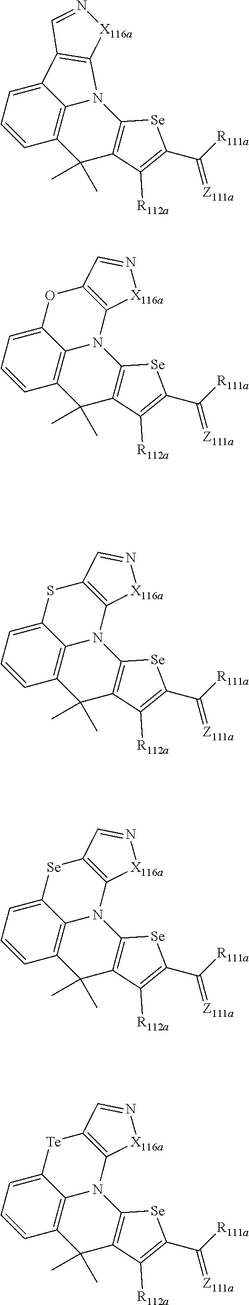

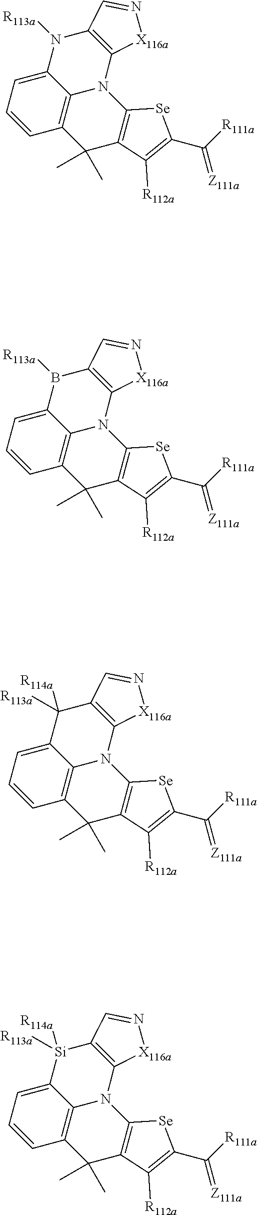

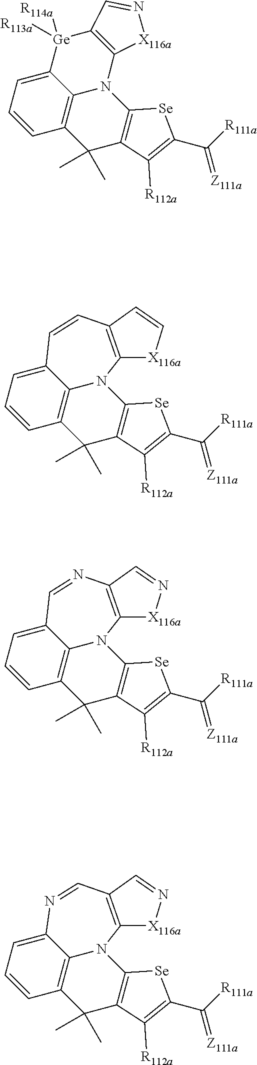

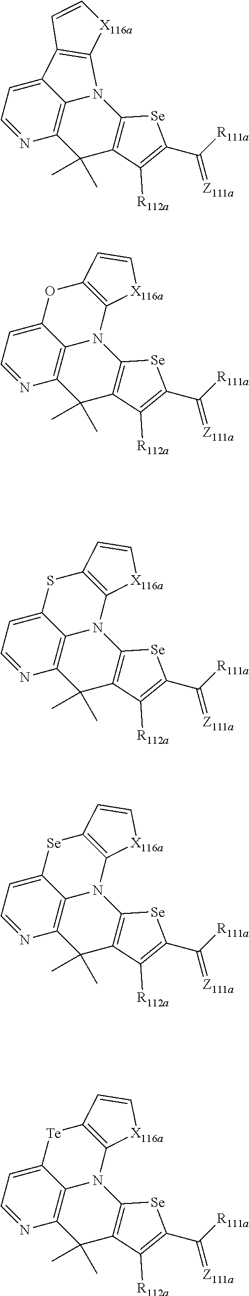

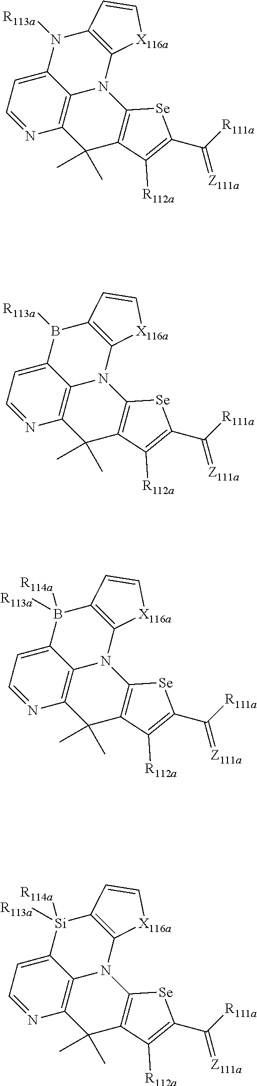

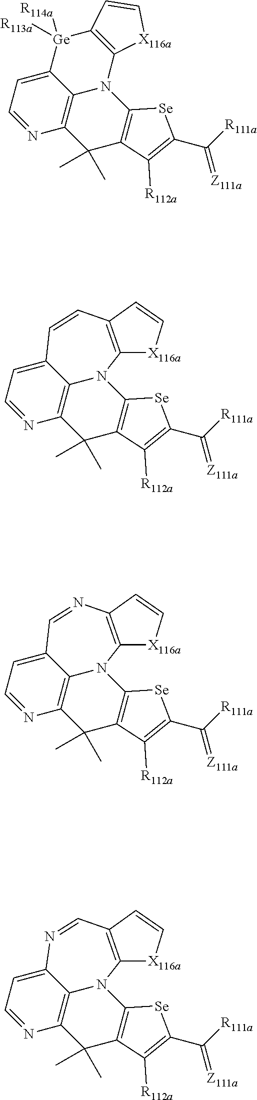

wherein, in the compounds of Group 1 to Group 3,
R₁₁₁ₐ to R₁₁₄ₐ may each be the same as described in connection with R₁₁₁ in Formula 1,
Z₁₁₁ₐ may be the same as described in connection with Z₁₁₁ in Formula 1, and
X₁₁₆ₐ may be the same as described in connection with X₁₁₁ in Formula 1.

For example, a HOMO energy absolute value of the p-type semiconductor compound may be greater than a HOMO energy absolute value of the second amine compound.

In an embodiment, the n-type semiconductor compound may include C60 fullerene, C70 fullerene, a compound represented by Formula 2, a compound represented by Formula 3, or any combination thereof:

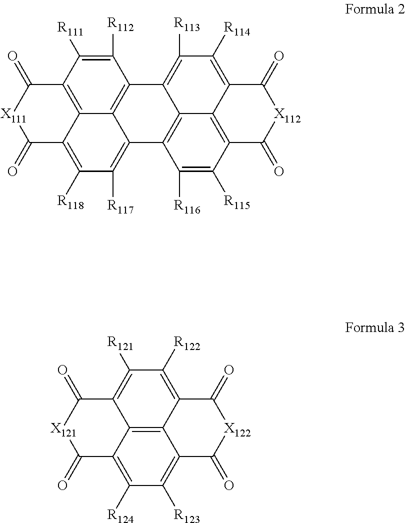

wherein, in Formula 2,
X₁₁₁ and X₁₁₂ may each independently be O or NR₁₁₉, and
R₁₁₁ to R₁₁₉ may each independently be hydrogen, deuterium, a halogen, a cyano group, a nitro group, a hydroxy group, a C₁-C₃₀ alkyl group that is unsubstituted or substituted with at least one R₁₀ₐ, a C₆-C₃₀ aryl group that is unsubstituted or substituted with at least one R₁₀ₐ, a C₃-C₃₀ heteroaryl group that is unsubstituted or substituted with at least one R₁₀ₐ, or any combination thereof,
in Formula 3,
X₁₂₁ and X₁₂₂ may each independently be O or NR₁₂₅, and
R₁₂₁ to R₁₂₅ may each independently be hydrogen, deuterium, a halogen, a cyano group, a nitro group, a hydroxy group, a C₁-C₃₀ alkyl group that is unsubstituted or substituted with at least one R₁₀ₐ, a C₆-C₃₀ aryl group that is unsubstituted or substituted with at least one R₁₀ₐ, a C₃-C₃₀ heteroaryl group that is unsubstituted or substituted with at least one R₁₀ₐ, or any combination thereof,
in Formulae 2 and 3,
R₁₀ₐ may be:
deuterium, —F, —Cl, —Br, —I, a hydroxyl group, a cyano group, or a nitro group; a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, or a C₁-C₆₀ heteroarylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁₁ to Q₁₃, Q₂₁ to Q₂₃, Q₃₁ to Q₃₂, Q₁₁₁, and Q₁₁₂ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment, each of the compound represented by Formula 2 and the compound represented by Formula 3 may include one of compounds:

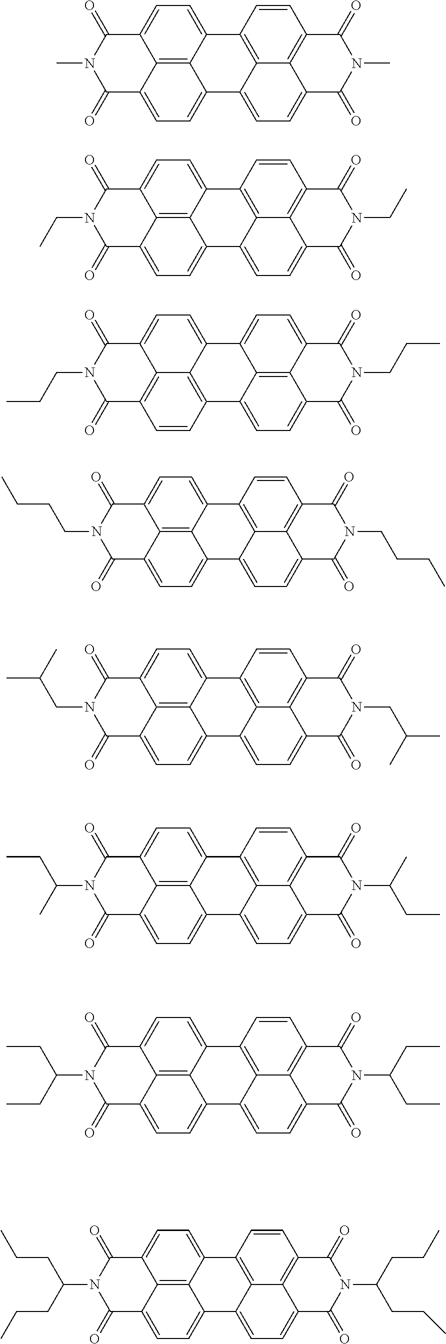

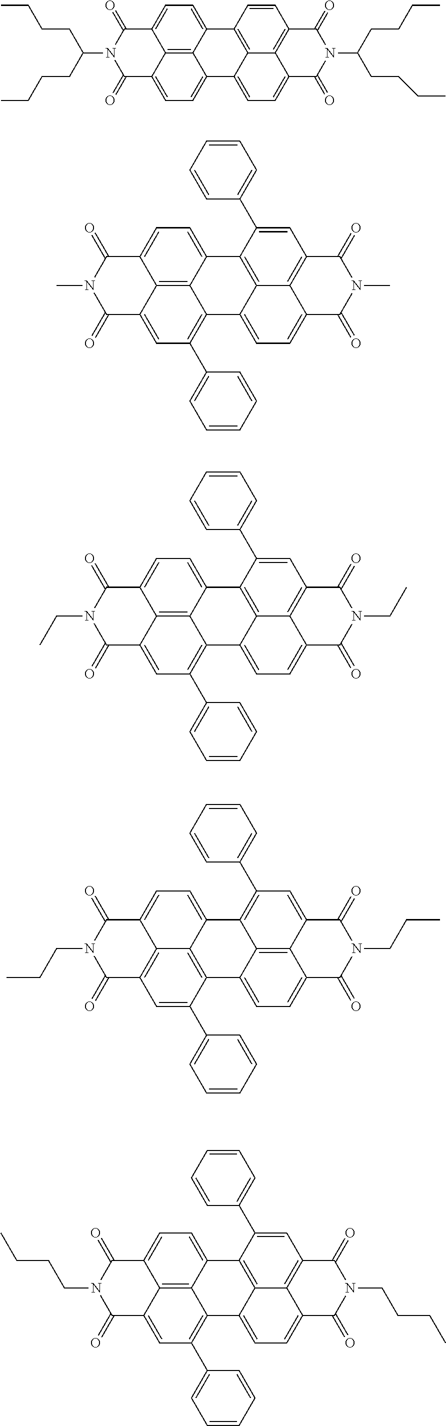

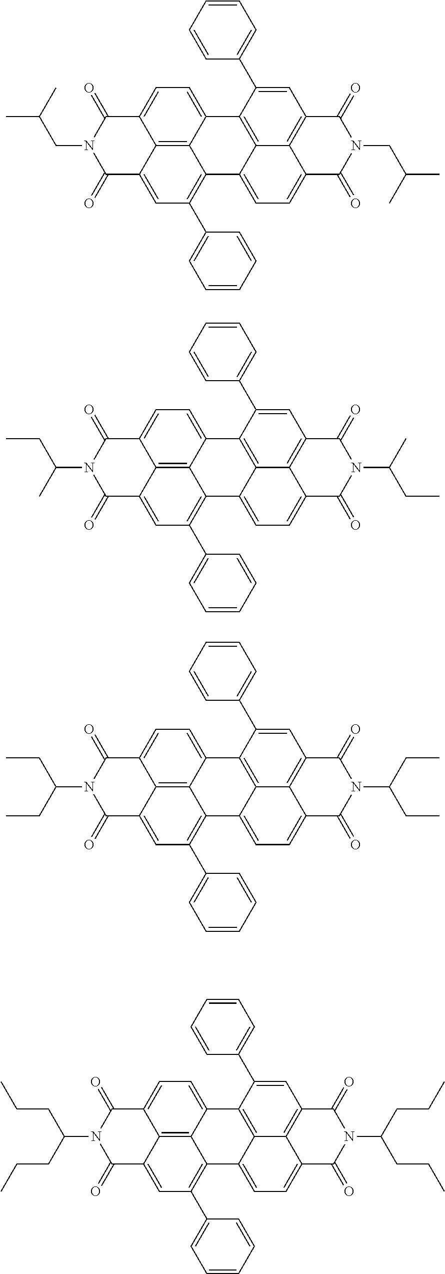

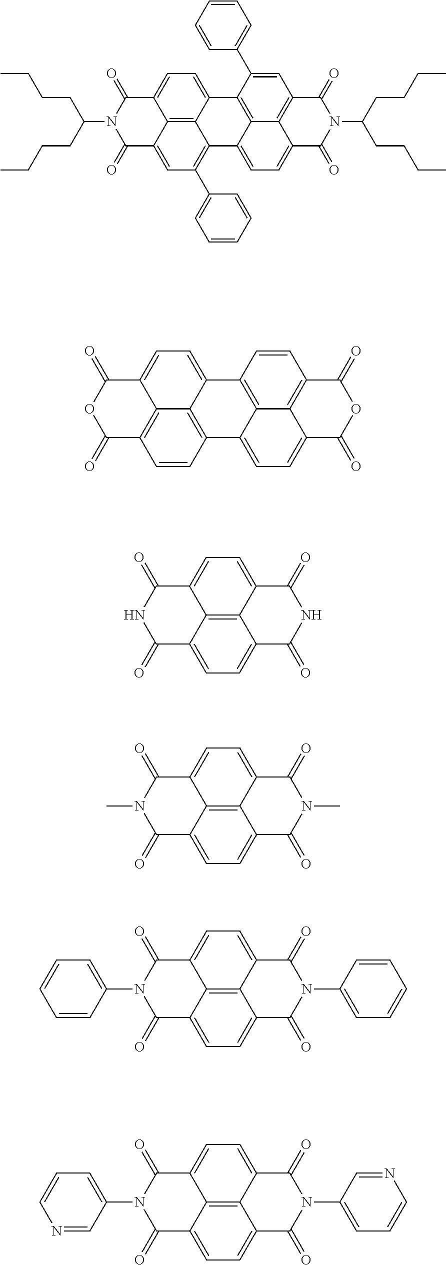

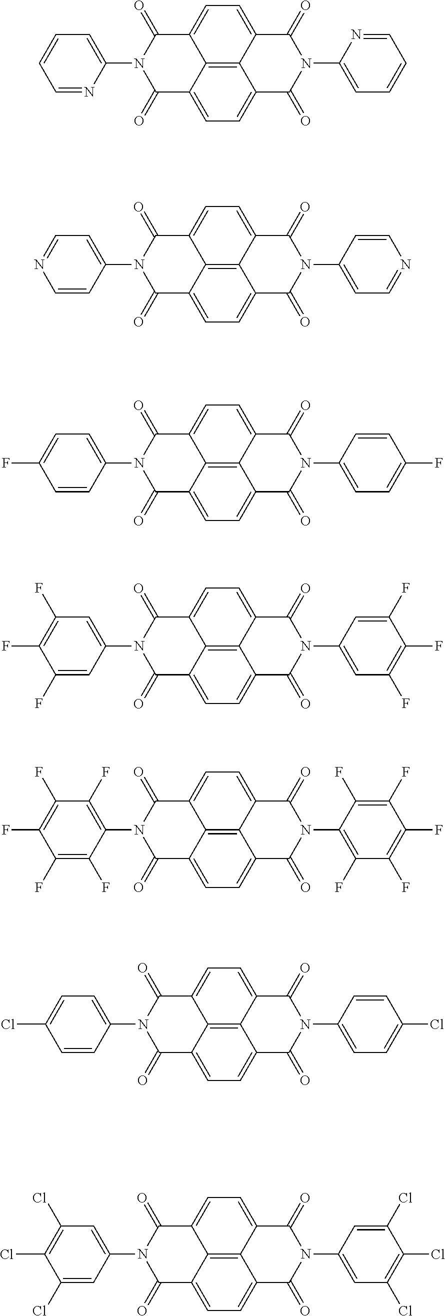

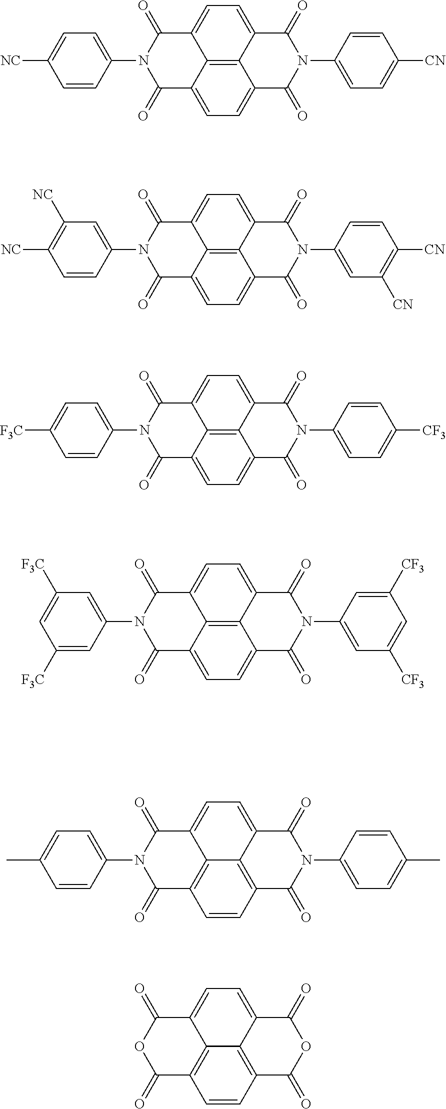

In the organic photodetector 10 according to an embodiment, as long as the HOMO energy absolute values of the first and second amine compounds are satisfied as described above, structures thereof may be irrelevant.

In an embodiment, the first amine compound may be a tertiary amine compound including: one or two fluorene moieties; and at least one aryl moiety.

In an embodiment, the second amine compound may be a tertiary amine compound including three fluorene moieties.

For example, the first amine compound may have a structure of Formula 4, and may include at least one aryl moiety and one or two fluorene moieties.

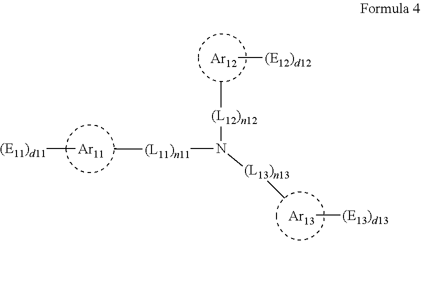

In Formula 4, Ar₁₁ to Ar₁₃ may each independently be a C₃-C₆₀ carbocyclic group or a C₁-C₆₀ heterocyclic group,
L₁₁ to L₁₃ may each independently be a single bond, a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
E₁₁ to E₁₃ may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, or a C₆-C₆₀ arylthio group that is unsubstituted or substituted with at least one R₁₀ₐ,
n11 to n13 may each independently be an integer from 0 to 3, and
d11 to d13 may each independently be an integer from 0 to 9.

R₁₀ₐ may be the same as described in connection with Formula 1.

For example, the second amine compound may be a tertiary amine compound having a structure of Formula 4 and including three fluorene moieties.

A fluorene moiety may include a spiro-compound.

In an embodiment, the first amine compound may include one of compounds:

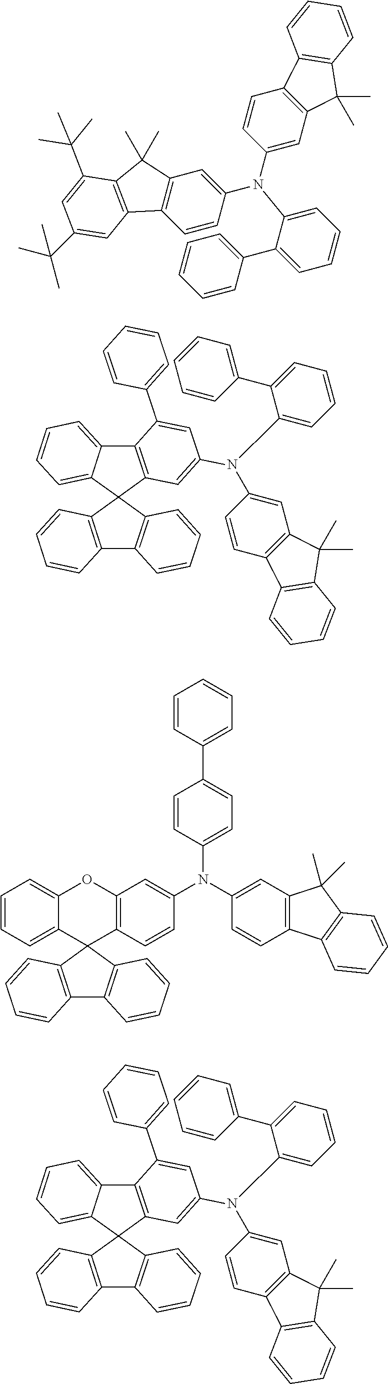

In an embodiment, the second amine compound may include one of compounds:

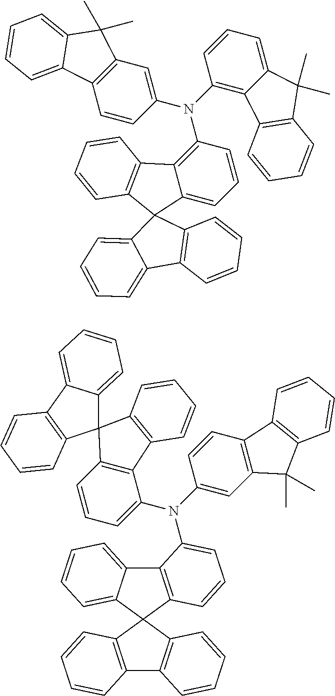

In an embodiment, the p-dopant may include a quinone derivative, a cyano group-containing compound, a compound including an element EL1 and an element EL2, or any combination thereof.

Examples of the quinone derivative may include TCNQ, F4-TCNQ, and/or the like.

Examples of the cyano group-containing compound may include HAT-CN, a compound represented by Formula 221, and/or the like.

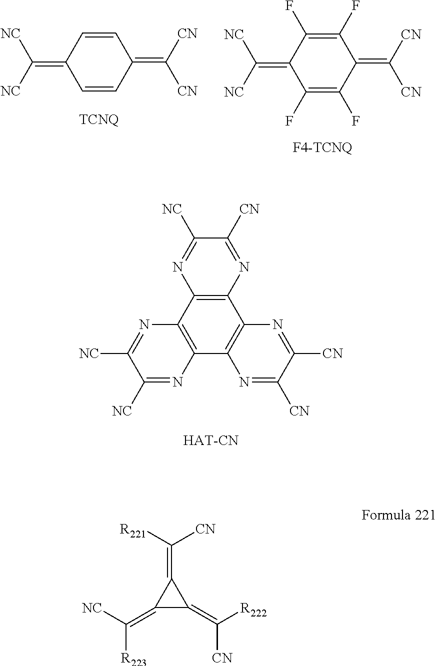

In Formula 221,
R₂₂₁ to R₂₂₃ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group that is substituted with a cyano group, —F, —Cl, —Br, —I, or any combination thereof; or any combination thereof.

In the compound containing an element EL1 and an element EL2, the element EL1 may be metal, metalloid, or a combination thereof, and the element EL2 may be non-metal, metalloid, or a combination thereof.

Examples of the metal may include an alkali metal (for example, lithium (Li), sodium (Na), potassium (K), rubidium (Rb), cesium (Cs), etc.); an alkaline earth metal (for example, beryllium (Be), magnesium (Mg), calcium (Ca), strontium (Sr), barium (Ba), etc.); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (for example, zinc (Zn), indium (In), tin (Sn), etc.); and a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.).

Examples of the metalloid may include silicon (Si), antimony (Sb), and tellurium (Te).

Examples of the non-metal may include oxygen (O) and a halogen (for example, F, Cl, Br, I, etc.).

In an embodiment, examples of the compound containing the element EL1 and the element EL2 may include a metal oxide, a metal halide (for example, a metal fluoride, a metal chloride, a metal bromide, or a metal iodide), a metalloid halide (for example, a metalloid fluoride, a metalloid chloride, a metalloid bromide, or a metalloid iodide), a metal telluride, or any combination thereof.

Examples of the metal oxide may include a tungsten oxide (for example, WO, W₂O₃, WO₂, WO₃, W₂O₅, etc.), a vanadium oxide (for example, VO, V₂O₃, VO₂, V₂O₅, etc.), a molybdenum oxide (MoO, Mo₂O₃, MoO₂, MoO₃, Mo₂O₅, etc.), and a rhenium oxide (for example, ReO₃, etc.).

Examples of the metal halide may include an alkali metal halide, an alkaline earth metal halide, a transition metal halide, a post-transition metal halide, and a lanthanide metal halide.

Examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, and CsI.

Examples of the alkaline earth metal halide may include BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, BeI₂, MgI₂, CaI₂, SrI₂, and BaI₂.

Examples of the transition metal halide may include a titanium halide (for example, TiF₄, TiCl₄, TiBr₄, TiI₄, etc.), a zirconium halide (for example, ZrF₄, ZrCl₄, ZrBr₄, ZrI₄, etc.), a hafnium halide (for example, HfF₄, HfCl₄, HfBr₄, HfI₄, etc.), a vanadium halide (for example, VF₃, VCl₃, VBr₃, VI₃, etc.), a niobium halide (for example, NbF₃, NbCl₃, NbBr₃, NbI₃, etc.), a tantalum halide (for example, TaF₃, TaCl₃, TaBr₃, TaI₃, etc.), a chromium halide (for example, CrF₃, CrCl₃, CrBr₃, CrI₃, etc.), a molybdenum halide (for example, MoF₃, MoCl₃, MoBr₃, MoI₃, etc.), a tungsten halide (for example, WF₃, WCl₃, WBr₃, WI₃, etc.), a manganese halide (for example, MnF₂, MnCl₂, MnBr₂, MnI₂, etc.), a technetium halide (for example, TcF₂, TcCl₂, TcBr₂, TcI₂, etc.), a rhenium halide (for example, ReF₂, ReCl₂, ReBr₂, ReI₂, etc.), an iron halide (for example, FeF₂, FeCl₂, FeBr₂, FeI₂, etc.), a ruthenium halide (for example, RuF₂, RuCl₂, RuBr₂, RuI₂, etc.), an osmium halide (for example, OsF₂, OsCl₂, OsBr₂, OsI₂, etc.), a cobalt halide (for example, CoF₂, CoCl₂, CoBr₂, CoI₂, etc.), a rhodium halide (for example, RhF₂, RhCl₂, RhBr₂, RhI₂, etc.), an iridium halide (for example, IrF₂, IrCl₂, IrBr₂, IrI₂, etc.), a nickel halide (for example, NiF₂, NiCl₂, NiBr₂, NiI₂, etc.), a palladium halide (for example, PdF₂, PdCl₂, PdBr₂, PdI₂, etc.), a platinum halide (for example, PtF₂, PtCl₂, PtBr₂, PtI₂, etc.), a copper halide (for example, CuF, CuCl, CuBr, CuI, etc.), a silver halide (for example, AgF, AgCl, AgBr, AgI, etc.), and a gold halide (for example, AuF, AuCl, AuBr, AuI, etc.).

Examples of the post-transition metal halide may include a zinc halide (for example, ZnF₂, ZnCl₂, ZnBr₂, ZnI₂, etc.), an indium halide (for example, InI₃, etc.), and a tin halide (for example, SnI₂, etc.).

Examples of the lanthanide metal halide may include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, and SmI₃.

Examples of the metalloid halide may include an antimony halide (for example, SbCl₅, etc.).

Examples of the metal telluride may include an alkali metal telluride (for example, Li₂Te, Na₂Te, K₂Te, Rb₂Te, Cs₂Te, etc.), an alkaline earth metal telluride (for example, BeTe, MgTe, CaTe, SrTe, BaTe, etc.), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), a post-transition metal telluride (for example, ZnTe, etc.), and a lanthanide metal telluride (for example, LaTe, CeTe, PrTe, NdTe, PmTe, EuTe, GdTe, TbTe, DyTe, HoTe, ErTe, TmTe, YbTe, LuTe, etc.).

In an embodiment, when the hole transport layer 120 includes a layer including the p-dopant, an amount of the p-dopant in the layer including the p-dopant may be about 0.1 volume % to about 10 volume %, for example, about 0.5 volume % to about 5 volume %.

A thickness of the layer including the p-dopant may be about 50 Å to about 2,000 Å, for example, about 100 Å to about 1,500 Å.

### First Electrode 110

In FIG. 1, a substrate may be additionally disposed under the first electrode 110 or above the second electrode 170. As the substrate, a glass substrate or a plastic substrate may be utilized. In an embodiment, the substrate may be a flexible substrate, and may include plastics with excellent or suitable heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, applying a material for forming the first electrode 110 onto the substrate by utilizing a deposition or sputtering method. When the first electrode 110 is an anode, the material for forming the first electrode 110 may be a high-work function material.

The first electrode 110 may be a reflective electrode, a semi-transmissive electrode, or a transmissive electrode. To form the first electrode 110 as a transmissive electrode, indium tin oxide (ITO), indium zinc oxide (IZO), tin oxide (SnO₂), zinc oxide (ZnO), or any combination thereof may be utilized as the material for forming the first electrode 110. In an embodiment, to form the first electrode 110 as a semi-transmissive electrode or a reflective electrode, magnesium (Mg), silver (Ag), aluminum (Al), aluminum-lithium (Al—Li), calcium (Ca), magnesium-indium (Mg—In), magnesium-silver (Mg—Ag), or any combination thereof may be utilized as the material for forming the first electrode 110.

The first electrode 110 may have a single-layered structure consisting of a single layer, or a multilayer structure including a plurality of layers. For example, the first electrode 110 may have a three-layered structure of ITO/Ag/ITO.

### Charge Auxiliary Layer

The organic photodetector 10 according to an embodiment may include a charge auxiliary layer that facilitates migration of holes and electrons divided in the activation layer 140.

The charge auxiliary layer may include a hole injection layer and the hole transport layer 120, which facilitate migration of holes, and may include the electron transport layer 160 and an electron injection layer, which facilitate migration of electrons.

### Hole Transport Region

Charge auxiliary layers arranged between the first electrode 110 and the activation layer 140 may be collectively referred to as a hole transport region.

The hole transport region may include the hole injection layer, the hole transport layer 120, and the electron blocking layer.

The hole transport region may include a hole transporting material. For example, the hole transporting material may include a compound represented by Formula 201, a compound represented by Formula 202, or any combination thereof:

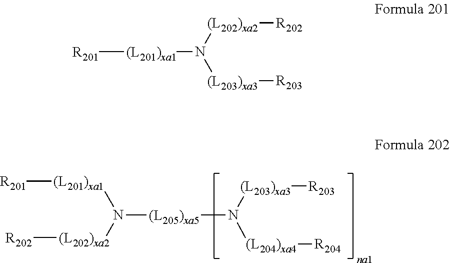

wherein, in Formulae 201 and 202,
L₂₀₁ to L₂₀₄ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
L₂₀₅ may be *—O—*′, *—S—*′, *—N(Q₂₀₁)-*′, a C₁-C₂₀ alkylene group that is unsubstituted or substituted with at least one R₁₀ₐ, a C₂-C₂₀ alkenylene group that is unsubstituted or substituted with at least one R₁₀ₐ, a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
R₂₀₁ and R₂₀₂ may optionally be linked to each other, via a single bond, a C₁-C₅ alkylene group that is unsubstituted or substituted with at least one R₁₀ₐ, or a C₂-C₅ alkenylene group that is unsubstituted or substituted with at least one R₁₀ₐ, to form a C₈-C₆₀ polycyclic group (for example, a carbazole group and/or the like) unsubstituted or substituted with at least one R₁₀ₐ (for example, Compound HT16),
R₂₀₃ and R₂₀₄ may optionally be linked to each other via a single bond, a C₁-C₅ alkylene group that is unsubstituted or substituted with at least one R₁₀ₐ, or a C₂-C₅ alkenylene group that is unsubstituted or substituted with at least one R₁₀ₐ, to form a C₈-C₆₀ polycyclic group that is unsubstituted or substituted with at least one R₁₀ₐ, and
na1 may be an integer from 1 to 4.

In an embodiment, each of Formulae 201 and 202 may include at least one of groups represented by Formulae CY201 to CY217:

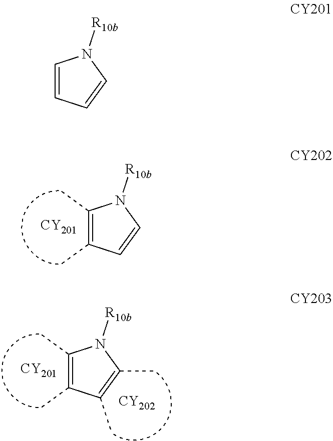

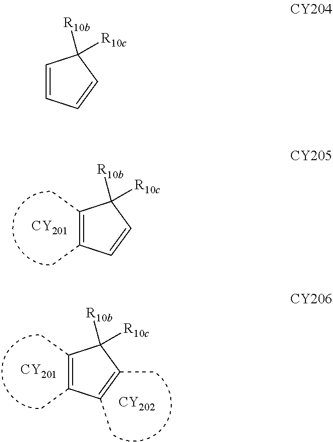

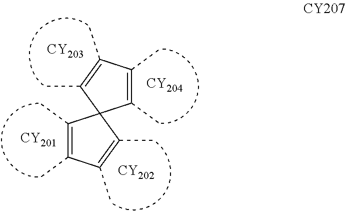

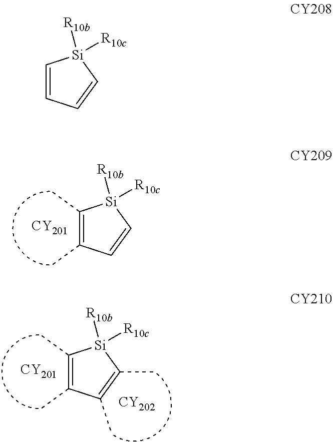

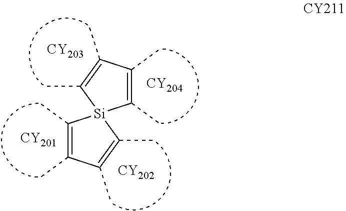

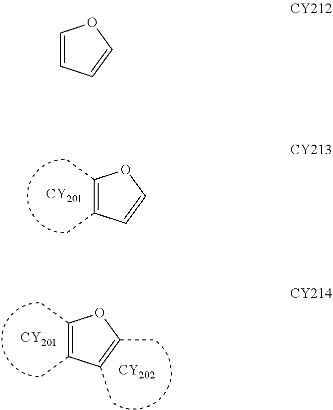

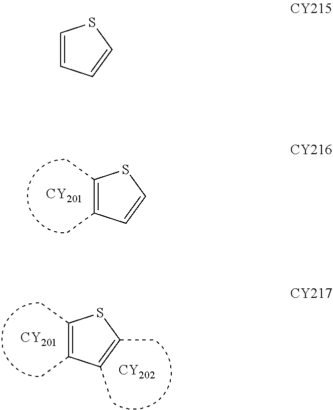

wherein, in Formulae CY201 to CY217, R_{10b} and R_{10c} may each be the same as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ as described above.

In an embodiment, ring CY₂₀₁ to ring CY₂₀₄ in Formulae CY201 to CY217 may each independently be a benzene group, a naphthalene group, a phenanthrene group, or an anthracene group.

In an embodiment, each of Formulae 201 and 202 may include at least one of groups represented by Formulae CY201 to CY203.

In an embodiment, Formula 201 may include at least one of groups represented by Formulae CY201 to CY203 and at least one of groups represented by Formulae CY204 to CY217.

In an embodiment, xa1 in Formula 201 may be 1, R₂₀₁ may be a group represented by one of Formulae CY201 to CY203, xa2 may be 0, and R₂₀₂ may be a group represented by one of Formulae CY204 to CY207.

In an embodiment, each of Formulae 201 and 202 may not include (e.g., may exclude) groups represented by Formulae CY201 to CY203.

In an embodiment, each of Formulae 201 and 202 may not include (e.g., may exclude) groups represented by Formulae CY201 to CY203, and may include at least one of groups represented by Formulae CY204 to CY217.

In an embodiment, each of Formulae 201 and 202 may not include (e.g., may exclude) groups represented by Formulae CY201 to CY217.

For example, the hole transporting material may include at least one of Compounds HT1 to HT46, m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

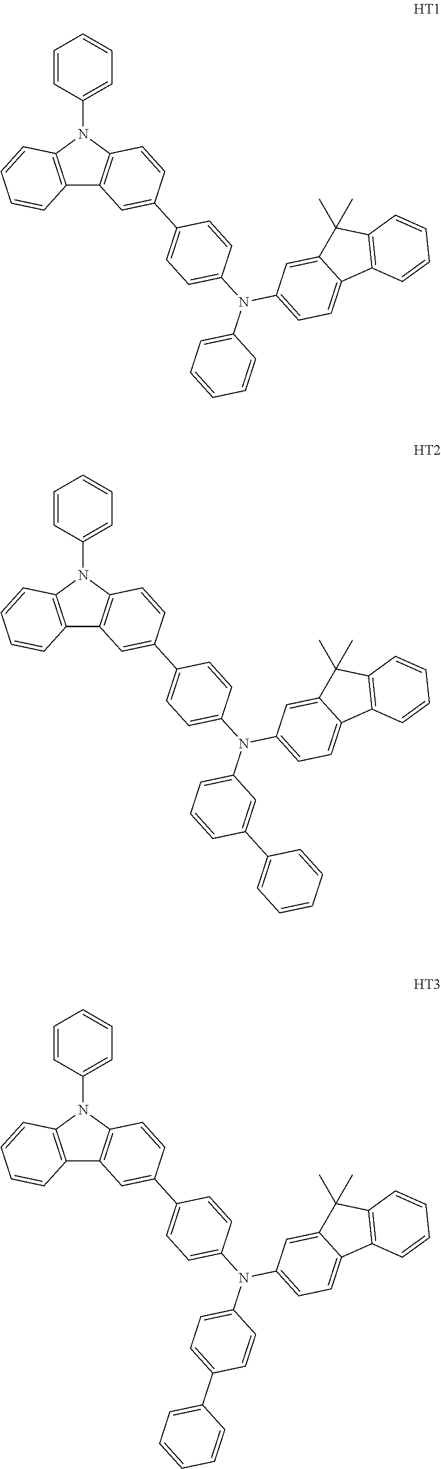 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

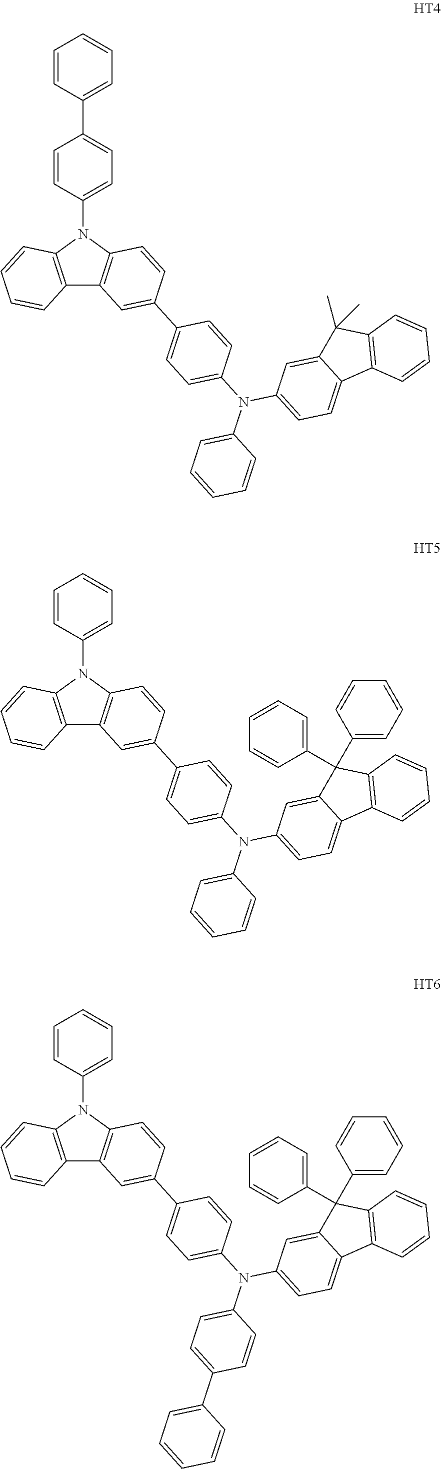 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

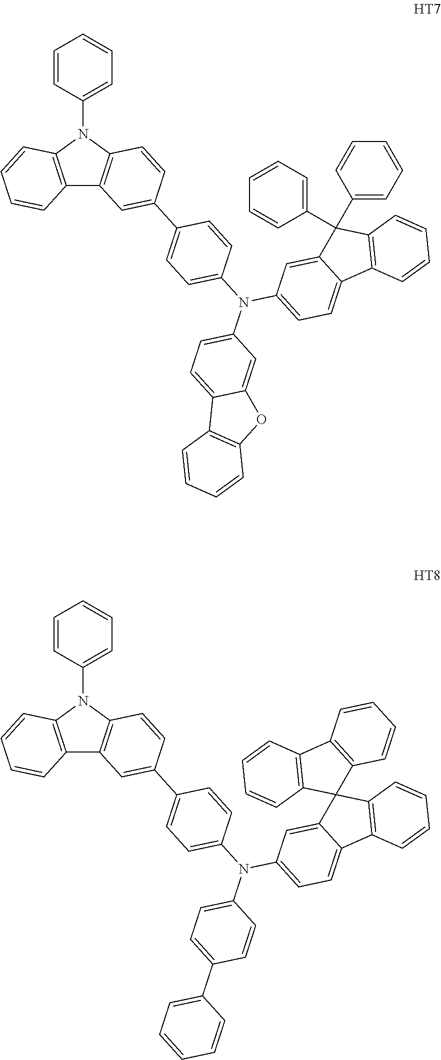 [SMILES: c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

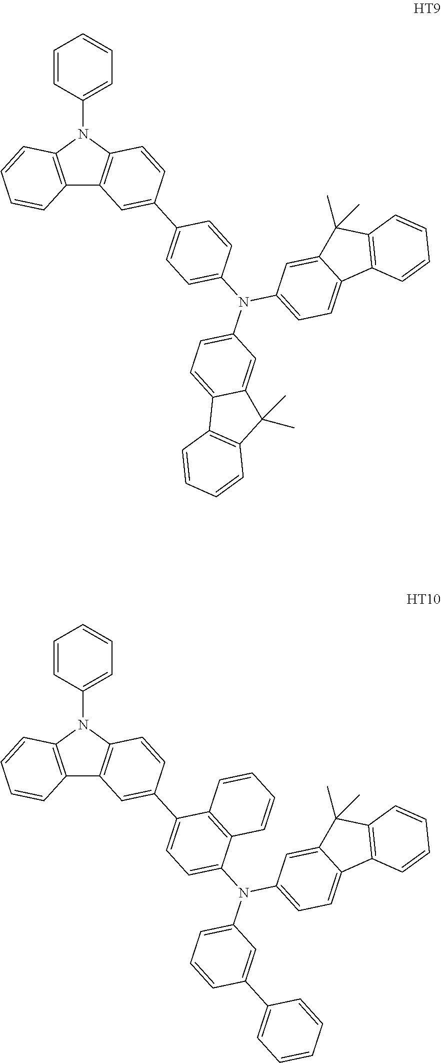 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21]

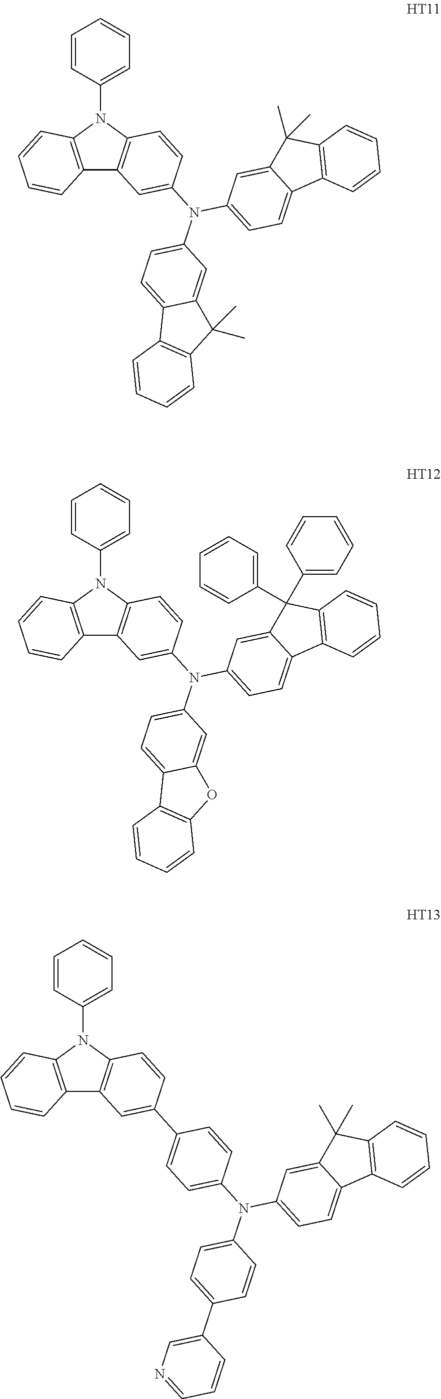 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1 ; CC1(C)c2ccccc2-c2ccc(N(c3ccc(-c4cccnc4)cc3)c3ccc(-c4ccc5c(c4)c4ccccc4n5-c4ccccc4)cc3)cc21]

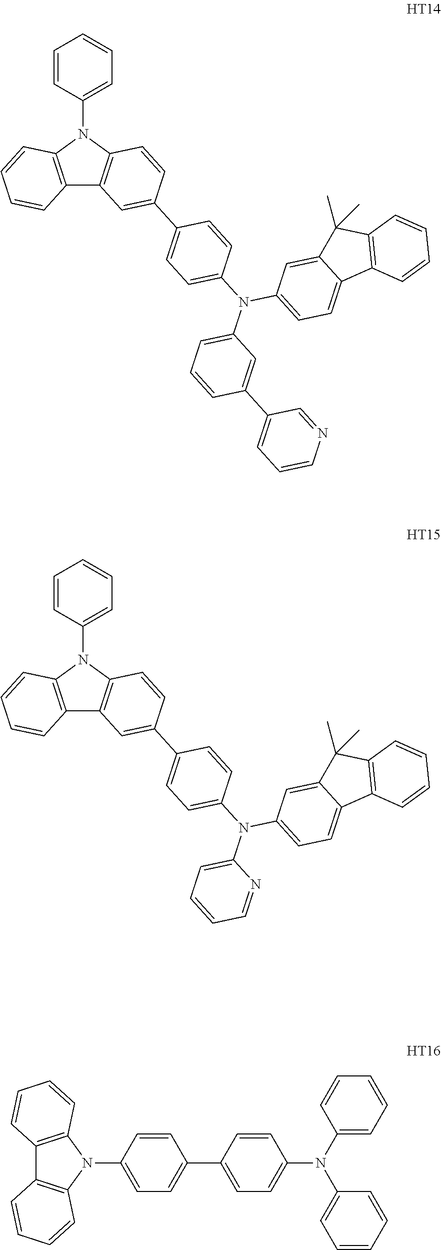 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1]

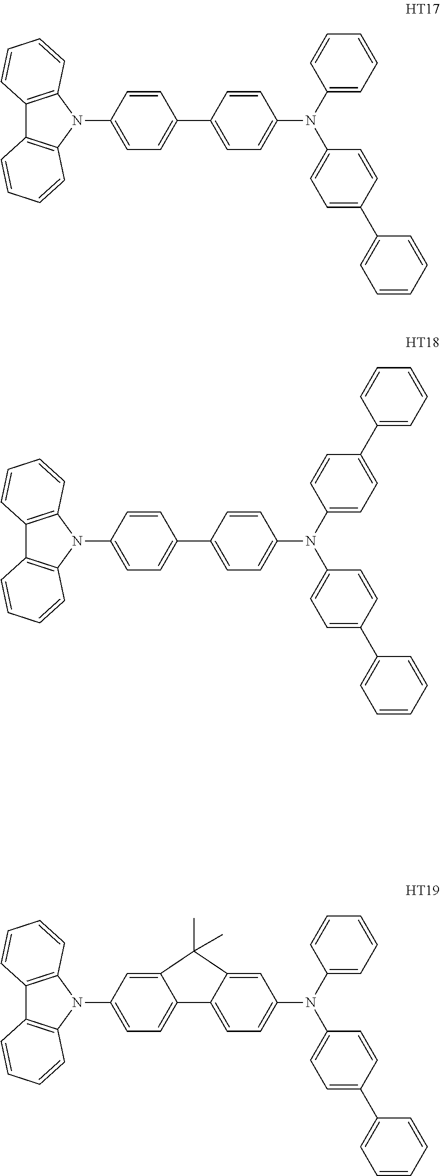 [SMILES: c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21]

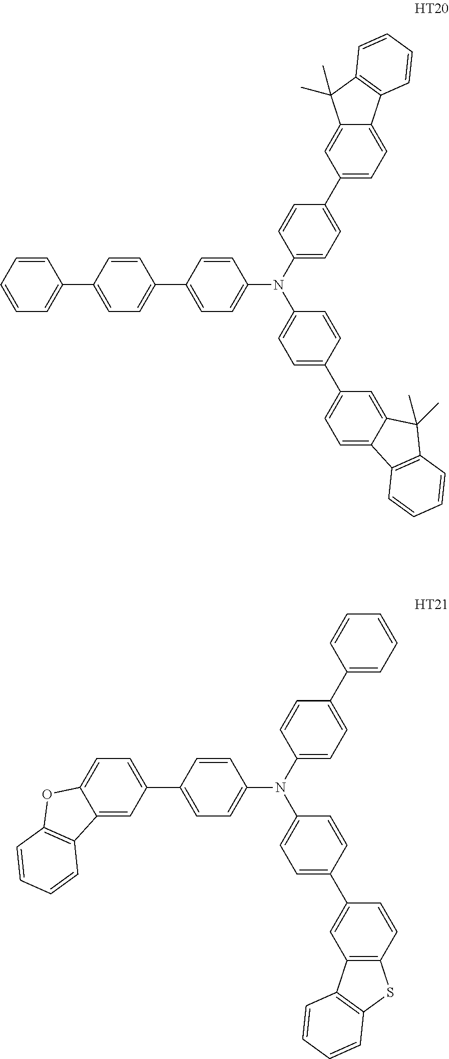 [SMILES: CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1]

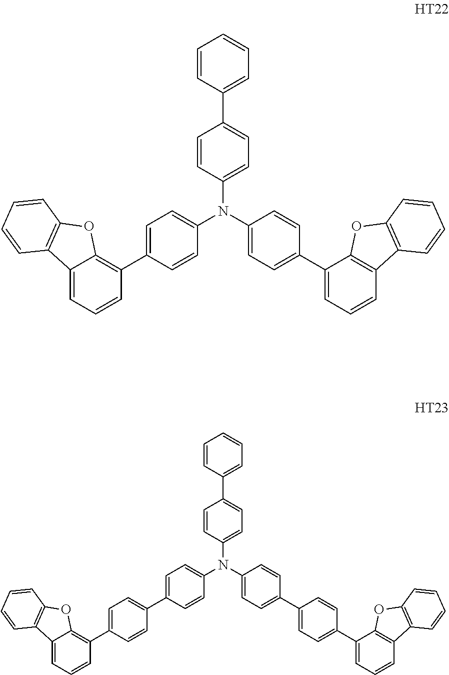 [SMILES: c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

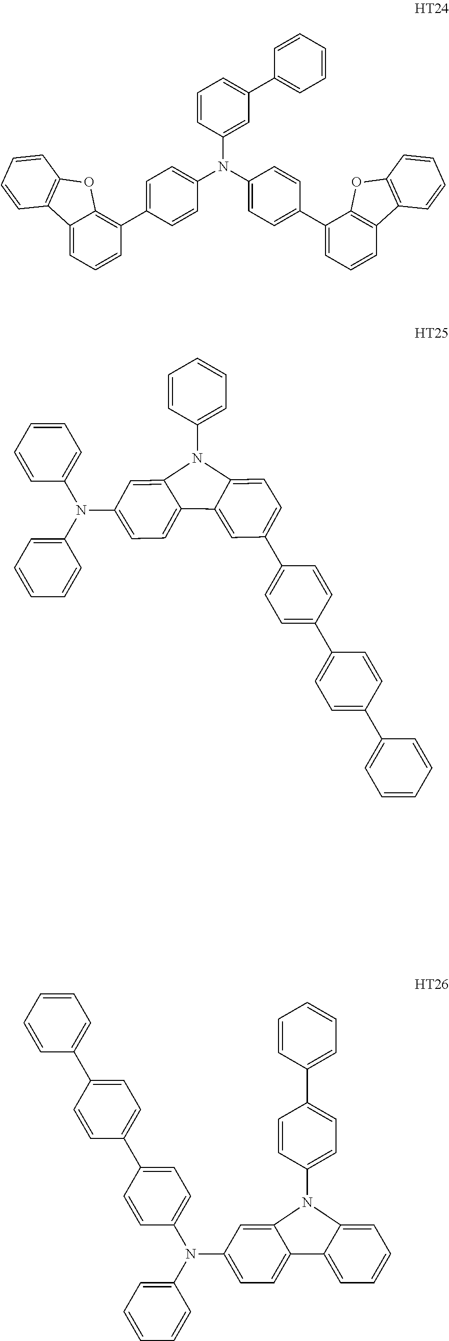 [SMILES: c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1 ; c1ccc(-c2ccc(-c3ccc(N(c4ccccc4)c4ccc5c6ccccc6n(-c6ccc(-c7ccccc7)cc6)c5c4)cc3)cc2)cc1]

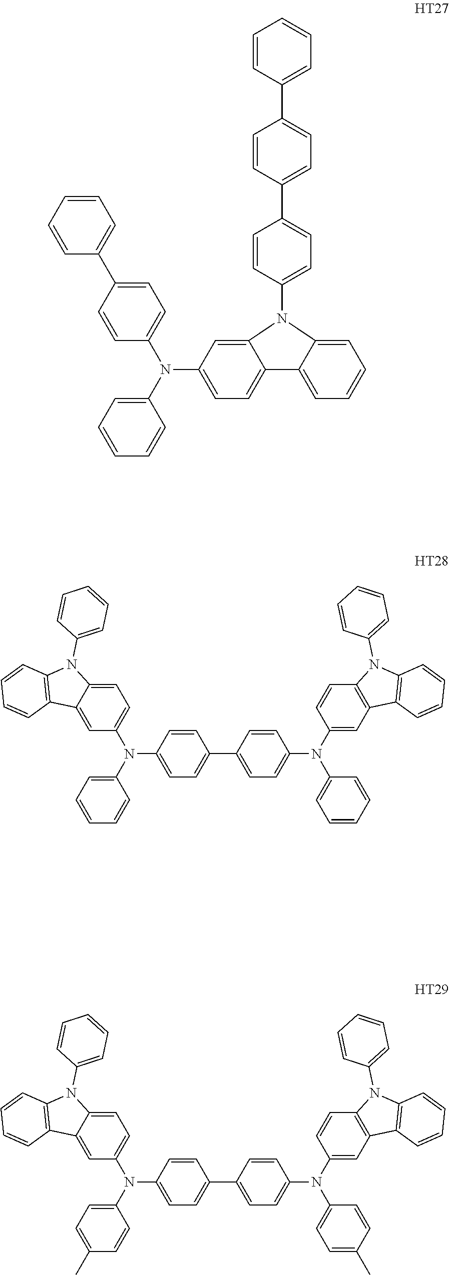 [SMILES: c1ccc(-c2ccc(-c3ccc(-n4c5ccccc5c5ccc(N(c6ccccc6)c6ccc(-c7ccccc7)cc6)cc54)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1]

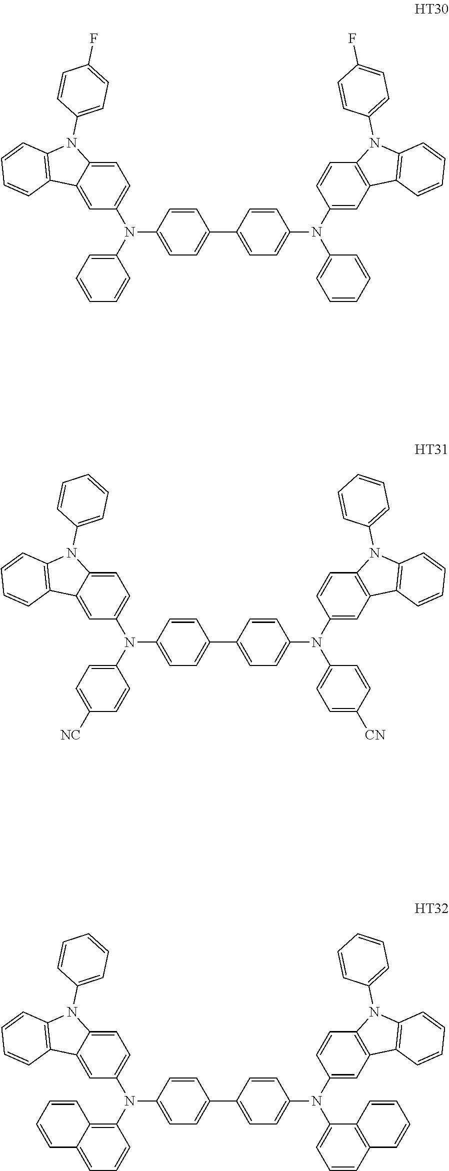 [SMILES: Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1]

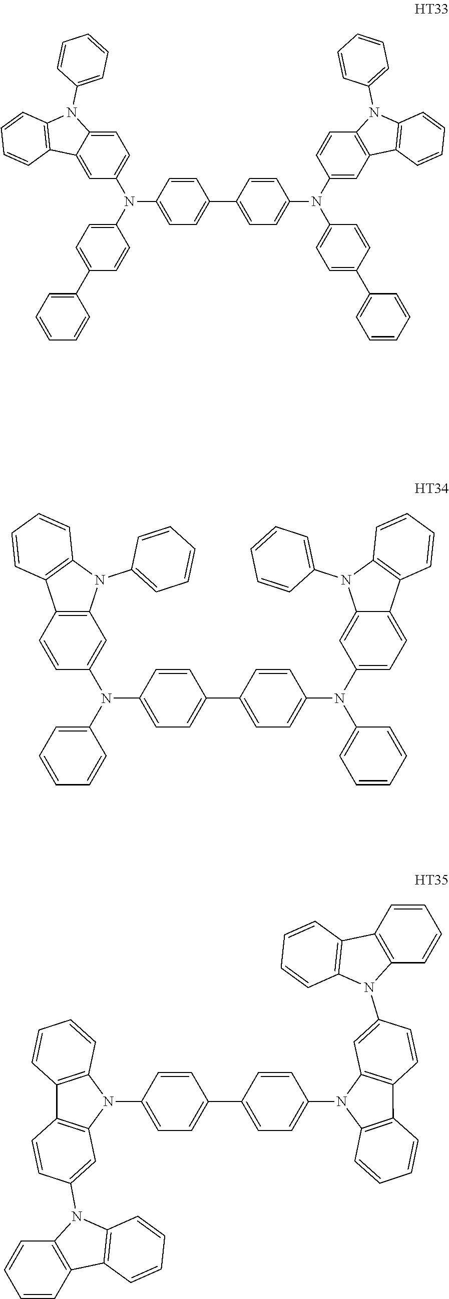 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(N(c2ccc(-c3ccc(N(c4ccccc4)c4ccc5c6ccccc6n(-c6ccccc6)c5c4)cc3)cc2)c2ccc3c4ccccc4n(-c4ccccc4)c3c2)cc1 ; c1ccc2c(c1)c1ccccc1n2-c1ccc2c3ccccc3n(-c3ccc(-c4ccc(-n5c6ccccc6c6ccc(-n7c8ccccc8c8ccccc87)cc65)cc4)cc3)c2c1]

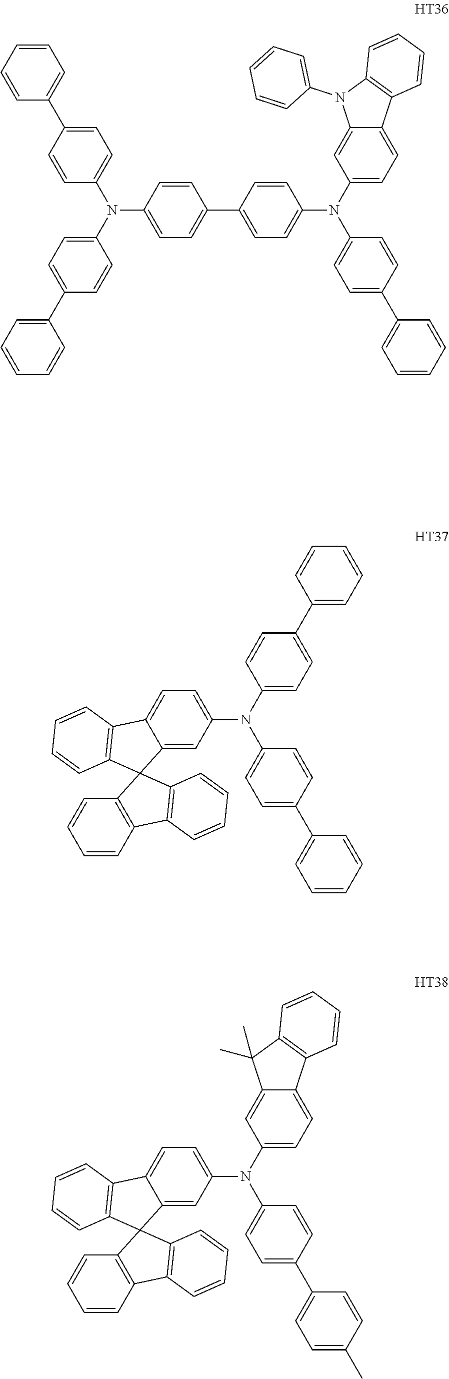 [SMILES: c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1 ; c1ccc(-c2ccc(N(c3ccc(-c4ccccc4)cc3)c3ccc4c(c3)C3(c5ccccc5-c5ccccc53)c3ccccc3-4)cc2)cc1 ; Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1]

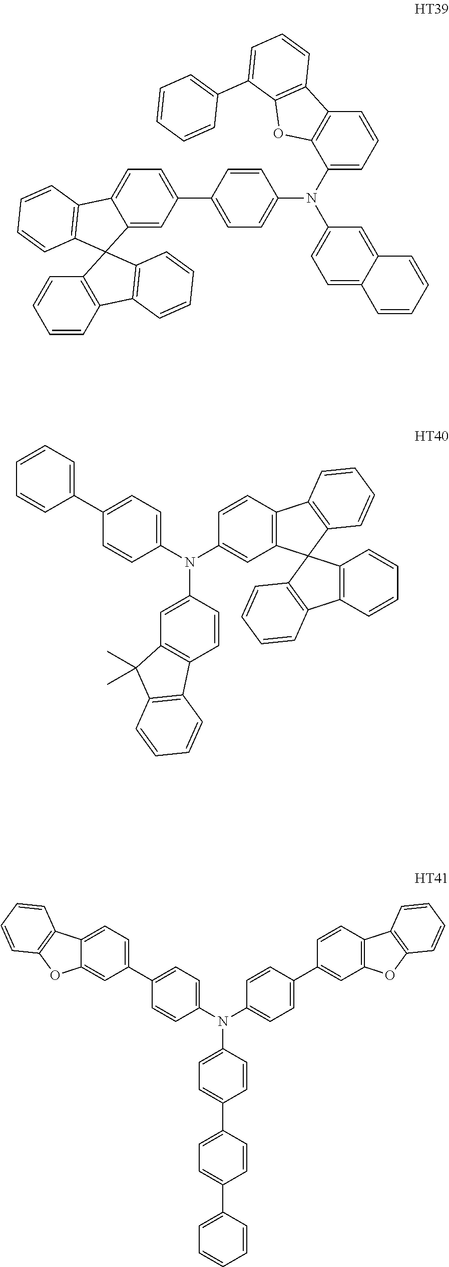 [SMILES: c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; c1ccc(-c2ccc(-c3ccc(N(c4ccc(-c5ccc6c(c5)oc5ccccc56)cc4)c4ccc(-c5ccc6c(c5)oc5ccccc56)cc4)cc3)cc2)cc1]

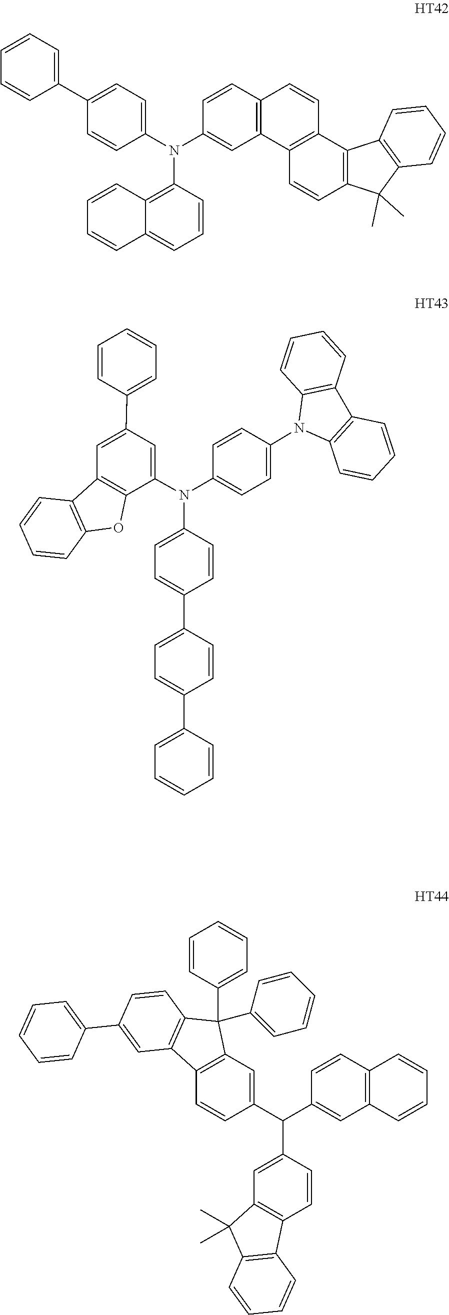

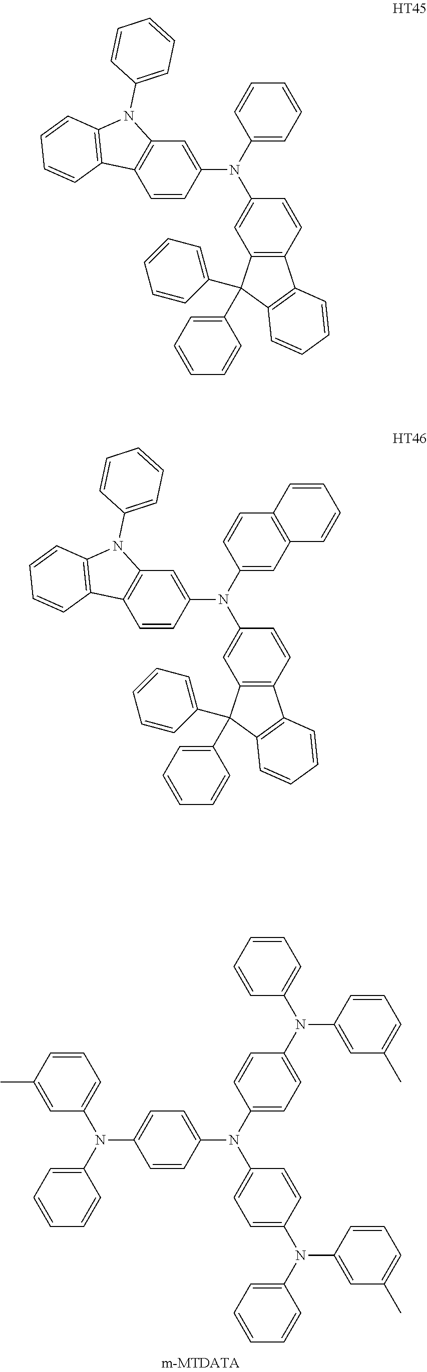 [SMILES: c1ccc(N(c2ccc3c(c2)C(c2ccccc2)(c2ccccc2)c2ccccc2-3)c2ccc3c4ccccc4n(-c4ccccc4)c3c2)cc1 ; c1ccc(-n2c3ccccc3c3ccc(N(c4ccc5c(c4)C(c4ccccc4)(c4ccccc4)c4ccccc4-5)c4ccc5ccccc5c4)cc32)cc1 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1]

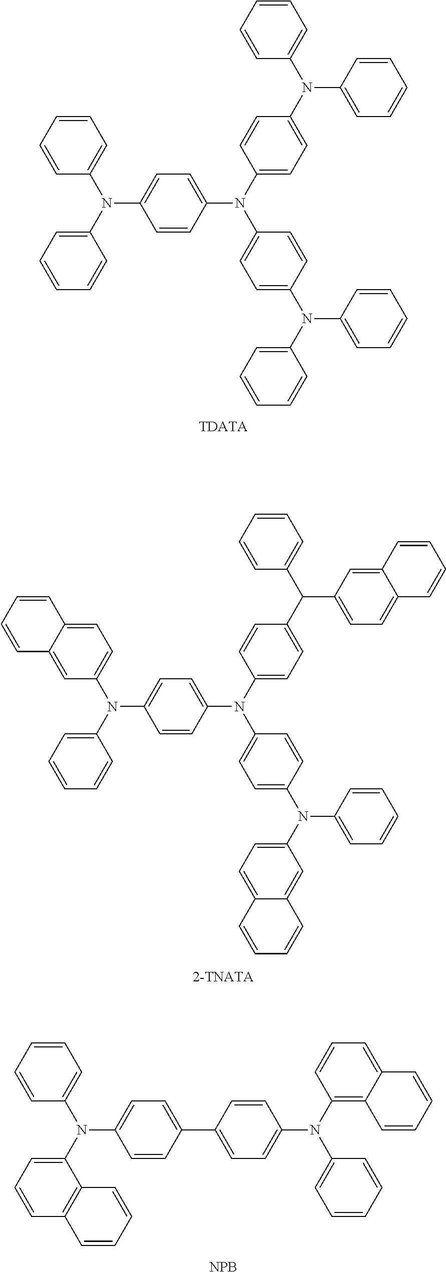 [SMILES: c1ccc(N(c2ccccc2)c2ccc(N(c3ccc(N(c4ccccc4)c4ccccc4)cc3)c3ccc(N(c4ccccc4)c4ccccc4)cc3)cc2)cc1 ; "TDATA" ; c1ccc(C(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1 ; "NPB"]

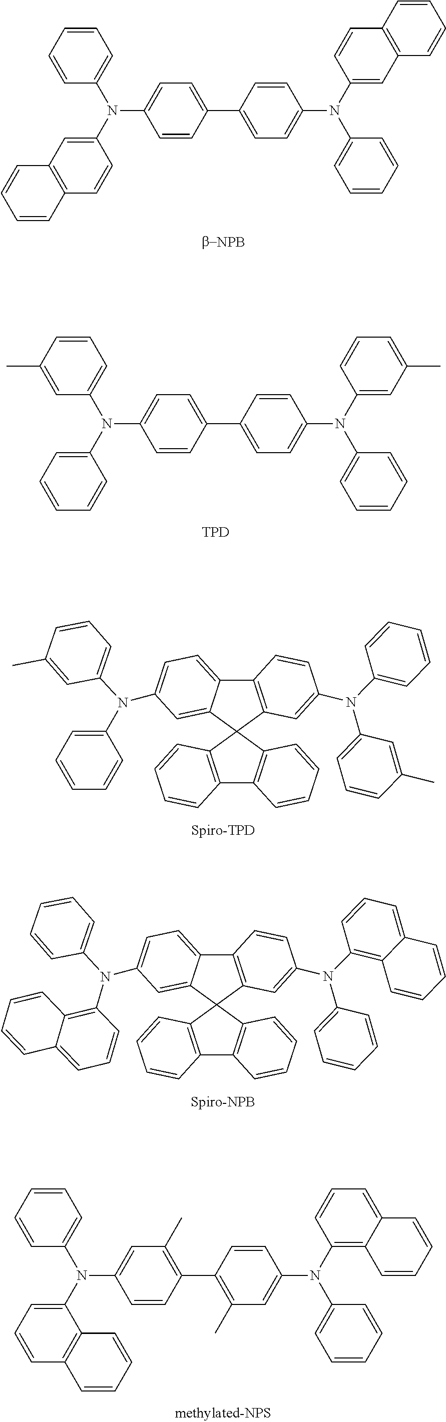

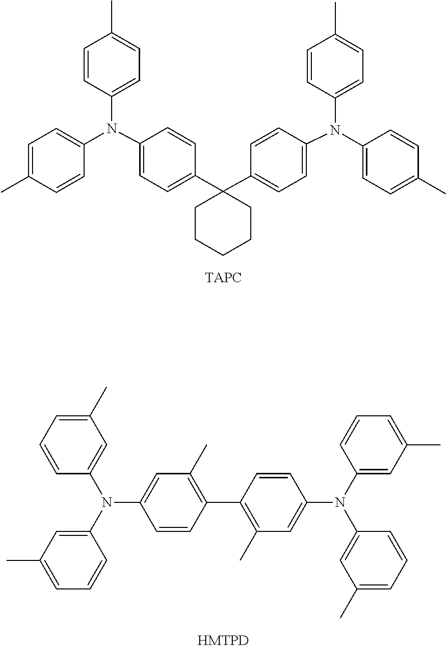

A thickness of the hole transport region may be in a range of about 50 Å to about 10,000 Å, for example, about 100 Å to about 4,000 Å. When the hole transport region includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer and the hole transport layer are within these ranges, satisfactory hole-transporting characteristics may be obtained without a substantial increase in driving voltage.

The electron blocking layer may prevent or reduce leakage of electrons from the activation layer 140 to the hole transport region. The hole transporting material may be included in the electron transport layer 160 and the electron blocking layer.

### Electron Transport Region

Charge auxiliary layers arranged between the activation layer 140 and the second electrode 170 may be collectively referred to as an electron transport region.

The electron transport region may have: i) a single-layered structure consisting of a single layer consisting of a single material, ii) a single-layered structure consisting of a single layer consisting of a plurality of different materials, or iii) a multilayer structure including a plurality of layers including different materials.

The electron transport region may include a buffer layer, a hole blocking layer, the electron transport layer 160, an electron injection layer, or any combination thereof.

For example, the electron transport region may have an electron transport layer/electron injection layer structure, a hole blocking layer/electron transport layer/electron injection layer structure, a buffer layer/electron transport layer/electron injection layer structure, or a buffer layer/electron transport layer structure, wherein, for each structure, constituting layer are sequentially stacked from the activation layer 140.

The electron transport region (for example, the buffer layer, the hole blocking layer, or the electron transport layer 160 in the electron transport region) may include a metal-free compound including at least one TT electron-deficient nitrogen-containing C₁-C₆₀ cyclic group.

In an embodiment, the electron transport region may include a compound represented by Formula 601:

[Ar₆₀₁]ₓₑ₁₁—[(L₆₀₁)ₓₑ₁—R₆₀₁]ₓₑ₂₁ Formula 601

wherein, in Formula 601,
Ar₆₀₁ and L₆₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same as described in connection with Q₁,
xe21 may be 1, 2, 3, 4, or 5, and
at least one of Ar₆₀₁, L₆₀₁, and R₆₀₁ may each independently be a π electron-deficient nitrogen-containing C₁-C₆₀ cyclic group that is unsubstituted or substituted with at least one R₁₀ₐ.

In an embodiment, when xe11 in Formula 601 is 2 or more, two or more Ar₆₀₁(s) may be linked to each other via a single bond.

In an embodiment, Ar₆₀₁ in Formula 601 may be a substituted or unsubstituted anthracene group.

In an embodiment, the electron transport region may include a compound represented by Formula 601-1:

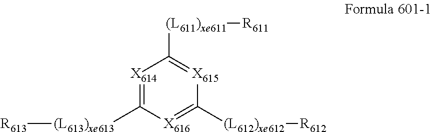

wherein, in Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,
L₆₁₁ to L₆₁₃ may each independently be the same as described in connection with L₆₀₁,
xe611 to xe613 may each independently be the same as described in connection with xe1,
R₆₁₁ to R₆₁₃ may each independently be the same as described in connection with R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group that is unsubstituted or substituted with at least one R₁₀ₐ, or a C₁-C₆₀ heterocyclic group that is unsubstituted or substituted with at least one R₁₀ₐ.

In an embodiment, xe1 and xe611 to xe613 in Formulae 601 and 601-1 may each independently be 0, 1, or 2.

The electron transport region may include at least one of Compounds ET1 to ET45, 2,9-dimethyl-4,7-diphenyl-1,10-phenanthroline (BCP), 4,7-diphenyl-1,10-phenanthroline (Bphen), Alq₃, BAlq, TAZ, NTAZ, or any combination thereof:

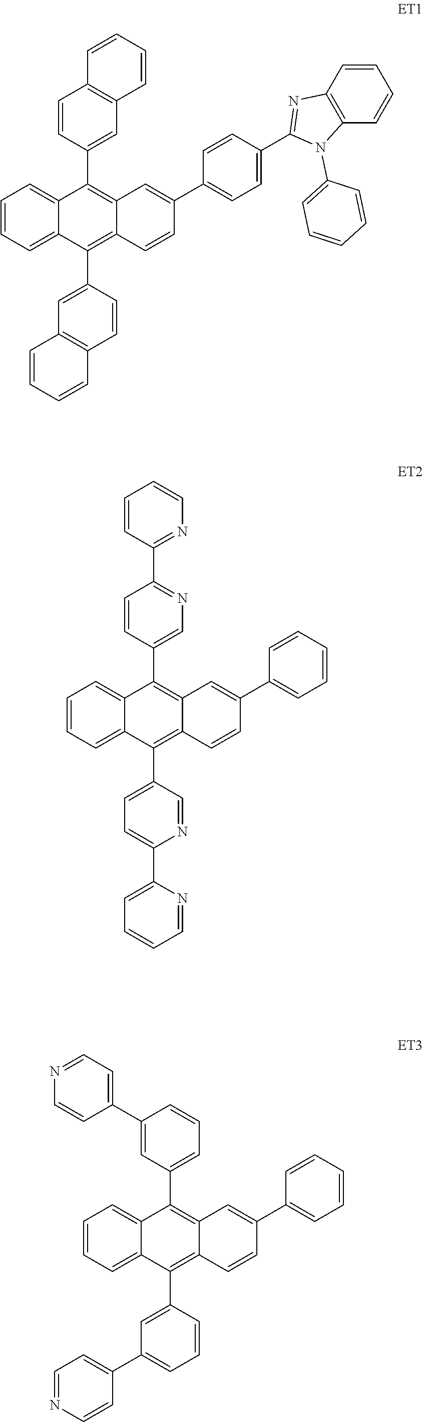 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

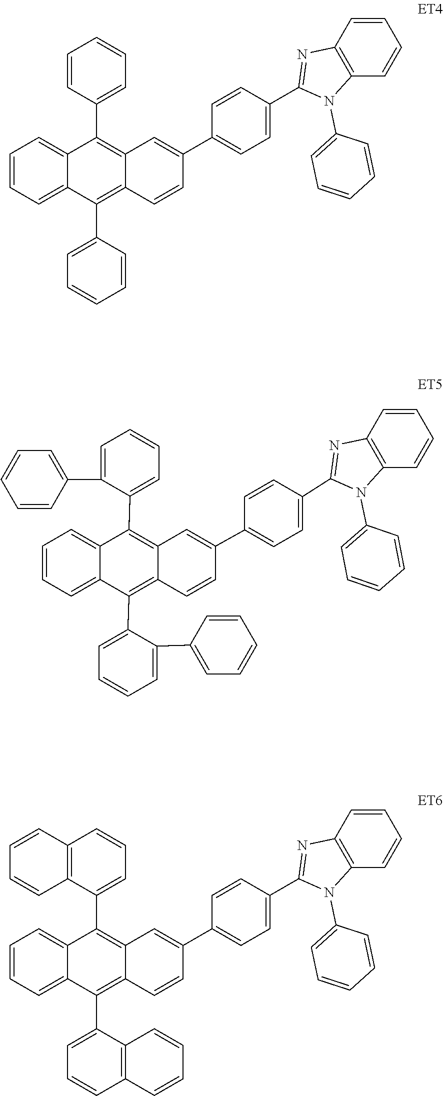 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

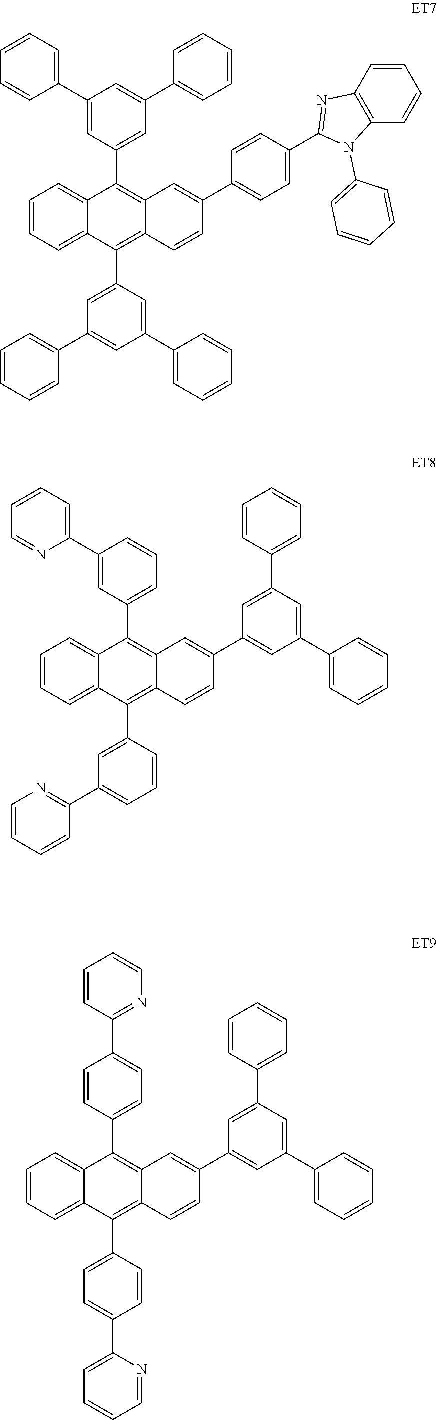 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

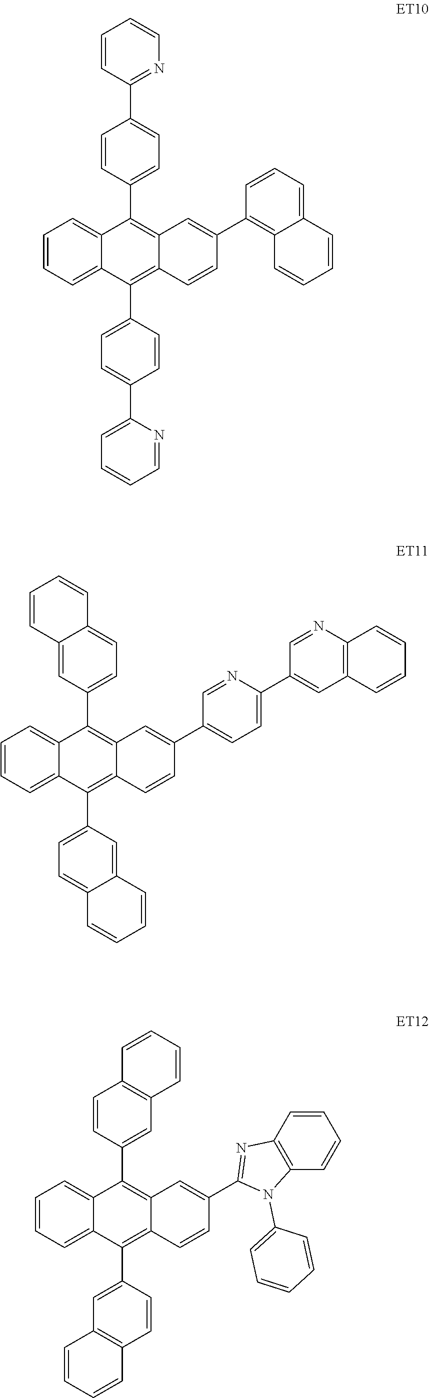 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

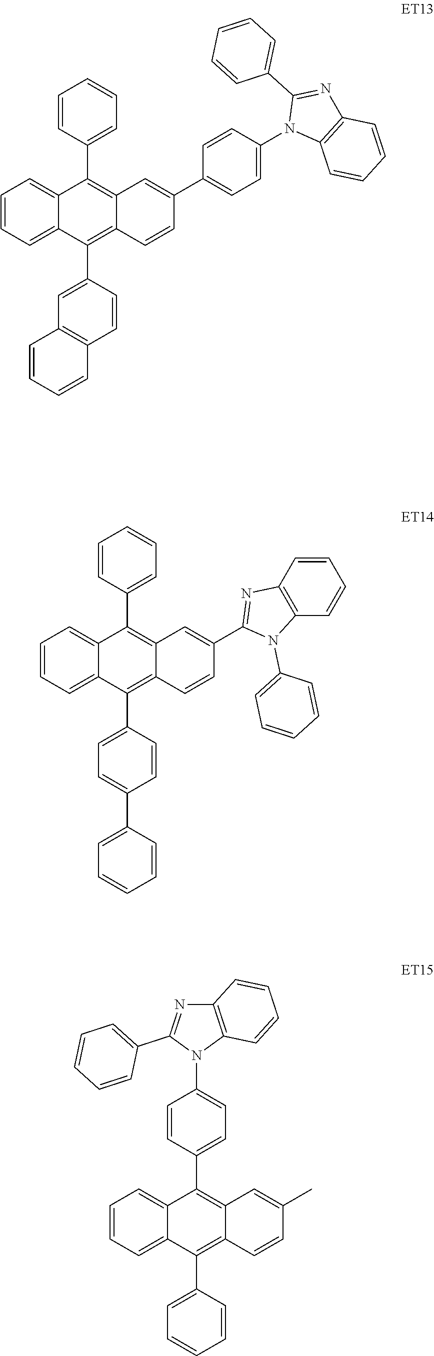 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

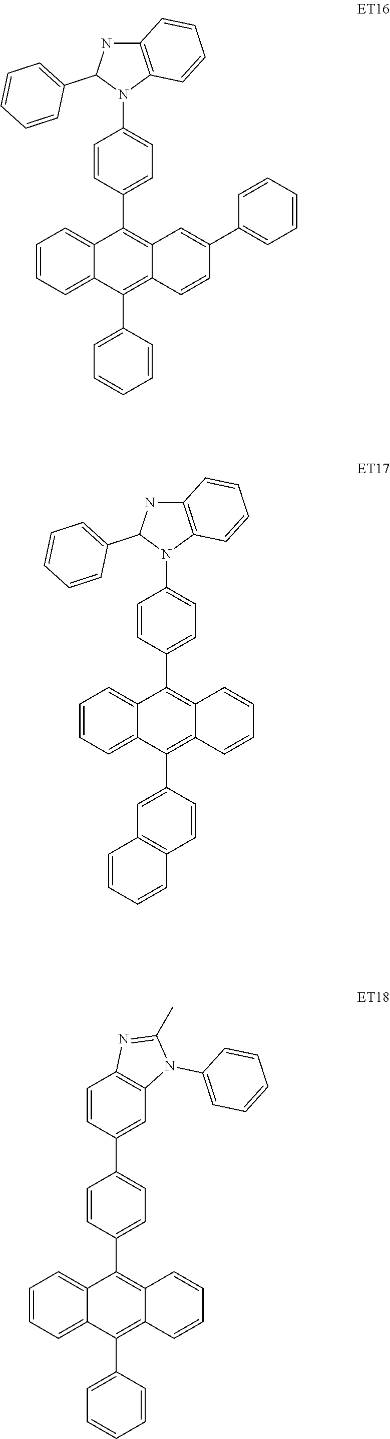

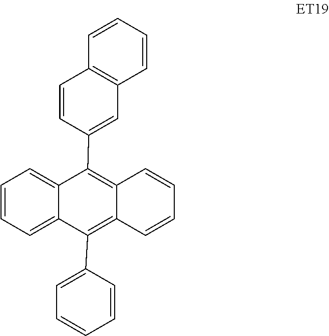 [SMILES: c1ccc(-c2c3ccccc3c(-c3ccc4ccccc4c3)c3ccccc23)cc1]

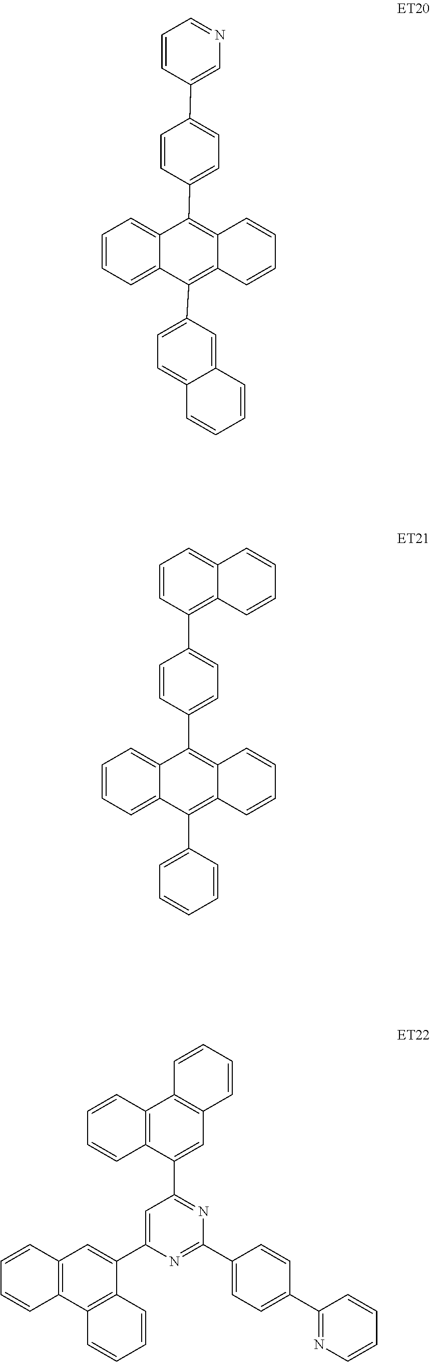

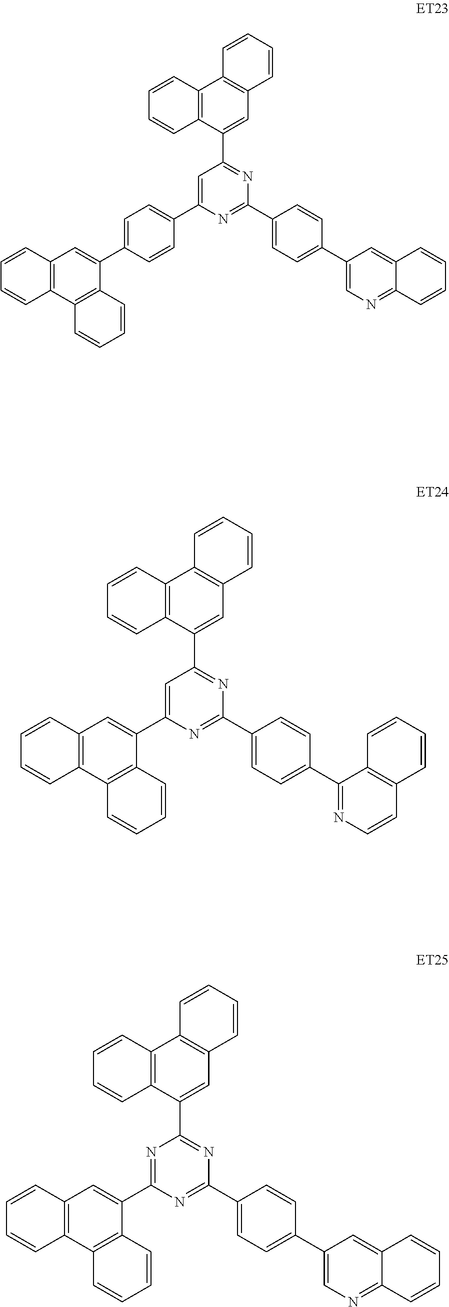 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

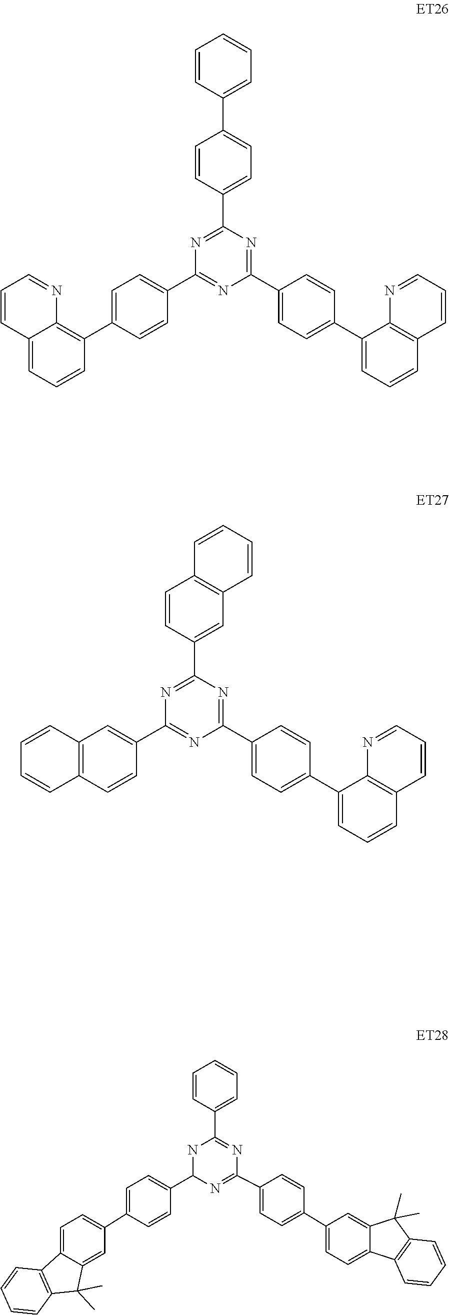

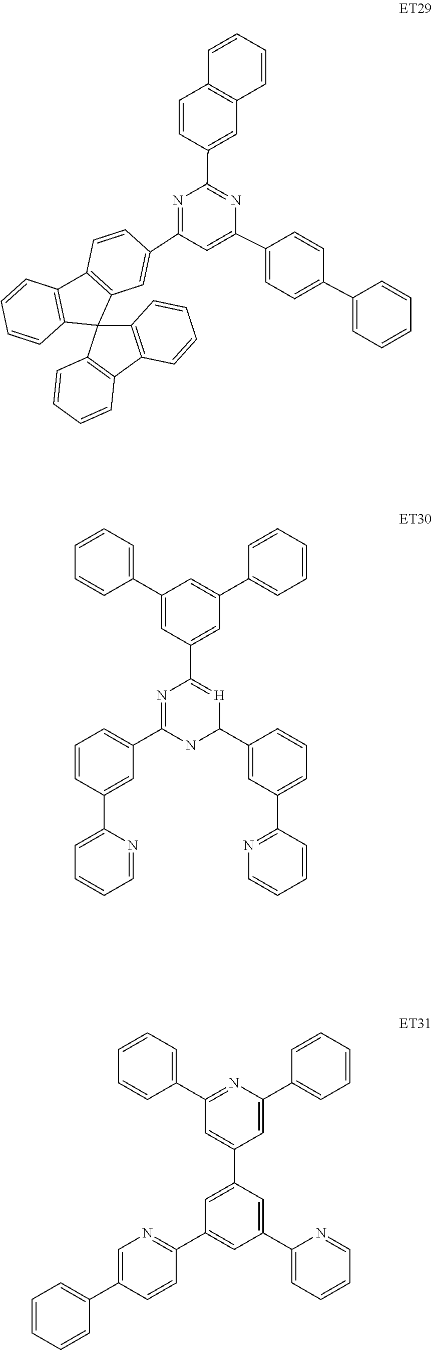

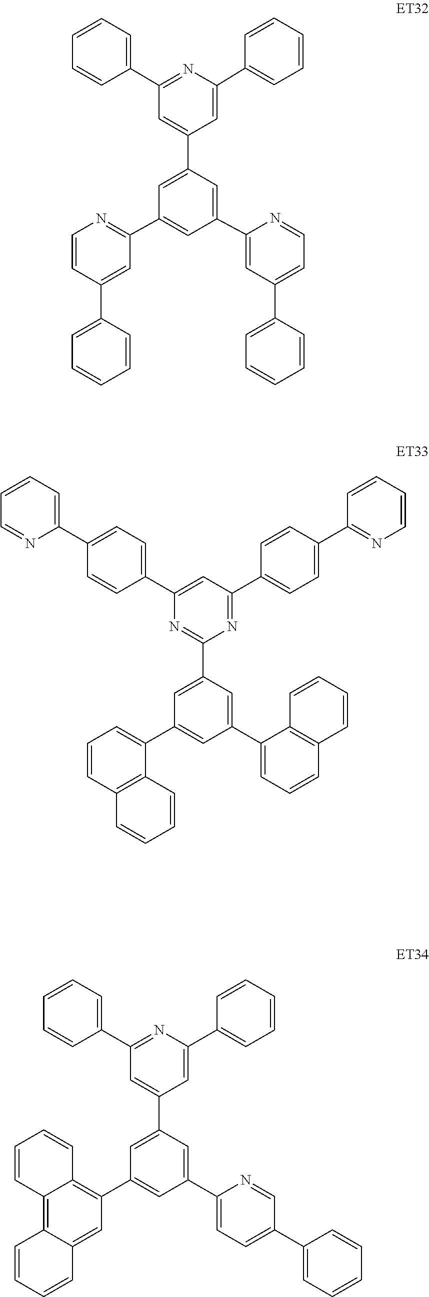 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

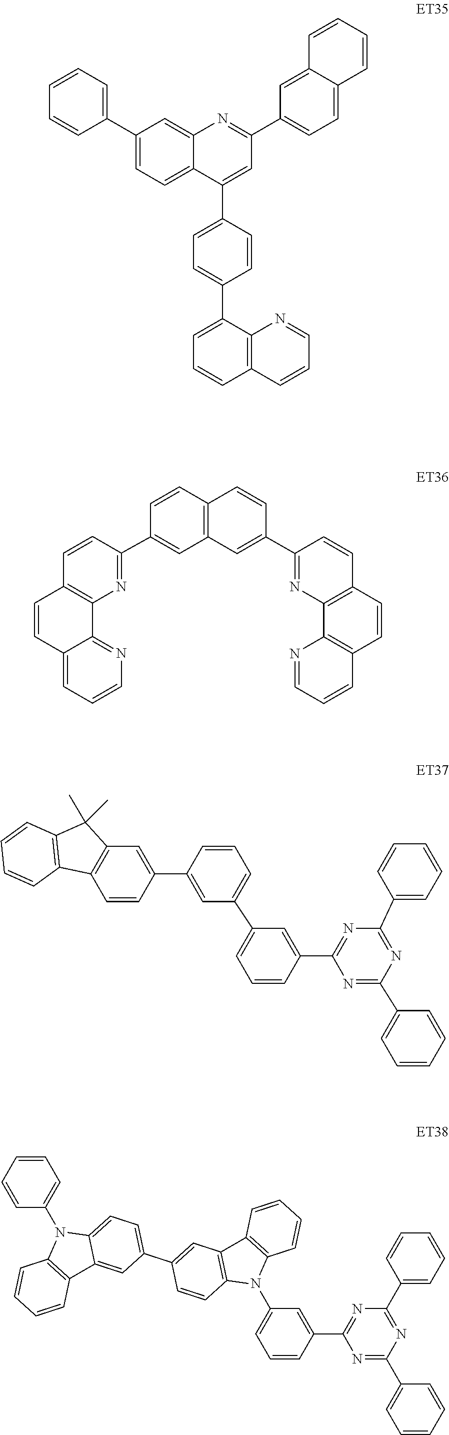 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

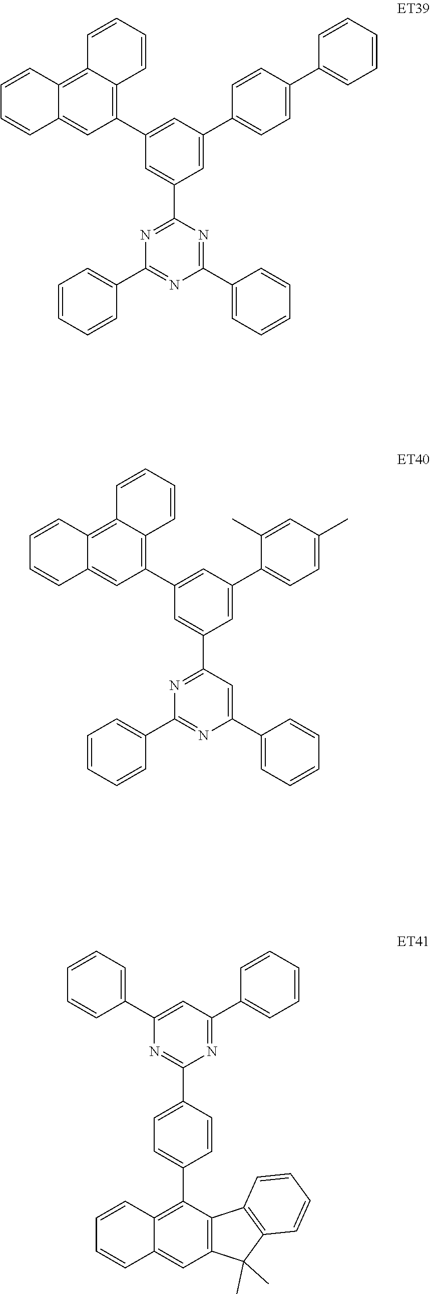 [SMILES: c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1]

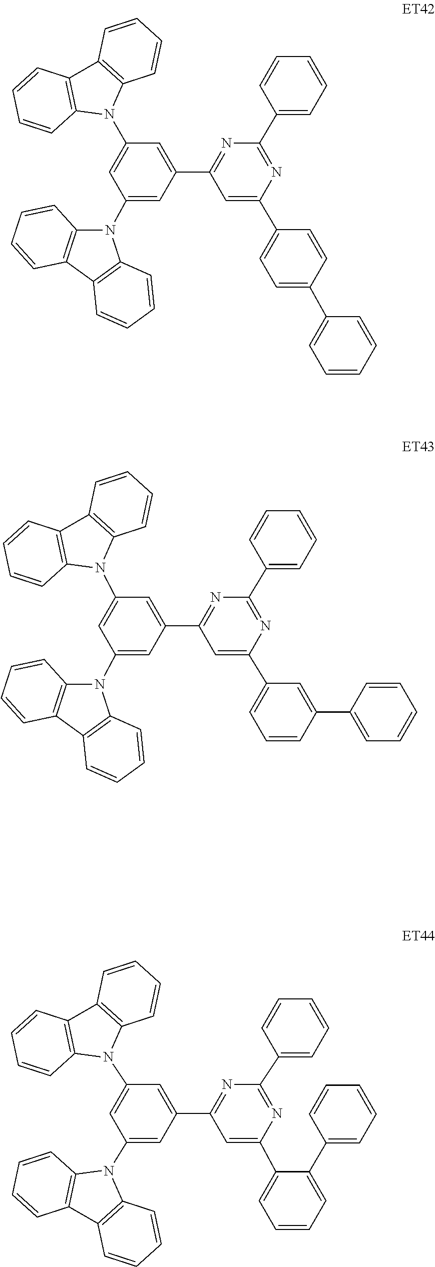 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1]

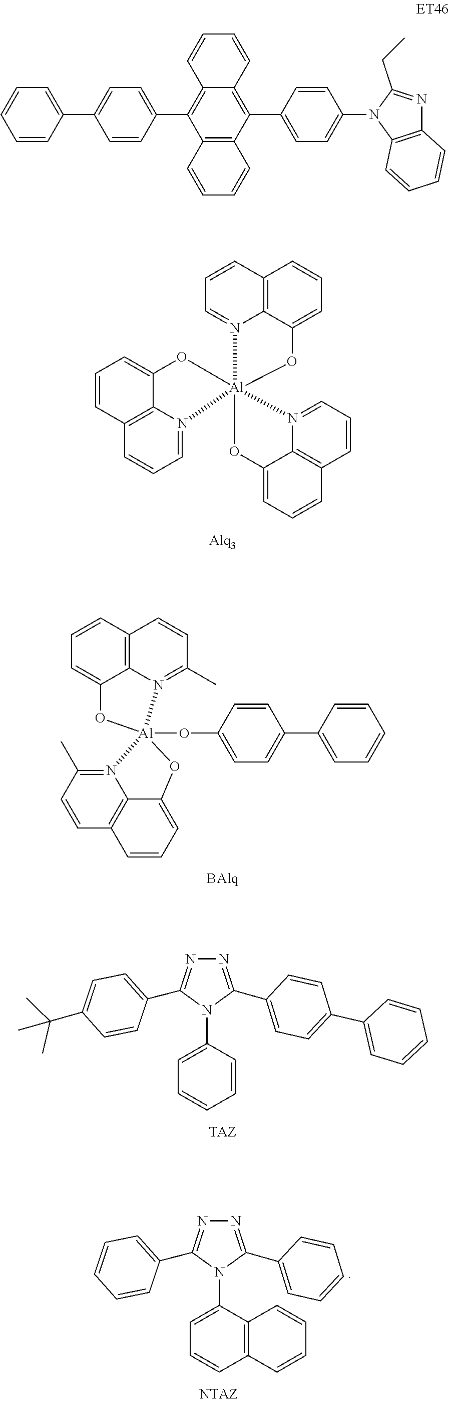

A thickness of the electron transport region may be about 50 Å to about 5,000 Å, for example, about 100 Å to about 4,000 Å. When the electron transport region includes a buffer layer, a hole blocking layer, an electron transport layer, or any combination thereof, thickness of the buffer layer and the hole blocking layer may each independently be about 20 Å to about 1,000 Å, for example, about 30 Å to about 300 Å, and a thickness of the electron transport layer may be about 100 Å to about 1,000 Å, for example, about 150 Å to about 500 Å. When the thicknesses of the buffer layer, the hole blocking layer, and/or the electron transport layer are within the ranges described above, satisfactory electron-transporting characteristics may be obtained without a substantial increase in driving voltage.

The electron transport region (for example, the electron transport layer in the electron transport region) may further include, in addition to the materials described above, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) or ET-D2:

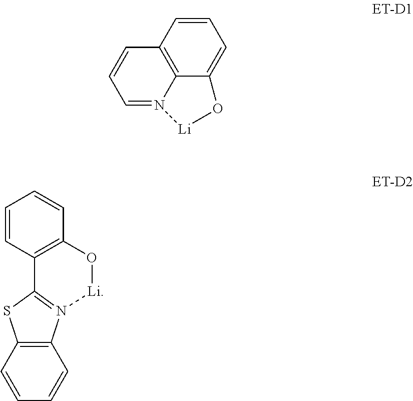

The electron transport region may include an electron injection layer that facilitates electron injection. The electron injection layer may be in direct contact with the second electrode 170.

The electron injection layer may have: i) a single-layered structure consisting of a single layer consisting of a single material, ii) a single-layered structure consisting of a single layer consisting of a plurality of different materials, or iii) a multilayer structure including a plurality of layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (for example, fluorides, chlorides, bromides, or iodides), or tellurides of the alkali metal, the alkaline earth metal, and the rare earth metal, or any combination thereof.

The alkali metal-containing compound may include alkali metal oxides, such as Li₂O, Cs₂O, or K₂O, alkali metal halides, such as LiF, NaF, CsF, KF, LiI, NaI, CsI, or KI, or any combination thereof. The alkaline earth metal-containing compound may include an alkaline earth metal compound, such as BaO, SrO, CaO, BaₓSr₁₋ₓO (x is a real number satisfying the condition of 0<x<1), BaₓCa₁₋ₓO (x is a real number satisfying the condition of 0<x<1), and/or the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In an embodiment, the rare earth metal-containing compound may include lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and Lu₂Te₃.

The alkali metal complex, the alkaline earth-metal complex, and the rare earth metal complex may include i) one of an ion of the alkali metal, the alkaline earth metal, and the rare earth metal and ii), as a ligand bonded to the metal ion, for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combination thereof.

The electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In an embodiment, the electron injection layer may further include an organic material (for example, a compound represented by Formula 601).

In an embodiment, the electron injection layer may include (e.g., consist of):
i) an alkali metal-containing compound (for example, an alkali metal halide);
ii) a) an alkali metal-containing compound (for example, an alkali metal halide); and b) an alkali metal, an alkaline earth metal, a rare earth metal; or
iii) any combination thereof.
   In an embodiment, the electron injection layer may be a KI:Yb co-deposited layer, a RbI:Yb co-deposited layer, and/or the like.

When the electron injection layer further includes an organic material, the alkali metal, alkaline earth metal, rare earth metal, alkali metal-containing compound, alkaline earth metal-containing compound, rare earth metal-containing compound, alkali metal complex, alkaline earth-metal complex, rare earth metal complex, or any combination thereof may be homogeneously or non-homogeneously dispersed in a matrix including the organic material.

A thickness of the electron injection layer may be about 1 Å to about 100 Å, and, for example, about 3 Å to about 90 Å. When the thickness of the electron injection layer is within the range described above, satisfactory electron injection characteristics may be obtained without a substantial increase in driving voltage.

### Second Electrode 170

The second electrode 170 may be disposed above the activation layer 140 or the electron transport region as described above. The second electrode 170 may be a cathode. At this time, as a material for forming the second electrode 170, a metal, an alloy, an electrically conductive compound, or any combination thereof, each having a low work function, may be utilized.

The second electrode 170 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 170 may be a transmissive electrode, a semi-transmissive electrode, or a reflective electrode.

The second electrode 170 may have a single-layered structure or a multilayer structure including a plurality of layers.

### Capping Layer

A first capping layer may be located outside the first electrode 110, and/or a second capping layer may be located outside the second electrode 170.

The first capping layer and/or the second capping layer may prevent or reduce penetration of impurities, such as water or oxygen, to the organic photodetector 10, thereby improving reliability of the organic photodetector 10.

Each of the first capping layer and second capping layer may include a material having a refractive index (at 589 nm) of 1.6 or more.

The first capping layer and the second capping layer may each independently be an organic capping layer including an organic material, an inorganic capping layer including an inorganic material, or an organic-inorganic composite capping layer including an organic material and an inorganic material.

At least one of the first capping layer or the second capping layer may each independently include carbocyclic compounds, heterocyclic compounds, amine group-containing compounds, porphyrin derivatives, phthalocyanine derivatives, naphthalocyanine derivatives, alkali metal complexes, alkaline earth metal complexes, or any combination thereof. The carbocyclic compound, the heterocyclic compound, and the amine group-containing compound may be optionally substituted with a substituent containing O, N, S, Se, Si, F, Cl, Br, I, or any combination thereof. In an embodiment, at least one of the first capping layer or the second capping layer may each independently include an amine group-containing compound.

In an embodiment, at least one of the first capping layer or the second capping layer may each independently include a compound represented by Formula 201, a compound represented by Formula 202, or any combination thereof.

In an embodiment, at least one of the first capping layer or the second capping layer may each independently include at least one of Compounds HT28 to HT33, at least one of Compounds CP1 to CP6, β-NPB, or any combination thereof:

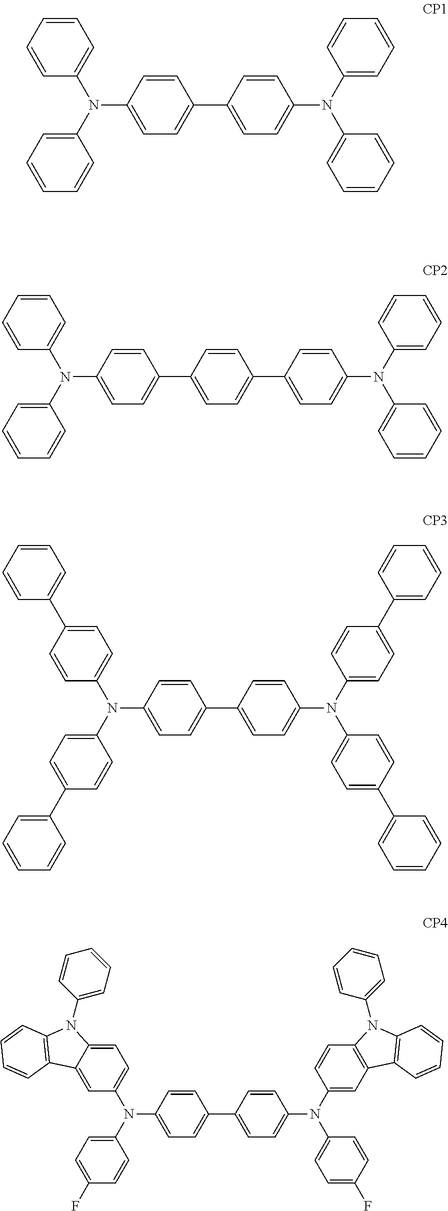 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

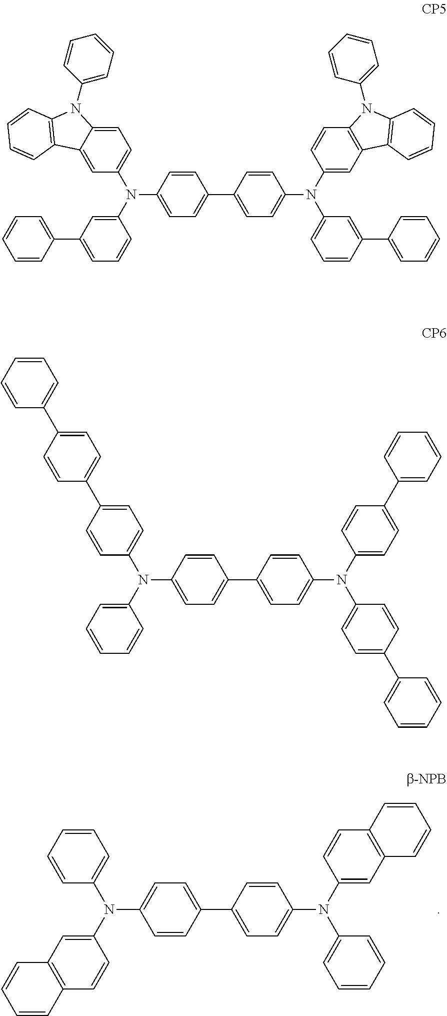 [SMILES: c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### Electronic Apparatus

There may be provided an electronic apparatus including the organic photodetector as described above. In an embodiment, the electronic apparatus may further include a light-emitting device.

Accordingly, the electronic apparatus according to an embodiment includes: a substrate including a photodetection area and an emission area;
an organic photodetector disposed on the photodetection area; and
a light-emitting device disposed on the emission area,
wherein the organic photodetector may include: a first pixel electrode; an opposite electrode facing the first pixel electrode; and a hole transport layer, an optical auxiliary layer, and an activation layer, sequentially arranged between the first pixel electrode and the opposite electrode, the activation layer may include a p-type semiconductor compound and an n-type semiconductor compound, the optical auxiliary layer may include: a first optical auxiliary layer including a first amine compound; and a second optical auxiliary layer including a second amine compound, a HOMO energy absolute value of the first amine compound may be smaller than a HOMO energy absolute value of the second amine compound, and the first optical auxiliary layer may face the first pixel electrode,
the light-emitting device may include: a second pixel electrode; the opposite electrode facing the second pixel electrode; and the hole transport layer, the optical auxiliary layer, and an emission layer, sequentially arranged between the second pixel electrode and the opposite electrode,
the first pixel electrode and the activation layer may be arranged in correspondence with the photodetection area,
the second pixel electrode and the emission layer may be arranged in correspondence with the emission area, and
the hole transport layer, the optical auxiliary layer, and the opposite electrode may be arranged throughout the photodetection area and the emission area.

The hole transport region and the electron transport region may each be the same as described above.

For example, the hole transport layer, the optical auxiliary layer, the buffer layer, the electron transport layer, and the opposite electrode may be arranged throughout the photodetection area and the emission area.

The electronic apparatus may be applied to one or more suitable displays, light sources, lighting, personal computers (for example, a mobile personal computer), mobile phones, digital cameras, electronic diaries, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, one or more suitable measuring instruments, meters (for example, meters for a vehicle, an aircraft, and a vessel), projectors, and/or the like.

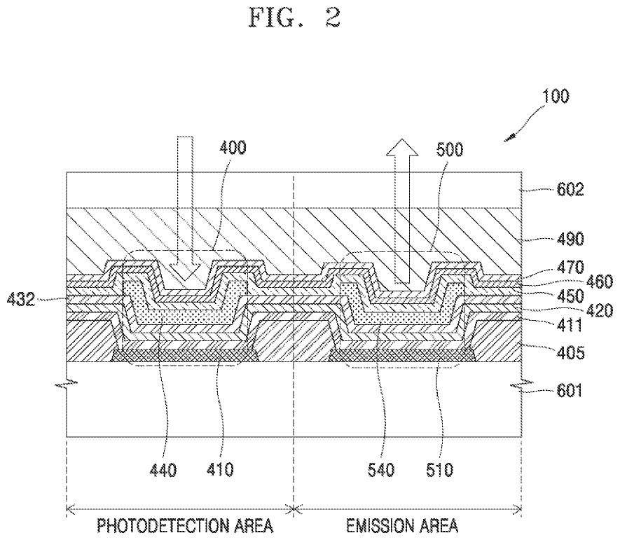

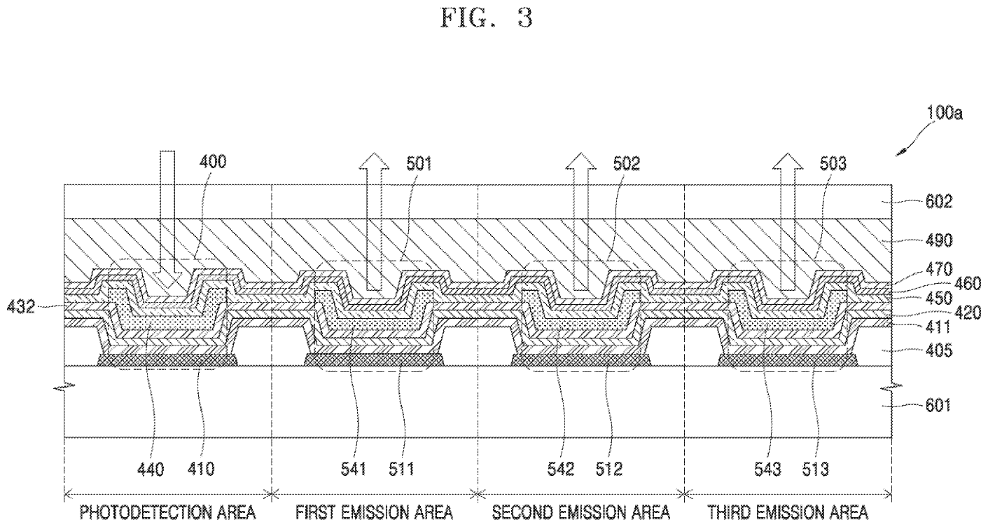

### Description of FIGS. 2 and 3

FIG. 2 is a schematic cross-sectional view of an electronic apparatus 100 according to an embodiment.

Referring to FIG. 2, the electronic apparatus 100 may include an organic photodetector 400 and a light-emitting device 500, arranged between a substrate 601 and a substrate 602.

The substrate 601 and the substrate 602 may be a flexible substrate, a glass substrate, or a metal substrate. A buffer layer and a thin-film transistor may be disposed on the substrate 601.

The buffer layer may prevent or reduce penetration of impurities through the substrate 601 and provide a flat surface on the substrate 601. The thin-film transistor may be disposed on the buffer layer and may include an activation layer, a gate electrode, a source electrode, and a drain electrode.

Such a thin-film transistor may be electrically connected to the light-emitting device 500 to drive the light-emitting device 500. One of the source electrode and drain electrode may be electrically connected to a second pixel electrode 510 of the light-emitting device 500.

Another thin-film transistor may be electrically connected to the organic photodetector 400. One of the source electrode or the drain electrode may be electrically connected to a first pixel electrode 410 of the organic photodetector 400.

The organic photodetector 400 may include the first pixel electrode 410, a hole transport layer 411, a first optical auxiliary layer 420, a second optical auxiliary layer 432, an activation layer 440, a buffer layer 450, an electron transport layer 460, and an opposite electrode 470.

In an embodiment, the first pixel electrode 410 may be an anode, and the opposite electrode 470 may be a cathode. In other words, as the organic photodetector 400 is driven by applying a reverse bias between the first pixel electrode 410 and the opposite electrode 470, the electronic apparatus 100 may detect light incident onto the organic photodetector 400, generate charges, and extract the charges as a current.

The light-emitting device 500 may include the second pixel electrode 510, the hole transport layer 411, the first optical auxiliary layer 420, the second optical auxiliary layer 432, an emission layer 540, the buffer layer 450, the electron transport layer 460, and the opposite electrode 470.

In an embodiment, the second pixel electrode 510 may be an anode, and the opposite electrode 470 may be a cathode. In other words, in the light-emitting device 500, holes injected from the second pixel electrode 510 and electrons injected from the opposite electrode 470 recombine in the emission layer 540 to generate excitons, which generate light by changing from an excited state to a ground state.

The first pixel electrode 410 and the second pixel electrode 510 may each be the same as described in connection with the first electrode 110 in the present specification.

A pixel-defining film 405 may be formed at edge portions of the first pixel electrode 410 and the second pixel electrode 510. The pixel-defining film 405 may define a pixel area and may electrically insulate the first pixel electrode 410 and the second pixel electrode 510. The pixel-defining film 405 may include, for example, one or more suitable organic insulating materials (e.g., a silicon-based material), inorganic insulating materials, or organic/inorganic composite insulating materials. The pixel-defining film 405 may be a transmissive film that transmits visible light or a blocking film that blocks visible light.

The hole transport layer 411 and the optical auxiliary layer, which are common layers, are formed sequentially on the first pixel electrode 410 and the second pixel electrode 510. The hole transport layer 411 and the optical auxiliary layer may each be the same as described in the present specification.

The activation layer 440 is formed above the second optical auxiliary layer 432 in correspondence with the photodetection area. The activation layer 440 is the same as described in the present specification.

The emission layer 540 is formed above the second optical auxiliary layer 432 in correspondence with the emission area. In an embodiment, the light-emitting device 500 may further include, between the second pixel electrode 510 and the emission layer 540, an electron blocking layer arranged in correspondence with the emission area.

As common layers for the entirety of the photodetection area and a first emission area, the buffer layer 450, the electron transport layer 460, and the opposite electrode 470 are sequentially formed above the activation layer 440 and the emission layer 540. The buffer layer 450, the electron transport layer 460, and the opposite electrode 470 may each be the same as described in connection with the buffer layer, the electron transport layer, and the second electrode 170 in the present specification.

Each of the hole transport layer 411, the first optical auxiliary layer 420, the second optical auxiliary layer 432, the buffer layer 450, and the electron transport layer 460 may be arranged throughout the photodetection area and the emission area.

As such, in the electronic apparatus 100, because a common layer is arranged in the organic photodetector 400 and the light-emitting device 500, a manufacturing process may be reduced, and a functional layer material utilized in the light-emitting device 500 may also be utilized in the organic photodetector 400 such that the organic photodetector 400 may be arranged in-pixel in the electronic apparatus 100.

In an embodiment, an electron injection layer may be further included between the electron transport layer 460 and the opposite electrode 470.

A capping layer may be disposed on the opposite electrode 470. A material for forming the capping layer may include the organic material and/or the inorganic material described herein. The capping layer may serve to protect the organic photodetector 400 and the light-emitting device 500 and to assist effective emission of light generated from the light-emitting device 500.

An encapsulation portion 490 may be disposed on the capping layer. The encapsulation portion 490 may be disposed on the organic photodetector 400 and the light-emitting device 500 to protect the organic photodetector 400 and the light-emitting device 500 from water or oxygen. The encapsulation portion 490 may include: an inorganic film including silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyethylene sulfonate, polyoxy methylene, poly aryllate, hexamethyl disiloxane, an acrylic resin (e.g., polymethyl methacrylate, polyacrylic acid, and/or the like), an epoxy-based resin (e.g., aliphatic glycidyl ether (AGE) and/or the like), or any combination thereof; or a combination of the inorganic film and the organic film.

The electronic apparatus 100 may be, for example, a display apparatus. The electronic apparatus 100 includes both (e.g., simultaneously) the organic photodetector 400 and the light-emitting device 500, and thus, may be a display apparatus with a light detection function.

In FIG. 2, the electronic apparatus 100 is illustrated as including one light-emitting device 500, but, as shown in FIG. 3, an electronic apparatus 100a according to an embodiment may include the organic photodetector 400, a first light-emitting device 501, a second light-emitting device 502, and a third light-emitting device 503.

Elements illustrated in FIG. 3 may be understood by referring to the descriptions of the electronic apparatus 100.

The first light-emitting device 501 may include a second pixel electrode 511, the hole transport layer 411, the first optical auxiliary layer 420, the second optical auxiliary layer 432, a first emission layer 541, the buffer layer 450, the electron transport layer 460, and the opposite electrode 470.

The second light-emitting device 502 may include a third pixel electrode 512, the hole transport layer 411, the first optical auxiliary layer 420, the second optical auxiliary layer 432, a second emission layer 542, the buffer layer 450, the electron transport layer 460, and the opposite electrode 470.

The third light-emitting device 503 may include a fourth pixel electrode 513, the hole transport layer 411, the first optical auxiliary layer 420, the second optical auxiliary layer 432, a third emission layer 543, the buffer layer 450, the electron transport layer 460, and the opposite electrode 470.

The second pixel electrode 511, the third pixel electrode 512, and the fourth pixel electrode 513 may be arranged in correspondence with a first emission area, a second emission area, and a third emission area, respectively, and may each be the same as described in connection with the first electrode 110 in the present specification.

The first emission layer 541 may be arranged in correspondence with the first emission area and emit first color light, the second emission layer 542 may be arranged in correspondence with the second emission area and emit second color light, and the third emission layer 543 may be arranged in correspondence with the third emission area and emit third color light.

A maximum emission wavelength of the first color light, a maximum emission wavelength of the second color light, and a maximum emission wavelength of the third color light may be identical to or different from each other. For example, a maximum emission wavelength of the first color light and a maximum emission wavelength of the second color light may each be longer than a maximum emission wavelength of the third color light.

For example, the first color light may be red light, the second color light may be green light, and the third color light may be blue light, but embodiments are not limited thereto. Therefore, the electronic apparatus 100a may be capable of full-color emission. When a mixed light of the first color light, the second color light, and the third color light is white light, the first color light, the second color light, and the third color light may not be respectively limited to red light, green light, and blue light.

The organic photodetector 400, the first light-emitting device 501, the second light-emitting device 502, and the third light-emitting device 503 may each be a sub-pixel forming a pixel. In an embodiment, one pixel may include at least one organic photodetector 400.

The electronic apparatus 100a may be a display apparatus. Because the electronic apparatus 100a may include the organic photodetector 400, the first light-emitting device 501, the second light-emitting device 502, and the third light-emitting device 503, the electronic apparatus 100a may be a full-color display apparatus having a light detection function.

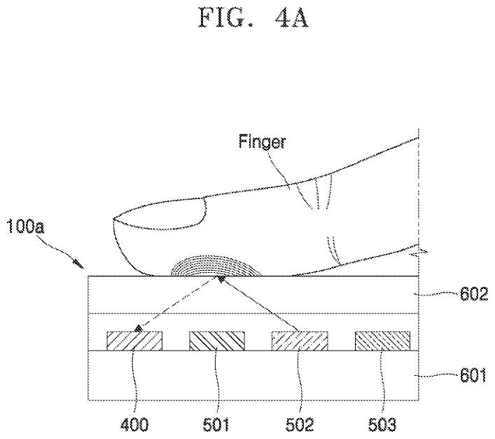

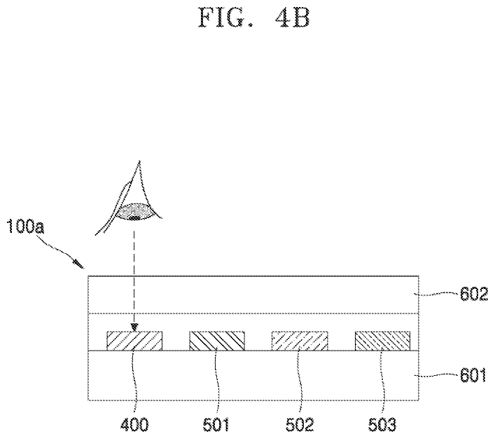

### Description of FIGS. 4A and 4B

In the electronic apparatus 100a shown in FIG. 4A, the organic photodetector 400 and the first to third light-emitting devices 501, 502, and 503 may be arranged between the substrate 601 and the substrate 602.

For example, red light, green light, and blue light may respectively be emitted from the first light-emitting device 501, the second light-emitting device 502, and the third light-emitting device 503.

The electronic apparatus 100a according to an embodiment may have a function of detecting an object being in contact with the electronic apparatus 100a, for example, a fingerprint of a finger. For example, as shown in FIG. 4A, at least some light (e.g., some amount of the light) emitted from the second light-emitting device 502 and reflected by a fingerprint of a user may be re-incident on the organic photodetector 400, and thus, the organic photodetector 400 may detect the reflected light. A ridge in a fingerprint pattern of a finger may adhere to the substrate 602, and thus, the organic photodetector 400 may selectively obtain a fingerprint pattern of the user, for example, image information of a ridge. Although FIG. 4A shows an example in which information of an object being in contact with the electronic apparatus 100a is obtained by utilizing light emitted from the second light-emitting device 502, the same may be applied to case where information is obtained by utilizing light emitted from the first light-emitting device 501 and/or the third light-emitting device 503.

In an embodiment, as shown in FIG. 4B, the electronic apparatus 100a according to an embodiment may detect an object that is not in contact with the electronic apparatus 100a.

### Manufacture Method

The layers constituting the hole transport region, the activation layer, and the layers constituting the electron transport region may be formed in a specific region by utilizing one or more suitable methods such as vacuum deposition, spin coating, casting, Langmuir-Blodgett (LB) deposition, ink-jet printing, laser printing, and/or laser-induced thermal imaging (LITI).

When layers constituting the hole transport region, an activation layer, and layers constituting the electron transport region may each independently be formed by vacuum-deposition, the vacuum-deposition may be performed at a deposition temperature in a range of about 100° C. to about 500° C., at a vacuum degree in a range of about 10⁻⁸ torr to about 10⁻³ torr, and at a deposition rate in a range of about 0.01 Å/sec to about 100 Å/sec, depending on a material to be included in each layer and a structure of each layer to be formed.

### Definition of Terms

The term “C₃-C₆₀ carbocyclic group” as utilized herein refers to a cyclic group consisting of carbon only as a ring-forming atom and having three to sixty carbon atoms, and the term “C₁-C₆₀ heterocyclic group” as utilized herein refers to a cyclic group that has one to sixty carbon atoms and further has, in addition to carbon, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. In an embodiment, the C₁-C₆₀ heterocyclic group has 3 to 61 ring-forming atoms.

The term “cyclic group” as utilized herein may include the C₃-C₆₀ carbocyclic group and the C₁-C₆₀ heterocyclic group.

The term “π electron-rich C₃-C₆₀ cyclic group” as utilized herein refers to a cyclic group that has three to sixty carbon atoms and does not include *—N═*′ as a ring-forming moiety, and the term “π electron-deficient nitrogen-containing C₁-C₆₀ cyclic group” as utilized herein refers to a heterocyclic group that has one to sixty carbon atoms and includes *—N═*′ as a ring-forming moiety.

In an embodiment,
the C₃-C₆₀ carbocyclic group may be i) a group T1 or ii) a condensed cyclic group in which two or more groups T1 are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) a group T2, ii) a condensed cyclic group in which two or more groups T2 are condensed with each other, or iii) a condensed cyclic group in which at least one group T2 and at least one group T1 are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
the π electron-rich C₃-C₆₀ cyclic group may be i) a group T1, ii) a condensed cyclic group in which two or more groups T1 are condensed with each other, iii) a group T3, iv) a condensed cyclic group in which two or more groups T3 are condensed with each other, or v) a condensed cyclic group in which at least one group T3 and at least one group T1 are condensed with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.), and
the π electron-deficient nitrogen-containing C₁-C₆₀ cyclic group may be i) a group T4, ii) a condensed cyclic group in which two or more group T4 are condensed with each other, iii) a condensed cyclic group in which at least one group T4 and at least one group T1 are condensed with each other, iv) a condensed cyclic group in which at least one group T4 and at least one group T3 are condensed with each other, or v) a condensed cyclic group in which at least one group T4, at least one group T1, and at least one group T3 are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
wherein the group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1 ]pentane group, a bicyclo[2.1.1]hexane group, a bicyclo[2.2.2]octane group, or a benzene group,
the group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
the group T3 may be a furan group, a thiophene group, a 1H-pyrrole group, a silole group, or a borole group, and
the group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The term “cyclic group”, “C₃-C₆₀ carbocyclic group”, “C₁-C₆₀ heterocyclic group”, “π electron-rich C₃-C₆₀ cyclic group”, or “π electron-deficient nitrogen-containing C₁-C₆₀ cyclic group” as utilized herein refers to a group condensed to any cyclic group or a polyvalent group (for example, a divalent group, a trivalent group, a tetravalent group, etc.), depending on the structure of a formula in connection with which the terms are utilized. In an embodiment, “a benzene group” may be a benzo group, a phenyl group, a phenylene group, and/or the like, which may be easily understood by those of ordinary skill in the art according to the structure of a formula including the “benzene group.”

Depending on context, a divalent group may refer or be a polyvalent group (e.g., trivalent, tetravalent, etc., and not just divalent) per, e.g., the structure of a formula in connection with which of the terms are utilized.

For example, examples of a monovalent C₃-C₆₀ carbocyclic group and a monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and examples of a divalent C₃-C₆₀ carbocyclic group and a divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as utilized herein refers to a linear or branched aliphatic hydrocarbon monovalent group that has one to sixty carbon atoms, and examples thereof include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as utilized herein refers to a divalent group having the same structure as the C₁-C₆₀ alkyl group.

The term “C₂-C₆₀ alkenyl group” as utilized herein refers to a monovalent hydrocarbon group having at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as utilized herein refers to a divalent group having the same structure as the C₂-C₆₀ alkenyl group.

The term “C₂-C₆₀ alkynyl group” as utilized herein refers to a monovalent hydrocarbon group having at least one carbon-carbon triple bond in the middle or at the terminus of the C₂-C₆₀ alkyl group, and examples thereof include an ethynyl group and a propynyl group. The term “C₂-C₆₀ alkynylene group” as utilized herein refers to a divalent group having the same structure as the C₂-C₆₀ alkynyl group.

The term “C₁-C₆₀ alkoxy group” as utilized herein refers to a monovalent group represented by —OA₁₀₁ (wherein A₁₀₁ is the C₁-C₆₀ alkyl group), and examples thereof include a methoxy group, an ethoxy group, and an isopropyloxy group.

The term “C₃-C₁₀ cycloalkyl group” as utilized herein refers to a monovalent saturated hydrocarbon cyclic group having 3 to 10 carbon atoms, and examples thereof include a cyclopropyl group, a cyclobutyl group, a cyclopentyl group, a cyclohexyl group, a cycloheptyl group, a cyclooctyl group, an adamantyl group, a norbornyl group (or a bicyclo[2.2.1]heptyl group), a bicyclo[1.1.1]pentyl group, a bicyclo[2.1.1 ]hexyl group, and a bicyclo[2.2.2]octyl group. The term “C₃-C₁₀ cycloalkylene group” as utilized herein refers to a divalent group having the same structure as the C₃-C₁₀ cycloalkyl group.

The term “C₁-C₁₀ heterocycloalkyl group” as utilized herein refers to a monovalent cyclic group that further includes, in addition to a carbon atom, at least one heteroatom as a ring-forming atom and has 1 to 10 carbon atoms, and examples thereof include a 1,2,3,4-oxatriazolidinyl group, a tetrahydrofuranyl group, and a tetrahydrothiophenyl group. The term “C₁-C₁₀ heterocycloalkylene group” as utilized herein refers to a divalent group having the same structure as the C₁-C₁₀ heterocycloalkyl group.

The term “C₃-C₁₀ cycloalkenyl group” utilized herein refers to a monovalent cyclic group that has three to ten carbon atoms and at least one carbon-carbon double bond in the ring thereof and no aromaticity, and examples thereof include a cyclopentenyl group, a cyclohexenyl group, and a cycloheptenyl group. The term “C₃-C₁₀ cycloalkenylene group” as utilized herein refers to a divalent group having the same structure as the C₃-C₁₀ cycloalkenyl group.

The term “C₁-C₁₀ heterocycloalkenyl group” as utilized herein refers to a monovalent cyclic group that has, in addition to a carbon atom, at least one heteroatom as a ring-forming atom, 1 to 10 carbon atoms, and at least one carbon-carbon double bond in the cyclic structure thereof. Examples of the C₁-C₁₀ heterocycloalkenyl group include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as utilized herein refers to a divalent group having the same structure as the C₁-C₁₀ heterocycloalkenyl group.

The term “C₆-C₆₀ aryl group” as utilized herein refers to a monovalent group having a carbocyclic aromatic system having six to sixty carbon atoms, and the term “C₆-C₆₀ arylene group” as utilized herein refers to a divalent group having a carbocyclic aromatic system having six to sixty carbon atoms. Examples of the C₆-C₆₀ aryl group include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. When the C₆-C₆₀ aryl group and the C₆-C₆₀ arylene group each include two or more rings, the rings may be condensed with each other.

The term “C₁-C₆₀ heteroaryl group” as utilized herein refers to a monovalent group having a heterocyclic aromatic system that has, in addition to a carbon atom, at least one heteroatom as a ring-forming atom, and 1 to 60 carbon atoms. The term “C₁-C₆₀ heteroarylene group” as utilized herein refers to a divalent group having a heterocyclic aromatic system that has, in addition to a carbon atom, at least one heteroatom as a ring-forming atom, and 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the rings may be condensed with each other.

The term “monovalent non-aromatic condensed polycyclic group” as utilized herein refers to a monovalent group having two or more rings condensed with each other, only carbon atoms (for example, having 8 to 60 carbon atoms) as ring-forming atoms, and non-aromaticity in its molecular structure when considered as a whole. Examples of the monovalent non-aromatic condensed polycyclic group include an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as utilized herein refers to a divalent group having the same structure as a monovalent non-aromatic condensed polycyclic group.

The term “monovalent non-aromatic condensed heteropolycyclic group” as utilized herein refers to a monovalent group having two or more rings condensed with each other, at least one heteroatom, in addition to carbon atoms (for example, including 1 to 60 carbon atoms), as a ring-forming atom, and non-aromaticity in its molecular structure when considered as a whole. Examples of the monovalent non-aromatic condensed heteropolycyclic group include a 9,9-dihydroacridinyl group and a 9H-xanthenyl group. The term “divalent non-aromatic condensed heteropolycyclic group” as utilized herein refers to a divalent group having the same structure as a monovalent non-aromatic condensed heteropolycyclic group.

The term “C₆-C₆₀ aryloxy group” as utilized herein indicates —OA₁₀₂ (wherein A₁₀₂ is the C₆-C₆₀ aryl group), and the term “C₆-C₆₀ arylthio group” as utilized herein indicates —SA₁₀₃ (wherein A₁₀₃ is the C₆-C₆₀ aryl group).

The term “C₇-C₆₀ arylalkyl group” as utilized herein refers to —A₁₀₄A₁₀₅ (where A₁₀₄ may be a C₁-C₅₄ alkylene group, and A₁₀₅ may be a C₆-C₅₉ aryl group), and the term “C₂-C₆₀ heteroarylalkyl group” utilized herein refers to —A₁₀₆A₁₀₇ (where A₁₀₆ may be a C₁-C₅₉ alkylene group, and A₁₀₇ may be a C₁-C₅₉ heteroaryl group). R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q31), —S(═O)₂(Q31), or —P(═O)(Q₃₁)(Q₃₂).

Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

The term “hetero atom” as utilized herein refers to any atom other than a carbon atom. Examples of the heteroatom include O, S, N, P, Si, B, Ge, Se, or any combination thereof.

The term “the third-row transition metal” as utilized herein includes hafnium (Hf), tantalum (Ta), tungsten (W), rhenium (Re), osmium (Os), iridium (Ir), platinum (Pt), gold (Au), and/or the like.

The term “Ph” as utilized herein refers to a phenyl group, the term “Me” as utilized herein refers to a methyl group, the term “Et” as utilized herein refers to an ethyl group, the term “ter-Bu” or “But” as utilized herein refers to a tert-butyl group, and the term “OMe” as utilized herein refers to a methoxy group.

The term “biphenyl group” as utilized herein refers to “a phenyl group that is substituted with a phenyl group.” In other words, the “biphenyl group” is a substituted phenyl group having a C₆-C₆₀ aryl group as a substituent.

The term “terphenyl group” as utilized herein refers to “a phenyl group that is substituted with a biphenyl group”. The “terphenyl group” is a substituted phenyl group having, as a substituent, a C₆-C₆₀ aryl group that is substituted with a C₆-C₆₀ aryl group.

### EXAMPLES

### Comparative Example 1

An ITO glass substrate (anode) was cut to a size of 50 mm×50 mm×0.5 mm, sonicated in isopropyl alcohol and pure water for 10 minutes in each solvent, and cleaned by irradiation of ultraviolet rays and exposure of ozone thereto for 10 minutes. Then, the glass substrate was mounted to a vacuum-deposition apparatus. HT3 was vacuum-deposited on the anode to form a hole transport layer having a thickness of 1,250 Å.

Compound D and p-dopant HAT-CN were co-deposited on the hole transport layer to form a first optical auxiliary layer having a thickness of 100 Å (doping concentration: 1 volume %), and then Compound D was deposited thereon to form a second optical auxiliary layer having a thickness of 100 Å.

SubPC having a thickness of 200 Å and a C60 fullerene having a thickness of 250 Å were sequentially deposited on the second optical auxiliary layer to form an activation layer.

Next, BAlq was vacuum-deposited thereon to form a buffer layer having a thickness of 50 Å, and ET1 was vacuum-deposited on the buffer layer to form an electron transport layer having a thickness of 300 Å.

LiF was vacuum-deposited on the electron transport layer to form an electron injection layer having a thickness of 10 Å, and then MgAg having a thickness of 100 Å was sequentially deposited thereon to form a cathode, thereby completing manufacture of an organic photodetector.

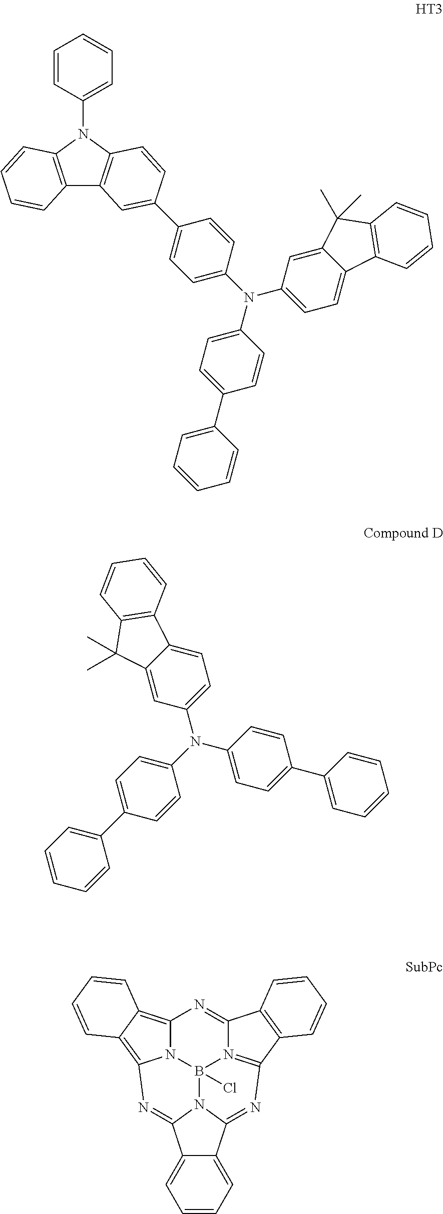

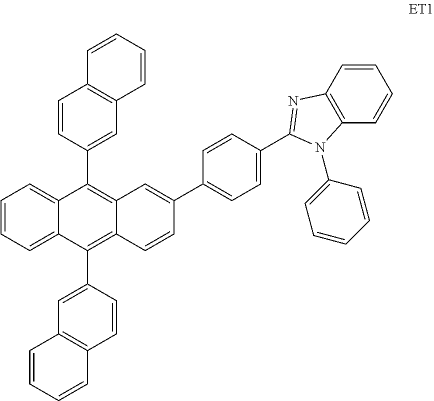 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

### Comparative Example 2

An organic photodetector was manufactured in substantially the same manner as in Comparative Example 1, except that Compound D was deposited on the hole transport layer to form a single optical auxiliary layer having a thickness of 200 Å.

### Comparative Example 3

An organic photodetector was manufactured in substantially the same manner as in Comparative Example 1, except that Compound E was deposited on the hole transport layer to form a single optical auxiliary layer having a thickness of 200 Å.

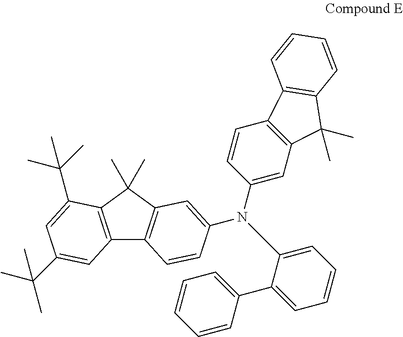 [SMILES: CC(C)(C)c1cc2c(c(C(C)(C)C)c1)C(C)(C)c1cc(N(c3ccc4c(c3)C(C)(C)c3ccccc3-4)c3ccccc3-c3ccccc3)ccc1-2]

### Comparative Example 4

An organic photodetector was manufactured in substantially the same manner as in Comparative Example 1, except that Compound F was deposited on the hole transport layer to form a single optical auxiliary layer having a thickness of 200 Å.

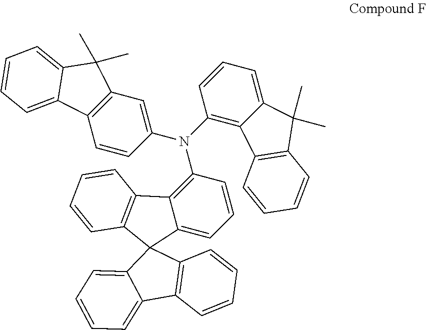 [SMILES: CC1(C)c2ccccc2-c2ccc(N(c3cccc4c3-c3ccccc3C4(C)C)c3cccc4c3-c3ccccc3C43c4ccccc4-c4ccccc43)cc21]

### Example 1

An organic photodetector was manufactured in substantially the same manner as in Comparative Example 1, except that Compound E (HOMO energy value=−5.15 eV) was deposited on the hole transport layer to form a first optical auxiliary layer having a thickness of 100 Å, and then Compound F (HOMO energy value=−5.30 eV) was deposited thereon to form a second optical auxiliary layer having a thickness of 100 Å.

### Comparative Example 5

An organic photodetector was manufactured in substantially the same manner as in Comparative Example 1, except that Compound F (HOMO energy value=−5.30 eV) was deposited on the hole transport layer to form a first optical auxiliary layer having a thickness of 100 Å, and then Compound E (HOMO energy value=−5.15 eV) was deposited thereon to form a second optical auxiliary layer having a thickness of 100 Å.

### Comparative Example 6

An ITO glass substrate (anode) was cut to a size of 50 mm×50 mm×0.5 mm, sonicated in isopropyl alcohol and pure water for 10 minutes in each solvent, and cleaned by irradiation of ultraviolet rays and exposure of ozone thereto for 10 minutes. Then, the glass substrate was mounted to a vacuum-deposition apparatus. HT3 was vacuum-deposited on the anode to form a hole transport layer having a thickness of 1,250 Å.

Compound D and p-dopant HAT-CN were co-deposited on the hole transport layer to form a first optical auxiliary layer having a thickness of 100 Å (doping concentration: 1 volume %), and then Compound D was deposited thereon to form a second optical auxiliary layer having a thickness of 100 Å.

Compound A was deposited on the second optical auxiliary layer to a thickness of 200 Å, and then Compounds B and C were co-deposited thereon (at a weight ratio of 5:5) to a thickness of 250 Å, to thereby form an activation layer.

Next, BAlq was vacuum-deposited thereon to form a buffer layer having a thickness of 50 Å, and ET1 was vacuum-deposited on the buffer layer to form an electron transport layer having a thickness of 300 Å.

LiF was vacuum-deposited on the electron transport layer to form an electron injection layer having a thickness of 10 Å, and then MgAg having a thickness of 100 Å was sequentially deposited thereon to form a cathode, thereby completing manufacture of an organic photodetector.

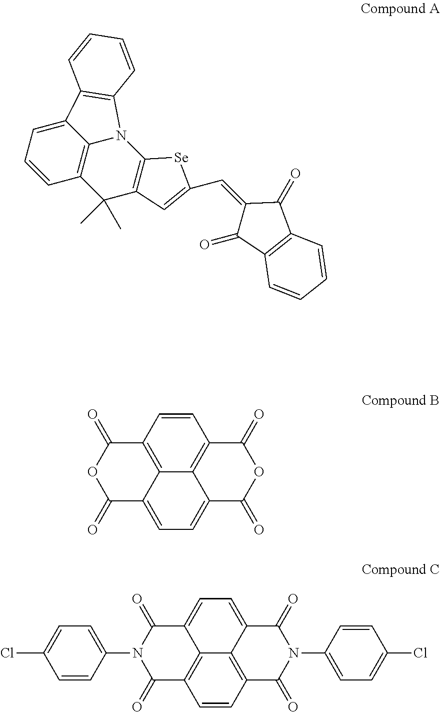 [SMILES: CC1(C)c2cc(C=C3C(=O)c4ccccc4C3=O)[se]c2-n2c3ccccc3c3cccc1c32 ; O=C1OC(=O)c2ccc3c4c(ccc1c24)C(=O)OC3=O ; O=C1c2ccc3c4c(ccc(c24)C(=O)N1c1ccc(Cl)cc1)C(=O)N(c1ccc(Cl)cc1)C3=O]

### Comparative Example 7

An organic photodetector was manufactured in substantially the same manner as in Comparative Example 6, except that Compound D was deposited on the hole transport layer to form a single optical auxiliary layer having a thickness of 200 Å.

### Comparative Example 8

An organic photodetector was manufactured in substantially the same manner as in Comparative Example 6, except that Compound E was deposited on the hole transport layer to form a single optical auxiliary layer having a thickness of 200 Å.

### Comparative Example 9

An organic photodetector was manufactured in substantially the same manner as in Comparative Example 6, except that Compound F was deposited on the hole transport layer to form a single optical auxiliary layer having a thickness of 200 Å.

### Example 2

An organic photodetector was manufactured in substantially the same manner as in Comparative Example 6, except that Compound E (HOMO energy value=−5.15 eV) was deposited on the hole transport layer to form a first optical auxiliary layer having a thickness of 100 Å, and then Compound F (HOMO energy value=−5.30 eV) was deposited thereon to form a second optical auxiliary layer having a thickness of 100 Å.

### Comparative Example 10

An organic photodetector was manufactured in substantially the same manner as in Comparative Example 6, except that Compound F (HOMO energy value=−5.30 eV) was deposited on the hole transport layer to form a first optical auxiliary layer having a thickness of 100 Å, and then Compound E (HOMO energy value=−5.15 eV) was deposited thereon to form a second optical auxiliary layer having a thickness of 100 Å.

External quantum efficiency (EQE) at a wavelength of 530 nm, which is a peak wavelength of each of the organic photodetectors manufactured in Comparative Examples 1 to 10 and Examples 1 and 2, was measured, and results thereof are shown in Table 1.

TABLE 1

| | EQE(%) @530 nm |
|---|---|
| Comparative Example 1 | 24.5 |
| Comparative Example 2 | 19.5 |
| Comparative Example 3 | 18.7 |
| Comparative Example 4 | 19.3 |
| Example 1 | 24.0 |
| Comparative Example 5 | 8.7 |
| Comparative Example 6 | 42.5 |
| Comparative Example 7 | 36.5 |
| Comparative Example 8 | 36.8 |
| Comparative Example 9 | 36.3 |
| Example 2 | 42.0 |
| Comparative Example 10 | 12.5 |

Referring to Table 1, it was found that in substantially the same device structure, Example 1 exhibited better external quantum efficiency than Comparative Examples 2 to 5, and Example 2 exhibited better external quantum efficiency than Comparative Examples 7 to 10.

Regarding only the organic photodetector, Comparative Example 1 exhibited better efficiency than Example 1, but the organic photodetector of Comparative Example 1 had a lateral leakage issue occurring between an OLED pixel and an OPD pixel.

As a result of manufacturing electronic apparatuses with Comparative Example 1 and Example 1, each including a green organic light-emitting device as shown in FIG. 2, and comparing efficiencies thereof, it was found that the electronic apparatus with Example 1 exhibited better efficiency than the electronic apparatus with Comparative Example 1.

Likewise, regarding only the organic photodetector, Comparative Example 6 exhibited better efficiency than Example 2, but the organic photodetector of

Comparative Example 6 had a lateral leakage issue occurring between an OLED pixel and an OPD pixel. As a result of manufacturing electronic apparatuses with Comparative Example 6 and Example 2, each including a green organic light-emitting device as shown in FIG. 2, and comparing efficiencies thereof, it was found that the electronic apparatus with Example 2 exhibited better efficiency than the electronic apparatus with Comparative Example 6.

The organic photodetector according to an embodiment has excellent or suitable efficiency.

The apparatus, device and/or any other relevant devices or components according to embodiments of the present invention described herein may be implemented utilizing any suitable hardware, firmware (e.g. an application-specific integrated circuit), software, or a combination of software, firmware, and hardware. For example, the various components of the apparatus may be formed on one integrated circuit (IC) chip or on separate IC chips. Further, the various components of the apparatus may be implemented on a flexible printed circuit film, a tape carrier package (TCP), a printed circuit board (PCB), or formed on one substrate. Further, the various components of the apparatus may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the present invention.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. An organic photodetector comprising:
a first electrode;
a second electrode facing the first electrode; and
an activation layer and an optical auxiliary layer, the activation layer and the optical auxiliary layer being between the first electrode and the second electrode,
wherein the activation layer comprises a p-type semiconductor compound and an n-type semiconductor compound,
the optical auxiliary layer comprises: a first optical auxiliary layer comprising a first amine compound; and a second optical auxiliary layer comprising a second amine compound,
a highest occupied molecular orbital (HOMO) energy absolute value of the first amine compound is smaller than a HOMO energy absolute value of the second amine compound, and
the first optical auxiliary layer faces the first electrode.

2. The organic photodetector of claim 1, wherein the activation layer and the optical auxiliary layer are in contact with each other.

3. The organic photodetector of claim 1, wherein the activation layer and the second optical auxiliary layer are in contact with each other.

4. The organic photodetector of claim 1, wherein the activation layer comprises a layer comprising the p-type semiconductor compound and a layer comprising the n-type semiconductor compound, and
the layer comprising the p-type semiconductor compound is in contact with the second optical auxiliary layer.

5. The organic photodetector of claim 1, wherein the HOMO energy absolute value of the first amine compound is about 5.00 eV or more.

6. The organic photodetector of claim 1, wherein the HOMO energy absolute value of the second amine compound is about 5.20 eV or more.

7. The organic photodetector of claim 1, wherein the first optical auxiliary layer and the second optical auxiliary layer are in contact with each other.

8. The organic photodetector of claim 1, wherein the first electrode is an anode,
the second electrode is a cathode,
the organic photodetector further comprises a hole transport region arranged between the optical auxiliary layer and the first electrode, and
the hole transport region comprises a hole injection layer, a hole transport layer, an electron blocking layer, or any combination thereof.

9. The organic photodetector of claim 1, wherein the first electrode is an anode,
the second electrode is a cathode,
the organic photodetector further comprises an electron transport region arranged between the activation layer and the second electrode, and
the electron transport region comprises a buffer layer, a hole blocking layer, an electron transport layer, an electron injection layer, or any combination thereof.

10. The organic photodetector of claim 1, wherein the p-type semiconductor compound comprises boron subphthalocyanine chloride (SubPc), copper(II)phthalocyanine (CuPc), tetraphenyldibenzoperiflanthene (DBP), a compound represented by Formula 1, or any combination thereof: 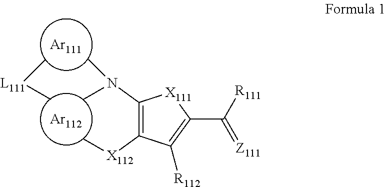
wherein, in Formula 1,
Ar₁₁₁ and Ar₁₁₂ are each independently a C₆-C₃₀ arylene group that is unsubstituted or substituted with at least one R₁₀ₐ or a C₃-C₃₀ heteroarylene group that is unsubstituted or substituted with at least one R₁₀ₐ,
X₁₁₁ is selected from —Se—, —Te—, —S(═O)—, —S(═O)₂—, —N(Q₁₁₁)-, —B(Q₁₁₁)-, —C(Q₁₁₁)(Q₁₁₂)-, —Si(Q₁₁₁)(Q₁₁₂)-, and —Ge(Q₁₁₁)(Q₁₁₂)-,
X₁₁₂ and L₁₁₁ are each independently selected from —O—, —S—, —Se—, —Te—, —S(═O)—, —S(═O)₂—, —N(Q₁₁₁)-, —B(Q₁₁₁)-, —C(Q₁₁₁)(Q₁₁₂)-, —Si(Q₁₁₁)(Q₁₁₂)-, —Ge(Q₁₁₁)(Q₁₁₂)-, —(C(Q₁₁₁)=C(Q₁₁₂))-, and —(C(Q₁₁₁)=N))—,
when L₁₁₁ is selected from —N(Q₁₁₁)-, —B(Q₁₁₁)-, —C(Q₁₁₁)(Q₁₁₂)-, —Si(Q₁₁₁)(Q₁₁₂)-, —Ge(Q₁₁₁)(Q₁₁₂)-, —(C(Q₁₁₁)=C(Q₁₁₂))-, and —(C(Q₁₁₁)=N))-, L₁₁₁ is optionally linked to Ar₁₁₁ or Ar₁₁₂ to form a condensed ring,
Z₁₁₁ is a C₆-C₃₀ carbocyclic group that is unsubstituted or substituted with at least one R₁₀ₐ and has at least one functional group selected from C═O, C═S, C═Se, and C═Te, or a C₁-C₃₀ heterocyclic group that is unsubstituted or substituted with at least one R₁₀ₐ and has at least one functional group selected from C═O, C═S, C═Se, and C═Te,
R₁₁₁ to R₁₁₆ are each independently hydrogen, deuterium, a halogen, a cyano group, a nitro group, a hydroxy group, a C₁-C₃₀ alkyl group that is unsubstituted or substituted with at least one R₁₀ₐ, a C₁-C₃₀ alkoxy group that is unsubstituted or substituted with at least one R₁₀ₐ, a C₆-C₃₀ aryl group that is unsubstituted or substituted with at least one R₁₀ₐ, a C₃-C₃₀ heteroaryl group that is unsubstituted or substituted with at least one R₁₀ₐ, a C₂-C₃₀ acyl group that is unsubstituted or substituted with at least one R₁₀ₐ, or any combination thereof,
R₁₀ₐ is:
deuterium, —F, —Cl, —Br, —I, a hydroxyl group, a cyano group, or a nitro group; a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, or a C₁-C₆₀ heteroarylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁₁ to Q₁₃, Q₂₁ to Q₂₃, Q₃₁ to Q₃₂, Q₁₁₁, and Q₁₁₂ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

11. The organic photodetector of claim 10, wherein Z₁₁₁ in Formula 1 is represented by one of Formulae 111A to 111F: 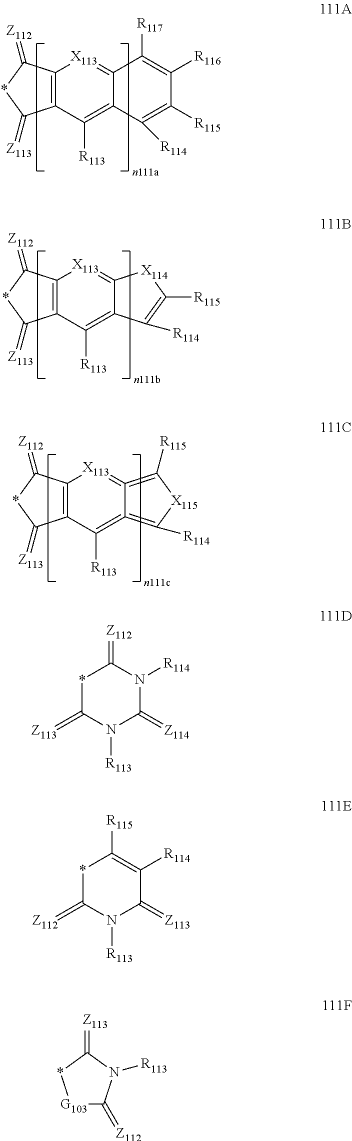
wherein, in Formulae 111A to 111F,
Z₁₁₂ to Z₁₁₄ are each independently O, S, Se, or Te,
X₁₁₃ is N or C(Q₁₁₃),
X₁₁₄ and X₁₁₅ are each independently O, S, Se, Te, Si(Q₁₁₁)(Q₁₁₂), or Ge(Q₁₁₁)(Q₁₁₂),
n₁₁₁ₐ to n_{111c} are each independently an integer from 0 to 3,
R₁₁₃ to R₁₁₇ are each independently hydrogen, deuterium, a halogen, a cyano group, a nitro group, a hydroxy group, a C₁-C₃₀ alkyl group that is unsubstituted or substituted with at least one R₁₀ₐ, a C₆-C₃₀ aryl group that is unsubstituted or substituted with at least one R₁₀ₐ, a C₃-C₃₀ heteroaryl group that is unsubstituted or substituted with at least one R₁₀ₐ, or any combination thereof, and
Q₁₁₁ to Q₁₁₃ are each the same as described in connection with Q₁₁₁ in claim 10.

12. The organic photodetector of claim 1, wherein the n-type semiconductor compound comprises C60 fullerene, C70 fullerene, a compound represented by Formula 2, a compound represented by Formula 3, or any combination thereof: 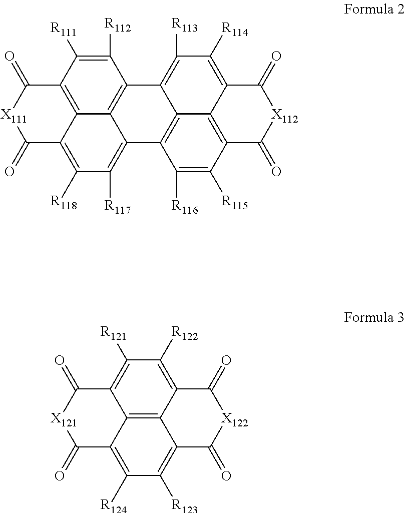
wherein, in Formula 2,
X₁₁₁ and X₁₁₂ are each independently O or NR₁₁₉, and
R₁₁₁ to R₁₁₉ are each independently hydrogen, deuterium, a halogen, a cyano group, a nitro group, a hydroxy group, a C₁-C₃₀ alkyl group that is unsubstituted or substituted with at least one R₁₀ₐ, a C₆-C₃₀ aryl group that is unsubstituted or substituted with at least one R₁₀ₐ, a C₃-C₃₀ heteroaryl group that is unsubstituted or substituted with at least one R₁₀ₐ, or any combination thereof,
in Formula 3,
X₁₂₁ and X₁₂₂ are each independently O or NR₁₂₅, and
R₁₂₁ to R₁₂₅ are each independently hydrogen, deuterium, a halogen, a cyano group, a nitro group, a hydroxy group, a C₁-C₃₀ alkyl group that is unsubstituted or substituted with at least one R₁₀ₐ, a C₆-C₃₀ aryl group that is unsubstituted or substituted with at least one R₁₀ₐ, a C₃-C₃₀ heteroaryl group that is unsubstituted or substituted with at least one R₁₀ₐ, or any combination thereof,
in Formulae 2 and 3,
R₁₀ₐ is:
deuterium, —F, —Cl, —Br, —I, a hydroxyl group, a cyano group, or a nitro group; a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, or a C₁-C₆₀ heteroarylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), -S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁₁ to Q_{13,} Q₂₁ to Q₂₃, Q₃₁, and Q₃₂ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

13. The organic photodetector of claim 12, wherein each of the compound represented by Formula 2 and the compound represented by Formula 3 comprises one of compounds:

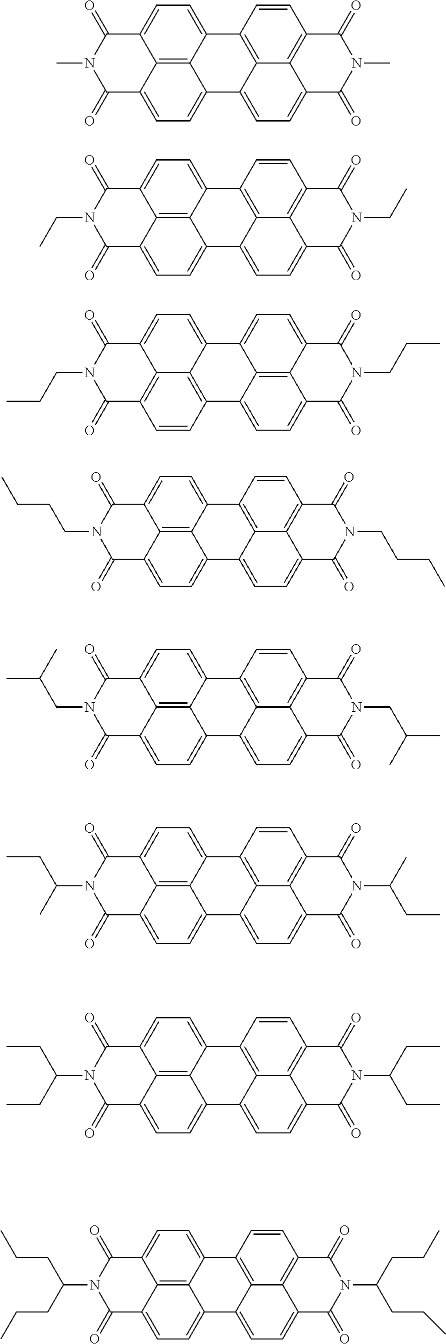

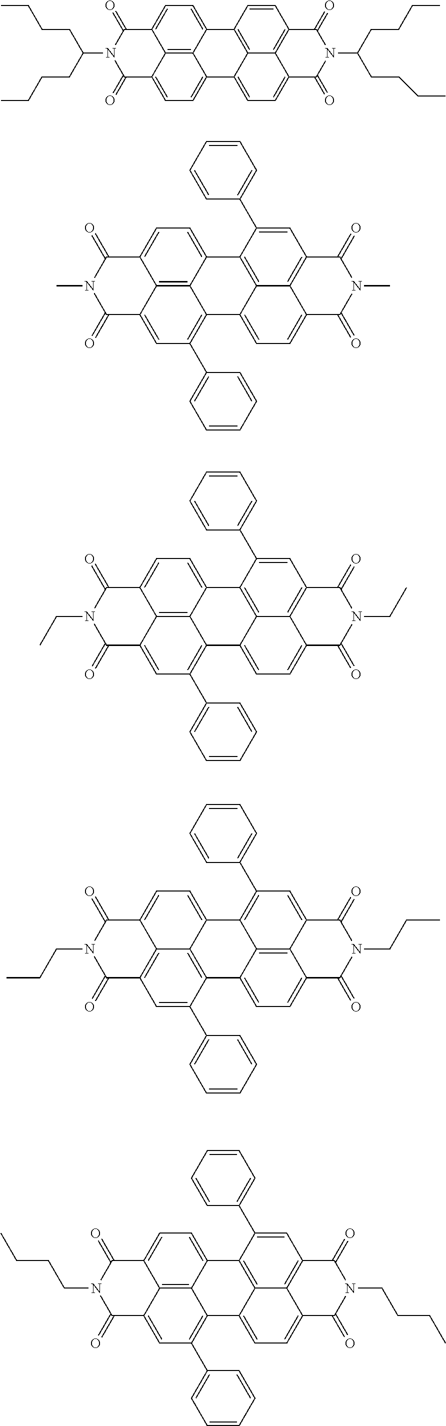

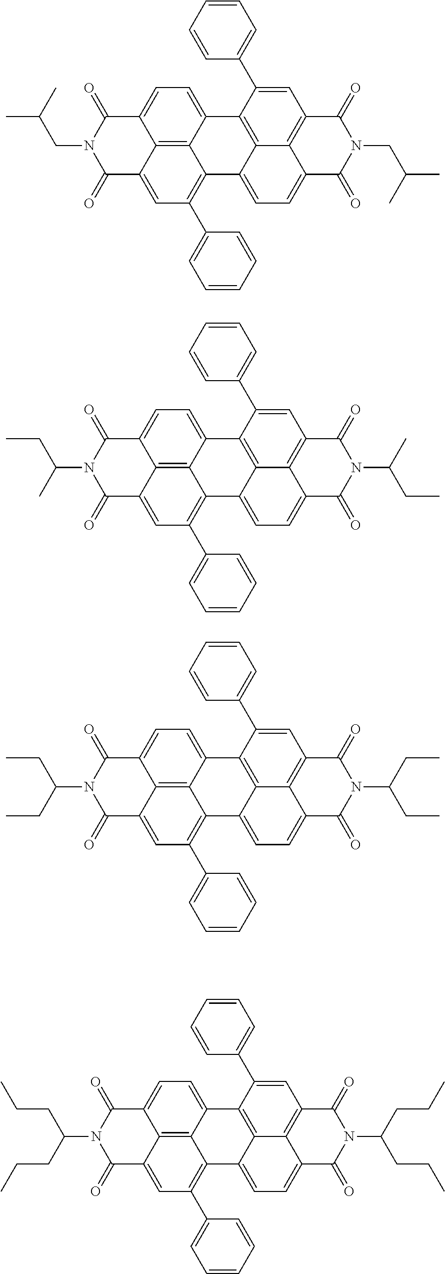

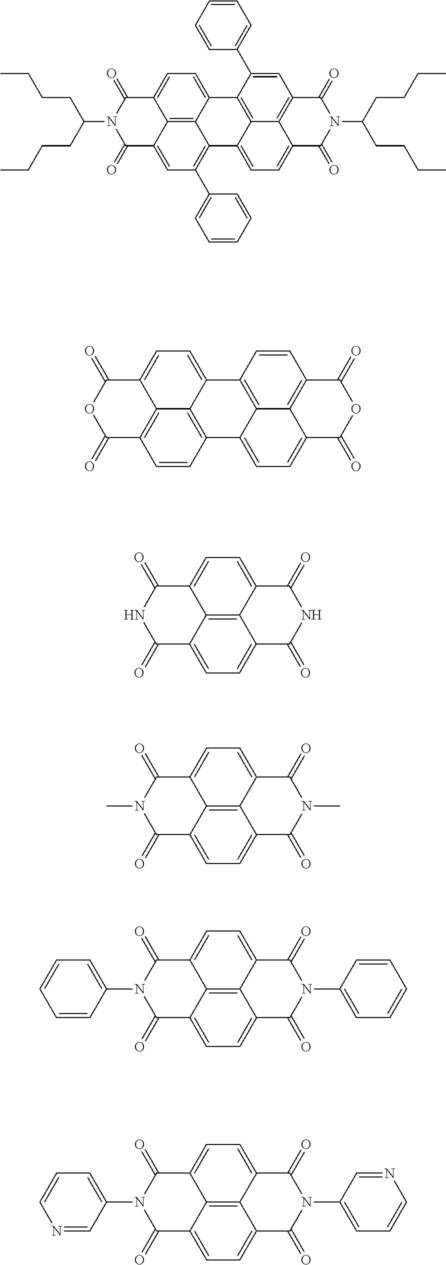

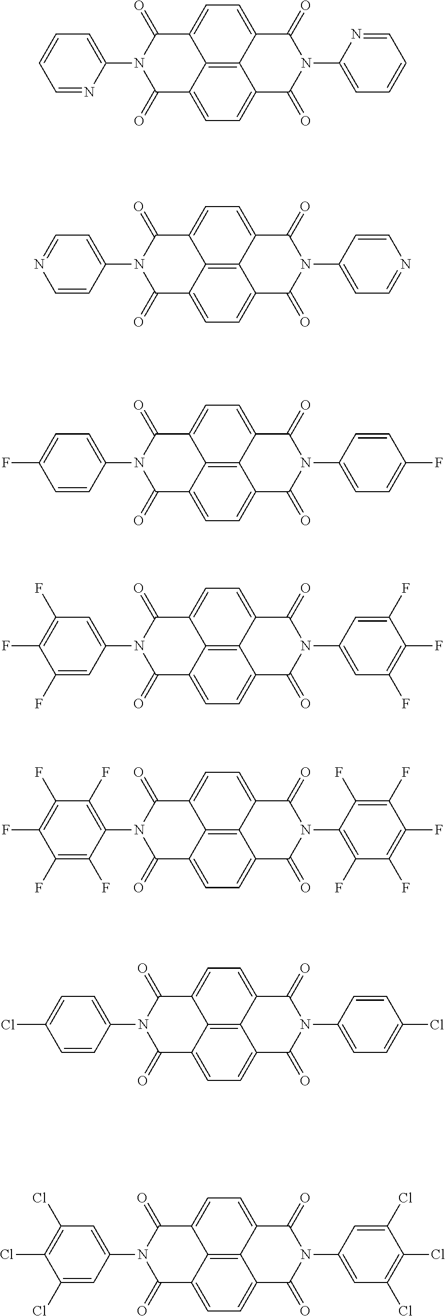

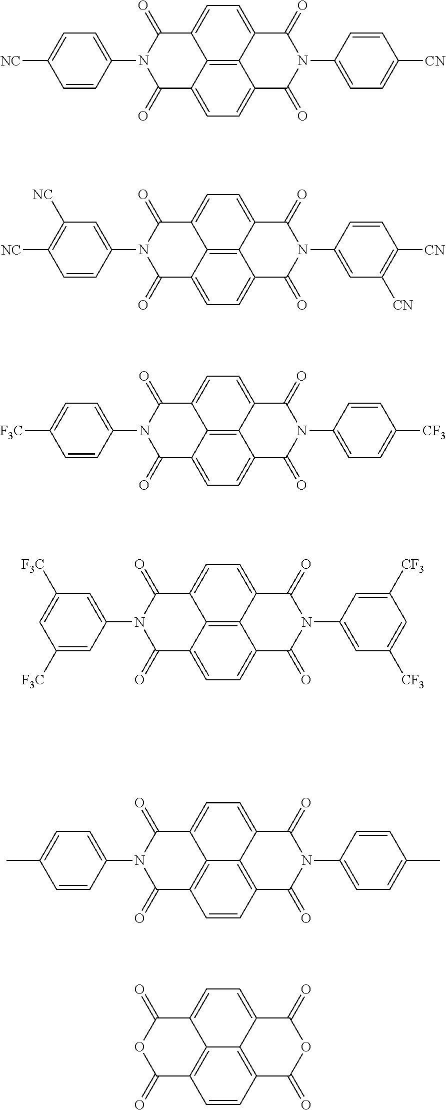

14. The organic photodetector of claim 1, wherein the first amine compound is a tertiary amine compound comprising:
one or two fluorene moieties; and
at least one aryl moiety.

15. The organic photodetector of claim 1, wherein the second amine compound is a tertiary amine compound comprising three fluorene moieties.

16. The organic photodetector of claim 1, wherein the first amine compound comprises one of compounds:

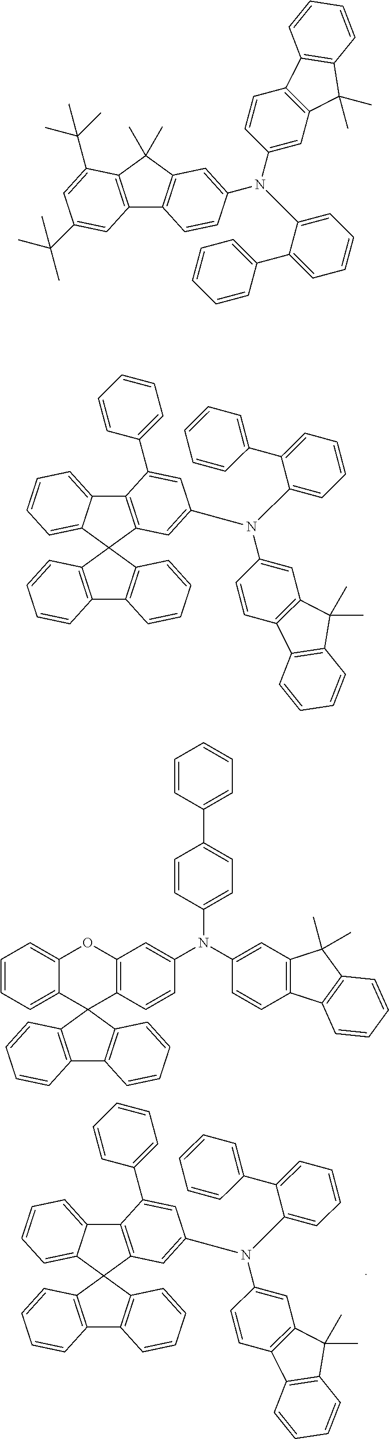

17. The organic photodetector of claim 1, wherein the second amine compound comprises one of compounds:

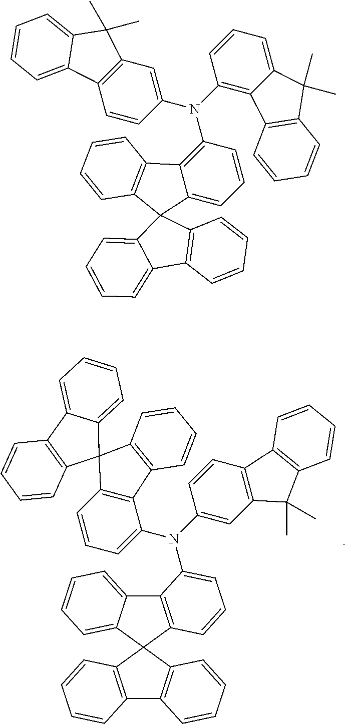 [SMILES: CC1(C)c2ccccc2-c2ccc(N(c3cccc4c3-c3ccccc3C4(C)C)c3cccc4c3-c3ccccc3C43c4ccccc4-c4ccccc43)cc21 ; CC1(C)c2ccccc2-c2ccc(N(c3cccc4c3-c3ccccc3C43c4ccccc4-c4ccccc43)c3cccc4c3-c3ccccc3C43c4ccccc4-c4ccccc43)cc21]

18. An electronic apparatus comprising the organic photodetector of claim 1.

19. The electronic apparatus of claim 18, further comprising a light-emitting device.

20. An electronic apparatus comprising:
a substrate comprising a photodetection area and an emission area;
an organic photodetector on the photodetection area; and
a light-emitting device on the emission area,
wherein the organic photodetector comprises: a first pixel electrode; an opposite electrode facing the first pixel electrode; and a hole transport layer, an optical auxiliary layer, and an activation layer, sequentially arranged between the first pixel electrode and the opposite electrode, the activation layer comprises a p-type semiconductor compound and an n-type semiconductor compound, the optical auxiliary layer comprises a first optical auxiliary layer comprising a first amine compound and a second optical auxiliary layer comprising a second amine compound, a highest occupied molecular orbital (HOMO) energy absolute value of the first amine compound is smaller than a HOMO energy absolute value of the second amine compound, and the first optical auxiliary layer faces the first pixel electrode,
the light-emitting device comprises: a second pixel electrode; the opposite electrode facing the second pixel electrode; and the hole transport layer, the optical auxiliary layer, and an emission layer, sequentially arranged between the second pixel electrode and the opposite electrode,
the first pixel electrode and the activation layer are arranged in correspondence with the photodetection area,
the second pixel electrode and the emission layer are arranged in correspondence with the emission area, and
the hole transport layer, the optical auxiliary layer, and the opposite electrode are arranged throughout the photodetection area and the emission area.
